(19) United States
(12) Patent Application Publication
(10) Pub. No.: US 2025/0280524 A1
(43) Pub. Date: Sep. 4, 2025

(54) SEMICONDUCTOR MEMORY DEVICES

(71) Applicant: Samsung Electronics Co., Ltd., Suwon-si (KR)

(72) Inventors: Keonhee PARK, Suwon-si (KR); Haewook JEONG, Suwon-si (KR)

(73) Assignee: Samsung Electronics Co., Ltd., Suwon-si (KR)

(21) Appl. No.: 18/986,236

(22) Filed: Dec. 18, 2024

(30) Foreign Application Priority Data
Dec. 29, 2023 (KR) 10-2023-0197698

(51) Int. Cl. H10B 12/00

(52) U.S. Cl. CPC H10B 12/30; H10B 12/05

(57) ABSTRACT

A semiconductor memory device is provided The semiconductor memory device includes: a semiconductor pattern extending in a first direction; a bit line extending in a second direction perpendicular to the first direction and connected to a first end of the semiconductor pattern in the first direction; a cell capacitor extending in the first direction and connected to a second end of the semiconductor pattern in the first direction; a gate structure extending in a third direction perpendicular to both the first direction and the second direction; and a back gate structure extending in the third direction. The semiconductor pattern is between the gate structure and the back gate structure. The back gate structure covers one surface of the semiconductor pattern and the gate structure covers other surfaces of the semiconductor pattern.

### CROSS-REFERENCE TO RELATED APPLICATION

This application claims priority to Korean Patent Application No. 10-2023-0197698, filed on Dec. 29, 2023, in the Korean Intellectual Property Office, the disclosure of which is incorporated by reference herein in its entirety.

### BACKGROUND

The present disclosure relates to a semiconductor memory device, and more particularly, to a three-dimensional semiconductor memory device.

To meet demands for miniaturization, multifunctionality, and high performance in electronic products, there is a need for high-capacity semiconductor memory devices. To this end, increased degrees of integration are required to provide high-capacity semiconductor memory devices. The degrees of integration of two-dimensional semiconductor memory devices are mainly determined by the areas occupied by unit memory cells. Accordingly, although the degrees of integration of two-dimensional semiconductor memory devices have been increased, the increase is still limited. Therefore, three-dimensional semiconductor memory devices to increase memory capacities by stacking a plurality of memory cells in a vertical direction on a substrate have been proposed.

### SUMMARY

One or more example embodiments provide a three-dimensional semiconductor memory device having improved operation reliability.

According to an aspect of an example embodiment, a semiconductor memory device includes: a semiconductor pattern extending in a first direction; a bit line extending in a second direction perpendicular to the first direction and connected to a first end of the semiconductor pattern in the first direction; a cell capacitor extending in the first direction and connected to a second end of the semiconductor pattern in the first direction; a gate structure extending in a third direction perpendicular to both the first direction and the second direction; and a back gate structure extending in the third direction. The semiconductor pattern is between the gate structure and the back gate structure, and the back gate structure covers one surface of the semiconductor pattern and the gate structure covers other surfaces of the semiconductor pattern.

According to another aspect of an example embodiment, a semiconductor memory device includes: a plurality of semiconductor patterns, each of the plurality of semiconductor patterns extending in a first horizontal direction on a substrate, wherein the plurality of semiconductor patterns are spaced apart from each other in a vertical direction and a second horizontal direction perpendicular to the first horizontal direction; a plurality of bit lines extending in the vertical direction on the substrate, wherein the plurality of bit lines are spaced apart from each other in the second horizontal direction, and connected to first ends of the plurality of semiconductor patterns in the first horizontal direction; a plurality of cell capacitors extending in the first horizontal direction on the substrate and connected to second ends of the plurality of semiconductor patterns in the first horizontal direction; a plurality of back gate structures extending in the second horizontal direction and covering a first one of upper surfaces and lower surfaces of the plurality of semiconductor patterns, wherein the plurality of back gate structures are spaced apart from each other in the vertical direction; and a plurality of gate structures extending in the second horizontal direction and covering a second one of the upper surfaces and the lower surfaces of the plurality of semiconductor patterns, and each of two side surfaces of the plurality of semiconductor patterns in the second horizontal direction. An upper surface and a lower surface of one back gate structure among the plurality of back gate structures respectively cover a lower surface of a first semiconductor pattern, which is one semiconductor pattern provided above the one back gate structure among the plurality of semiconductor patterns, and an upper surface of a second semiconductor pattern, which is another semiconductor pattern provided below the one back gate structure among the plurality of semiconductor patterns.

According to another aspect of an example embodiment, a semiconductor memory device includes: a plurality of semiconductor patterns, each of the plurality of semiconductor patterns extending in a first horizontal direction on a substrate, wherein the plurality of semiconductor patterns are spaced apart from each other in a vertical direction and a second horizontal direction perpendicular to the first horizontal direction; a plurality of bit lines extending in the vertical direction on the substrate, wherein the plurality of bit lines are spaced apart from each other in the second horizontal direction, and connected to first ends of the plurality of semiconductor patterns in the first horizontal direction; a plurality of cell capacitors extending in the first horizontal direction on the substrate and connected to second ends of the plurality of semiconductor patterns in the first horizontal direction; a plurality of back gate structures, each of the plurality of back gate structures extending in the second horizontal direction, wherein the plurality of back gate structures are spaced apart from each other in the vertical direction, the plurality of back gate structures each including a back gate dielectric film covering a first one of an upper surface and a lower surfaces of a corresponding semiconductor pattern among the plurality of semiconductor patterns and a back gate electrode film covering the back gate dielectric film; and a plurality of gate structures, each of the plurality of gate structures extending in the second horizontal direction, wherein the plurality of gate structures are spaced apart from each other in the vertical direction, and each of the plurality of gate structures includes a gate dielectric film covering a second one of the upper surface and the lower surface of the corresponding semiconductor pattern among the plurality of semiconductor patterns and both of side surfaces of the corresponding semiconductor pattern in the second horizontal direction and a gate electrode film covering the gate dielectric film. Two gate structures among the plurality of gate structures are between one semiconductor pattern among the plurality of semiconductor patterns and another semiconductor pattern above the one semiconductor pattern, and one back gate structure among the plurality of back gate structures is between one semiconductor pattern among the plurality of semiconductor patterns and another semiconductor pattern below the one semiconductor pattern.

### BRIEF DESCRIPTION OF DRAWINGS

The above and other aspects will be more apparent from the following description of example embodiments taken in conjunction with the accompanying drawings, in which:

FIG. 1 is an equivalent circuit diagram showing a cell array of a semiconductor memory device according to example embodiments;

FIGS. 2A, 2B, 2C, 2D, 2E, 2F, 2G, 3A, 3B, 3C, 3D, 3E, 3F, 3G, 4A, 4B, 4C, 4D, 4E, 4F, 4G, 5A, 5B, 5C, 5D, 5E, 5F, 5G, 6A, 6B, 6C, 6D, 6E, 6F, 6G, 7A, 7B, 7C, 7D, 7E, 7F, 7G, 8A, 8B, 8C, 8D, 8E, 8F, 8G, 9A, 9B, 9C, 9D, 9E, 9F, 9G, 10A, 10B, 10C, 10D, 10E, 10F, 10G, 11A, 11B, 11C, 11D, 11E, 11F, 11G, 12A, 12B, 12C, 12D, 12E, 12F, 12G, 13A, 13B, 13C, 13D, 13E, 13F, 13G, 14A, 14B, 14C, 14D, 14E, 14F, 14G, 15A, 15B, 15C, 15D, 15E, 15F, 15G, 16A, 16B, 16C, 16D, 16E, 16F, 16G, 17A, 17B, 17C, 17D, 17E, 17F and 17G are diagrams showing a method of manufacturing a semiconductor memory device in a process order, according to example embodiments;

FIG. 18A, 18B, 18C, 18D, 18E, 18F and 18G are diagrams showing a semiconductor memory device according to example embodiments;

FIG. 19, 20A, 20B, 20C and 20D are partial enlarged views of a semiconductor memory device according to example embodiments;

FIG. 21 is an equivalent circuit diagram showing a cell array of a semiconductor memory device according to an example embodiment;

FIGS. 22A, 22B, 22C, 22D, 22E, 22F, 22G, 23A, 23B, 23C, 23D, 23E, 23F, 23G, 24A, 24B, 24C, 24D, 24E, 24F, 24G, 25A, 25B, 25C, 25D, 25E, 25F, 25G, 26A, 26B, 26C, 26D, 26E, 26F, 26G, 27A, 27B, 27C, 27D, 27E, 27F, 27G, 28A, 28B, 28C, 28D, 28E, 28F, 28G, 29A, 29B, 29C, 29D, 29E, 29F, 29G, 30A, 30B, 30C, 30D, 30E, 30F, 30G, 31A, 31B, 31C, 31D, 31E, 31F, 31G, 32A, 32B, 32C, 32D, 32E, 32F and 32G are diagrams showing a method of manufacturing a semiconductor memory device in a process order, according to example embodiments;

FIG. 33A, 33B, 33C, 33D, 33E, 33F and 33G are diagrams showing a semiconductor memory device according to example embodiments;

FIG. 34, 35A, 35B, 35C and 35D are partial enlarged views of a semiconductor memory device according to example embodiments;

FIG. 36 is an equivalent circuit diagram showing a cell array of a semiconductor memory device 3 according to example embodiments;

FIG. 37 is a partial enlarged view of the semiconductor memory device 3 according to example embodiments;

FIG. 38 is an equivalent circuit diagram showing a cell array of a semiconductor memory device 4 according to example embodiments; and

FIG. 39 is a partial enlarged view of the semiconductor memory device 4 according to example embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

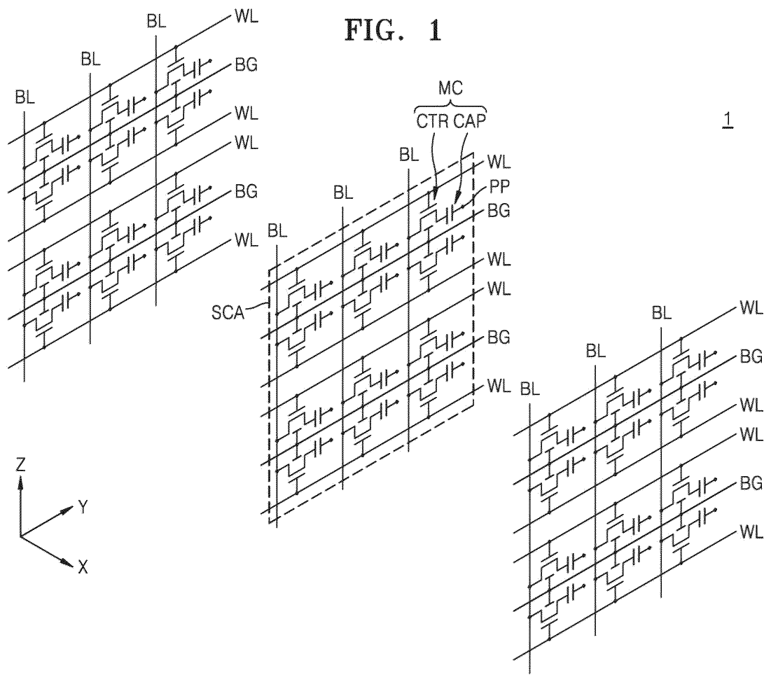

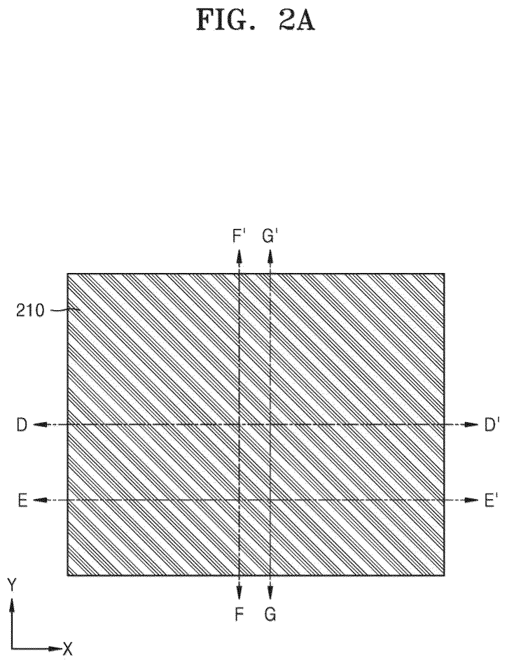

FIG. 1 is an equivalent circuit diagram showing a cell array of a semiconductor memory device 1 according to an example embodiment.

Referring to FIG. 1, the cell array of the semiconductor memory device 1 according to example embodiments may include a plurality of sub cell arrays SCA. The plurality of sub cell arrays SCA may be arranged in a first horizontal direction (X direction).

Each of the sub cell arrays SCA may include a plurality of bit lines BL, a plurality of word lines WL, a plurality of back gate lines BG, and a plurality of cell transistors CTR. One cell transistor CTR may be located between one word line WL and one bit line BL.

The word line WL may be spaced apart from a substrate and include a conductive pattern (e.g., a metal line) disposed above the substrate. The plurality of word lines WL may extend in a second horizontal direction (a Y direction). The second horizontal direction (the Y direction) may be perpendicular to the first horizontal direction (an X direction). The word lines WL in one sub cell array SCA may be spaced apart from each other in a vertical direction (a Z direction). Each of the back gate lines BG may be spaced apart from the substrate and include a conductive pattern (e.g., a metal line) disposed above the substrate. The plurality of back gate lines BG may extend in the second horizontal direction (the Y direction). The back gate lines BG in one sub cell array SCA may be spaced apart from each other in the vertical direction (the Z direction).

The word lines WL and the back gate lines BG in one sub cell array SCA may be spaced apart from each other in the vertical direction (the Z direction) and extend parallel to each other in the second horizontal direction (the Y direction). Each of the plurality of back gate lines BG may be located between a pair of neighboring word lines WL among the word lines WL. In one sub cell array SCA, the number of word lines WL may be approximately twice the number of back gate lines BG. For example, the word lines WL and the back gate lines BG in one sub cell array SCA may be configured such that two word lines WL among the word lines WL and one back gate line BG among the back gate lines BG are alternately arranged in the vertical direction (the Z direction). In this regard, one back gate line BG among the back gate lines BG may be located between two word lines WL adjacent to each other in the vertical direction (Z direction) among the word lines WL in one sub cell array SCA. Also, two word lines WL among the word lines WL may be arranged between two back gate lines BG adjacent to each other in the vertical direction (Z direction) among the back gate lines BG in the one sub cell array SCA.

The bit line BL may include a conductive pattern (e.g., a metal line) extending from the substrate in the vertical direction (Z direction). The bit lines BL in one sub cell array SCA may be spaced apart from each other in the second horizontal direction (Y direction).

A gate of the cell transistor CTR may be connected to the word line WL and a source of the cell transistor CTR may be connected to the bit line BL. The cell transistor CTR may be connected to a cell capacitor CAP. A drain of the cell transistor CTR may be connected to a first electrode of the cell capacitor CAP, and a second electrode of the cell capacitor CAP may be connected to a ground wire PP.

The semiconductor memory device 1 may include the plurality of sub cell arrays SCA, each of which includes a plurality of memory cells MC spaced apart from each other in the second horizontal direction (Y direction) and the vertical direction (Z direction) and arranged in rows and columns, the plurality of bit lines BL connected to the cell transistors CTR of the memory cells MC arranged in the vertical direction (Z direction), extending in the vertical direction (Z direction), and spaced apart from each other in the second horizontal direction (Y direction), and the plurality of word lines WL extending in the second horizontal direction (Y direction) and spaced apart from each other in the vertical direction (Z direction). The plurality of sub cell arrays SCA may be arranged in the first horizontal direction (X direction).

The first horizontal direction (X direction), the vertical direction (Z direction), and the second horizontal direction (Y direction) may be referred to as a first direction, a second direction, and a third direction, respectively. The first direction, the second direction, and the third direction may be perpendicular to each other.

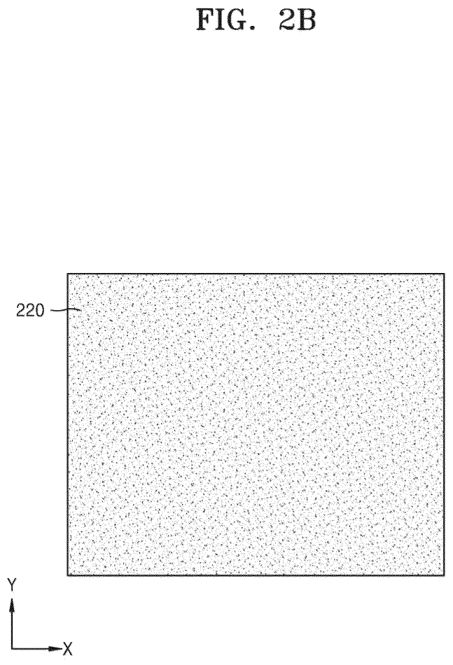

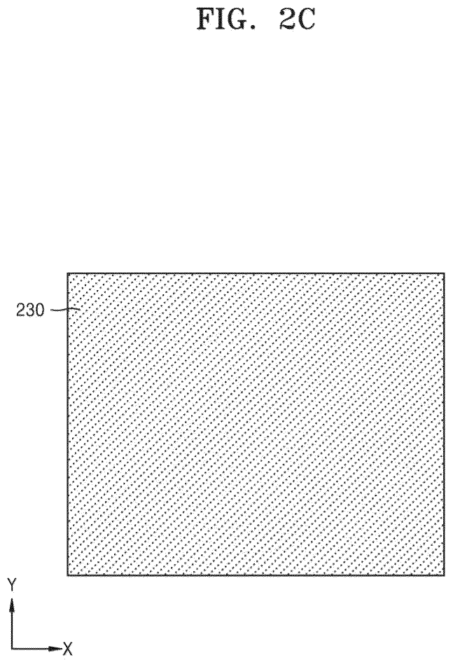

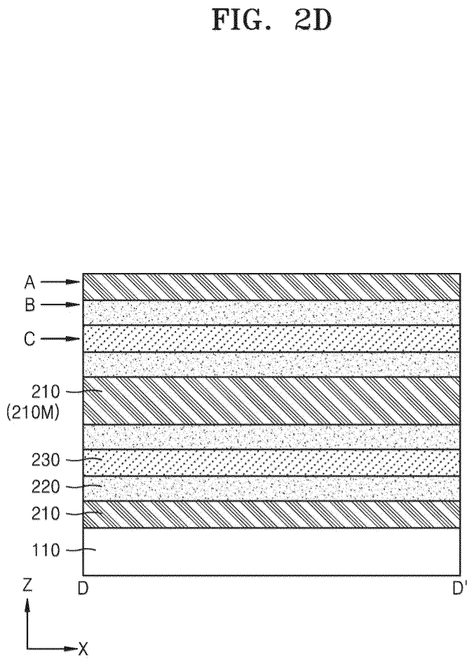

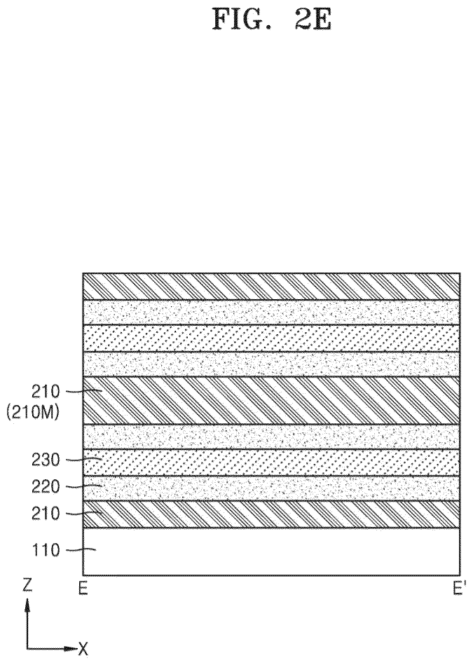

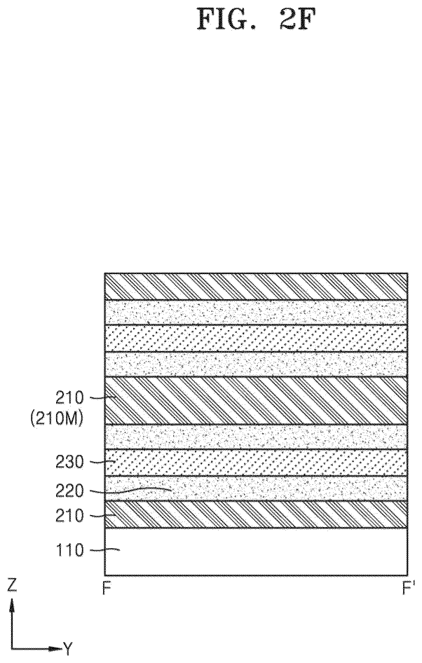

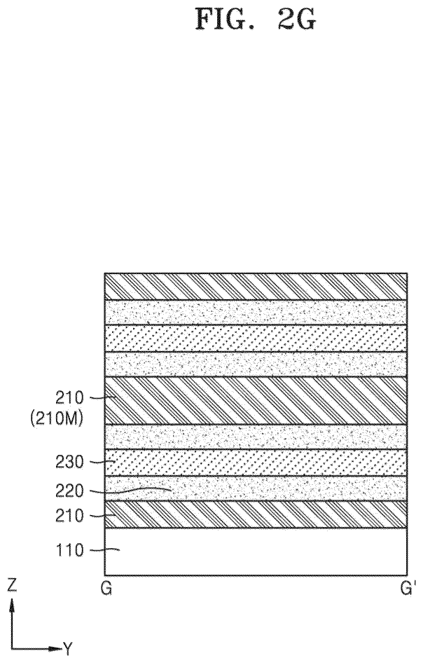

FIGS. 2A to 17G are diagrams showing a method of manufacturing a semiconductor memory device in a process order, according to example embodiments. Specifically, FIGS. 2A, 3A, 4A, 5A, 6A, 7A, 8A, 9A, 10A, 11A, 12A, 13A, 14A, 15A, 16A, and 17A are horizontal cross-sectional views of the semiconductor memory device taken along vertical level A of FIGS. 2D, 3D, 4D, 5D, 6D, 7D, 8D, 9D, 10D, 11D, 12D, 13D, 14D, 15D, 16D, and 17D. Also, FIGS. 2B, 3B, 4B, 5B, 6B, 7B, 8B, 9B, 10B, 11B, 12B, 13B, 14B, 15B, 16B, and 17B are horizontal cross-sectional views of the semiconductor memory device taken along vertical level B of FIGS. 2D, 3D, 4D, 5D, 6D, 7D, 8D, 9D, 10D, 11D, 12D, 13D, 14D, 15D, 16D, and 17D. Also, FIGS. 2C, 3C, 4C, 5C, 6C, 7C, 8C, 9C, 10C, 11C, 12C, 13C, 14C, 15C, 16C, and 17C are horizontal cross-sectional views of the semiconductor memory device taken along vertical level C of FIGS. 2D, 3D, 4D, 5D, 6D, 7D, 8D, 9D, 10D, 11D, 12D, 13D, 14D, 15D, 16D, and 17D. Also, FIGS. 2D, 3D, 4D, 5D, 6D, 7D, 8D, 9D, 10D, 11D, 12D, 13D, 14D, 15D, 16D, and 17D are vertical cross-sectional views of the semiconductor memory device taken along line D-D′ of FIGS. 2A, 3A, 4A, 5A, 6A, 7A, 8A, 9A, 10A, 11A, 12A, 13A, 14A, 15A, 16A, and 17A. Also, FIGS. 2E, 3E, 4E, 5E, 6E, 7E, 8E, 9E, 10E, 11E, 12E, 13E, 14E, 15E, 16E, and 17E are vertical cross-sectional views of the semiconductor memory device taken along line E-E′ of FIGS. 2A, 3A, 4A, 5A, 6A, 7A, 8A, 9A, 10A, 11A, 12A, 13A, 14A, 15A, 16A, and 17A. Also, FIGS. 2F, 3F, 4F, 5F, 6F, 7F, 8F, 9F, 10F, 11F, 12F, 13F, 14F, 15F, 16F, and 17F are vertical cross-sectional views of the semiconductor memory device taken along line F-F′ of FIGS. 2A, 3A, 4A, 5A, 6A, 7A, 8A, 9A, 10A, 11A, 12A, 13A, 14A, 15A, 16A, and 17A. Also, FIGS. 2G, 3G, 4G, 5G, 6G, 7G, 8G, 9G, 10G, 11G, 12G, 13G, 14G, 15G, 16G, and 17G are vertical cross-sectional views of the semiconductor memory device taken along line G-G′ of FIGS. 2A, 3A, 4A, 5A, 6A, 7A, 8A, 9A, 10A, 11A, 12A, 13A, 14A, 15A, 16A, and 17A.

Referring to FIGS. 2A to 2G together, a plurality of first insulating layers 210, a plurality of semiconductor layers 220, and a plurality of second insulating layers 230 are formed on the substrate 110. The plurality of first insulating layers 210, the plurality of semiconductor layers 220, and the plurality of second insulating layers 230 may be formed by a chemical vapor deposition (CVD) process, a plasma enhanced CVD (PECVD) process, or an atomic layer deposition (ALD) process. The semiconductor layers 220 may be disposed above and below the second insulating layer 230, and either the first insulating layer 210 or the second insulating layer 230 may be disposed above and below the semiconductor layer 220. A sub stack structure including the first insulating layer 210, the semiconductor layer 220, the second insulating layer 230, and the semiconductor layer 220 may be repeatedly stacked on the substrate 110. In some example embodiments, each of the first insulating layers 210, the semiconductor layers 220, and the second insulating layers 230 may have a thickness of about 10 nm to about 40 nm.

In some example embodiments, a first insulating layer 210M located between two semiconductor layers 220 adjacent to each other in the vertical direction (Z direction) among the plurality of first insulating layers 210 may be thicker than the other first insulating layers 210. For convenience of description, the first insulating layer 210M located between two semiconductor layers 220 adjacent to each other in the vertical direction (Z direction) among the plurality of first insulating layers 210 may be referred to as a middle insulating layer 210M. For example, the middle insulating layer 210M may have a thickness about twice that of the other first insulating layers 210. In some example embodiments, the middle insulating layer 210M may have a thickness of about 20 nm to about 40 nm, and the other first insulating layers 210 may have a thickness of about 10 nm to about 40 nm.

In some example embodiments, the middle insulating layer 210M may include a stack of two first insulating layers 210 obtained by continuously forming the first insulating layer 210 twice. For example, a sub stack structure including the first insulating layer 210, the semiconductor layer 220, the second insulating layer 230, the semiconductor layer 220, and the first insulating layer 210 may be repeatedly stacked on the substrate 110. In some example embodiments, the middle insulating layer 210M may include a stack of two first insulating layers 210 obtained by continuously forming the first insulating layer 210 twice, and the interface between the two stacked first insulating layers 210 may not be observed. In some example embodiments, the interface between the two stacked first insulating layers 210 may be observed.

The substrate 110 may include, for example, silicon (Si), such as crystalline Si, polycrystalline Si, and amorphous Si. Also, the substrate 110 may include a semiconductor element, such as germanium (Ge), or may include at least one compound semiconductor selected from a group consisting of silicon germanium (SiGe), silicon carbide (SiC), gallium arsenide (GaAs), indium arsenide (InAs), and indium phosphide (InP). Also, the substrate 110 may include a silicon-on-insulator (SOI) substrate or a germanium-on-insulator (GeOI) substrate. For example, the substrate 110 may have a buried oxide (BOX) layer. The substrate 110 may include a conductive region, for example, a well doped with impurities or a structure doped with impurities.

The first insulating layer 210, the semiconductor layer 220, and the second insulating layer 230 may include materials having etch selectivities relative to each other. For example, each of the first insulating layer 210, the semiconductor layer 220, and the second insulating layer 230 may be etched using difference etch recipes. In some example embodiments, the first insulating layer 210 may include nitride and the second insulating layer 230 may include oxide. For example, the first insulating layer 210 may include silicon nitride and the second insulating layer 230 may include silicon oxide. In some example embodiments, the semiconductor layer 220 may include a material having the same or similar etch characteristics as the substrate 110 or include the same material as the substrate 110. In some example embodiments, the semiconductor layer 220 may include Si. In some example embodiments, the semiconductor layer 220 may include a single crystalline semiconductor material. For example, the semiconductor layer 220 may include single crystalline Si. In some example embodiments, the semiconductor layer 220 may include a 2D semiconductor material or an oxide semiconductor material. For example, the 2D semiconductor material may include MoS₂, WSe₂, Graphene, Carbon Nano Tube, or a combination thereof. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the semiconductor layer 220 may include a single layer or multiple layers of the oxide semiconductor material. In some example embodiments, the semiconductor layer 220 may include a material having band gap energy greater than that of silicon. For example, the semiconductor layer 220 may include a material having band gap energy of about 1.5 eV to 5.6 eV. For example, each of the semiconductor layers 220 may include a material that may exhibit optimal channel performance when having a band gap energy of about 2.0 eV to 4.0 eV.

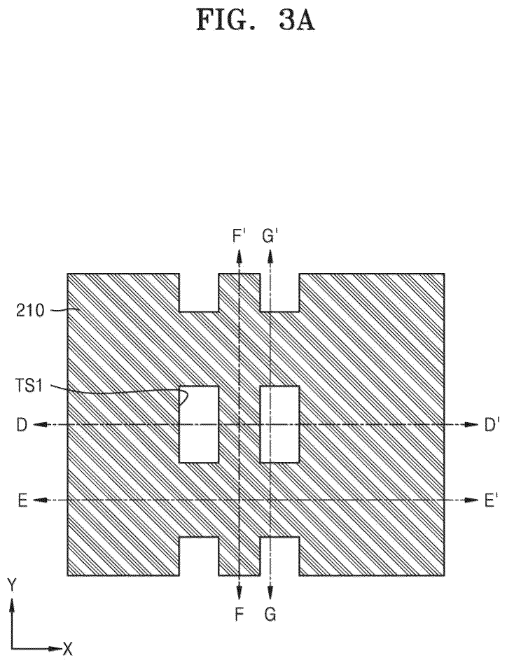

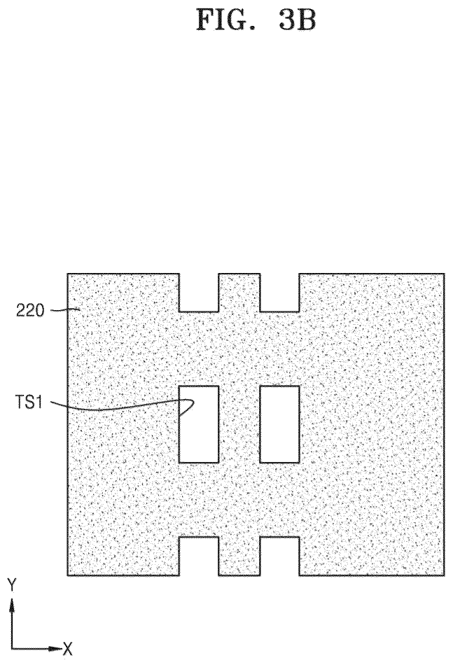

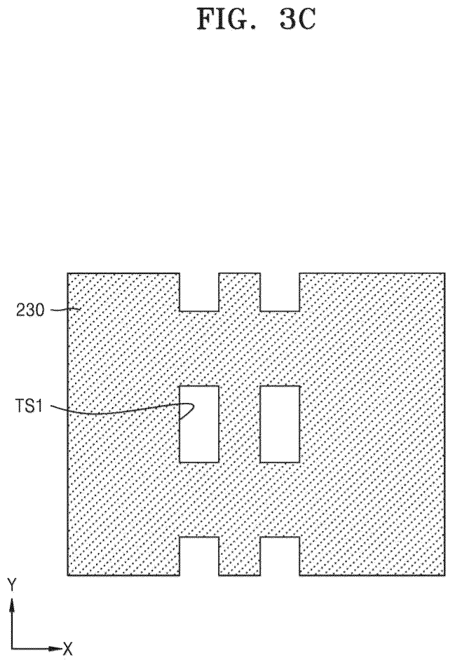

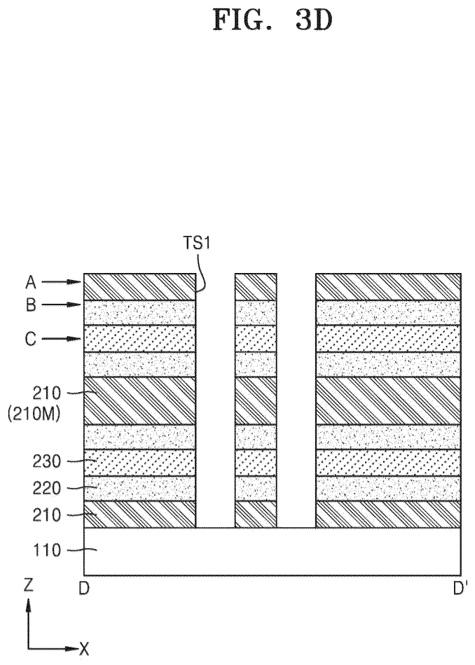

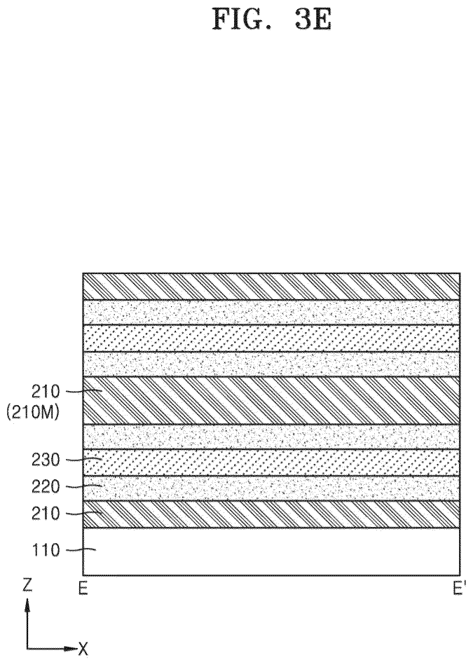

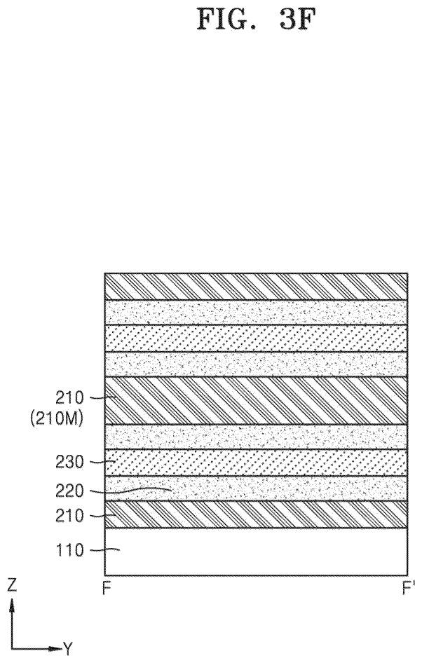

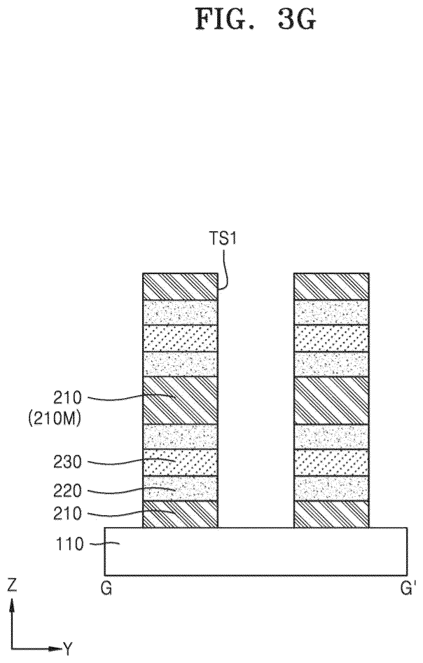

Referring to FIGS. 3A to 3G together, a plurality of first trim spaces TS1 are formed, which pass through the plurality of first insulating layers 210, the plurality of semiconductor layers 220, and the plurality of second insulating layers 230 but are spaced apart from each other in a plan view. Two of the plurality of first trim spaces TS1 may be arranged in the first horizontal direction (X direction), and the first trim spaces TS1 may be arranged in a row in the second horizontal direction (Y direction). The substrate 110 may be exposed from the bottom surface of each of the plurality of first trim spaces TS1.

The plurality of first trim spaces TS1 may have substantially the same horizontal width and the horizontal area in the vertical direction (Z direction), but example embodiments are not limited thereto. For example, each of the plurality of first trim spaces TS1 may have a tapered shape in which the horizontal width and horizontal area thereof increase in the vertical direction (Z direction) away from the substrate 110.

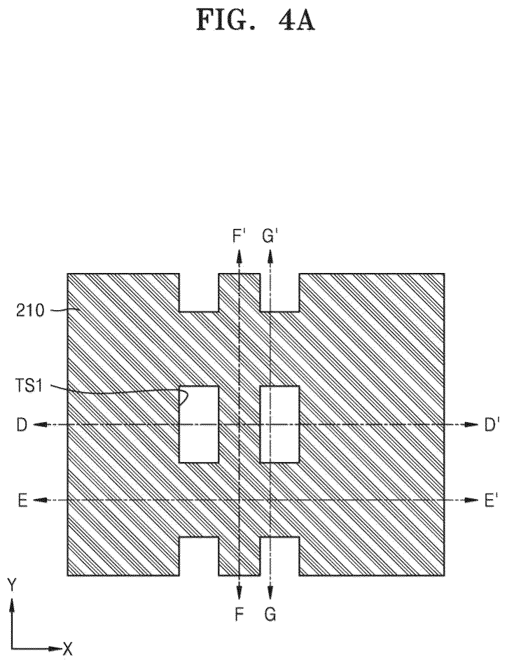

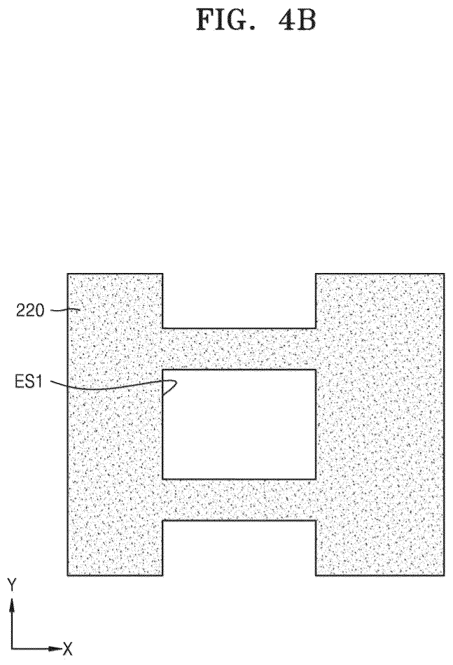

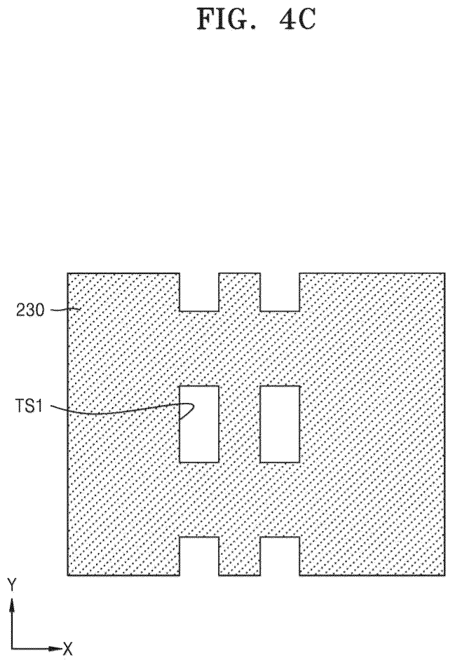

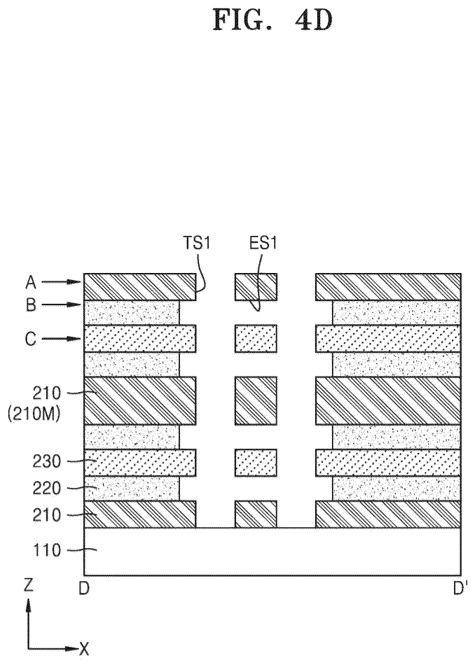

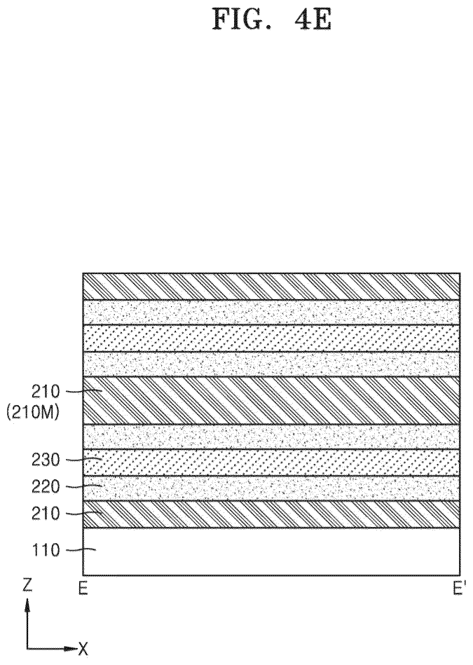

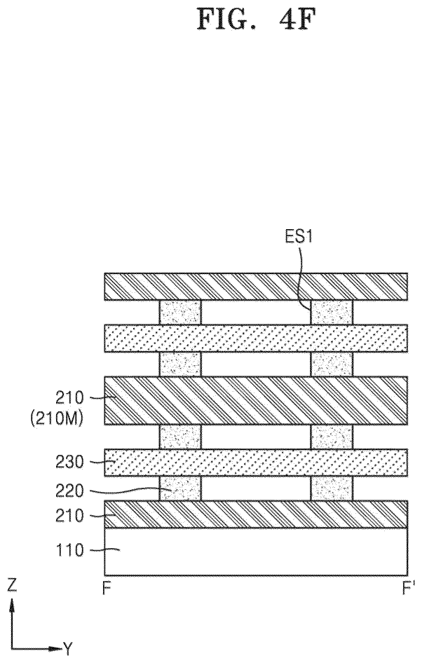

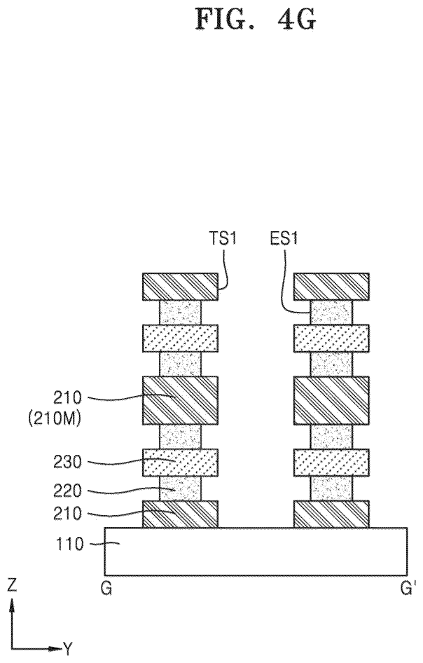

Referring to FIGS. 4A to 4G together, a portion of the plurality of semiconductor layers 220 is removed through the plurality of first trim spaces TS1 to form a plurality of first expansion spaces ES1 in each of the plurality of semiconductor layers 220. For example, the portion of the semiconductor layers may be removed through an etching operation. Each of the plurality of first expansion spaces ES1 may be formed such that two first trim spaces TS1 adjacent to each other in the first horizontal direction (X direction) in each of the plurality of semiconductor layers 220 are connected.

The horizontal width of the first expansion space ES1 of the semiconductor layer 220 in each of the first horizontal direction (X direction) and the second horizontal direction (Y direction) may be greater than the horizontal width of the footprint occupied by the two first trim spaces TS1 that are provided in each of the first insulating layer 210 and the second insulating layer 230 and adjacent to each other in the first horizontal direction (X direction).

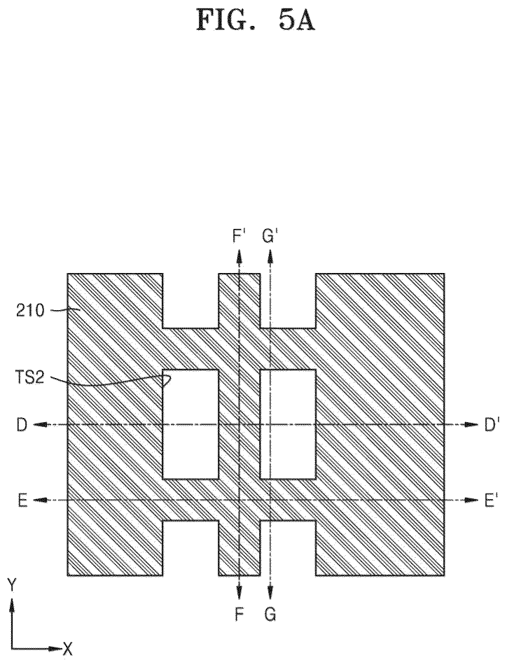

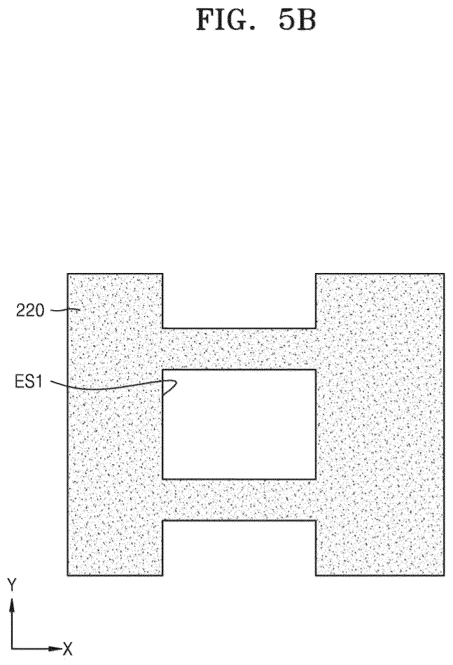

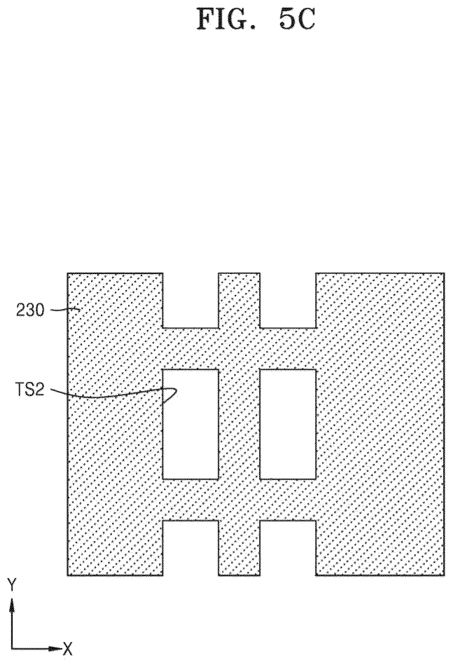

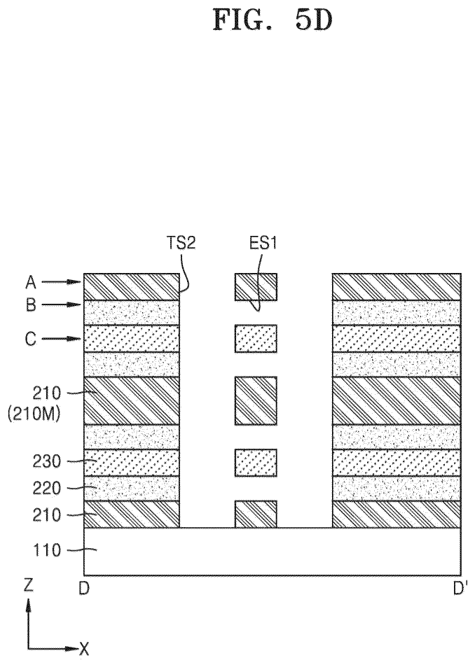

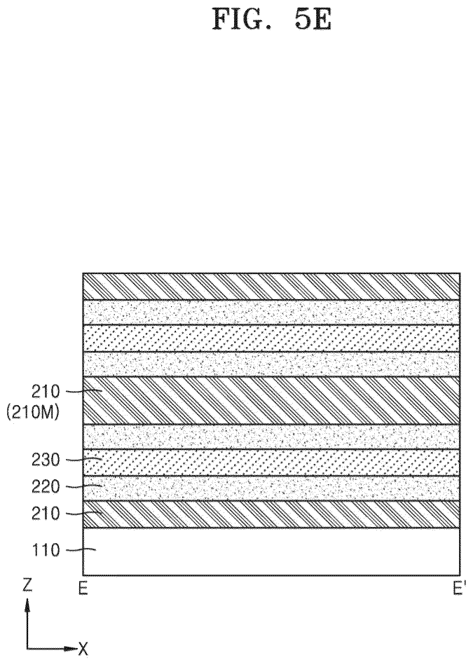

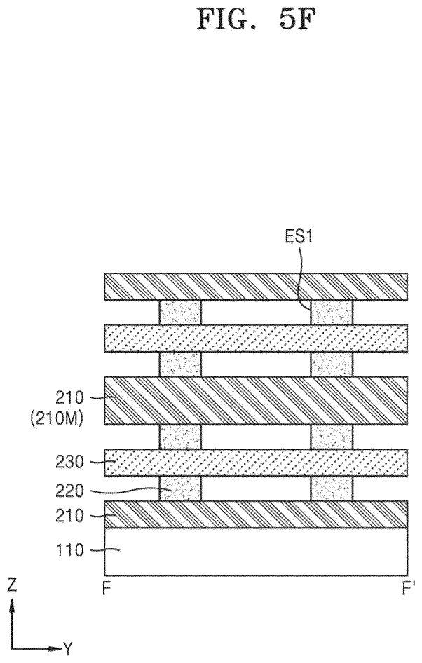

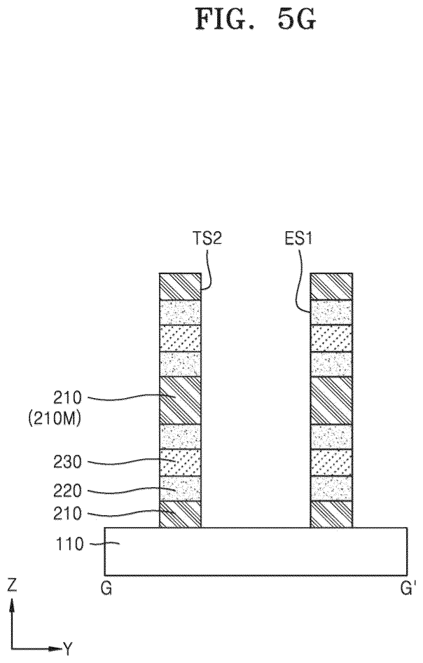

Referring to FIGS. 4A to 4G and FIGS. 5A to 5G together, portions of each of the plurality of first insulating layers 210 and the plurality of second insulating layers 230 are removed to form a plurality of second trim spaces TS2 in which the plurality of first trim spaces TS1 provided in each of the plurality of first insulating layers 210 and the plurality of second insulating layers 230 are expanded.

In some example embodiments, a mask layer corresponding to the semiconductor layer 220 and portions of the first insulating layer 210 and portions of the second insulating layer 230 located between two first trim spaces TS1 adjacent to each other in the first horizontal direction (X direction) in a plan view is formed on the stack structure of the plurality of first insulating layers 210, the plurality of semiconductor layers 220, and the plurality of second insulating layers 230. Subsequently, portions of each of the plurality of first insulating layers 210 and the plurality of second insulating layers 230 may be removed using the mask layer as an etch mask to form the plurality of second trim spaces TS2.

In some example embodiments, portions of each of the plurality of first insulating layers 210 and the plurality of second insulating layers 230 are removed using an etching solution or an etching gas having an etch selectivity relative to the semiconductor layer 220, so that two second trim spaces TS2 adjacent to each other in the first horizontal direction (X direction) among the plurality of second trim spaces TS2 in which the plurality of first trim spaces TS1 are expanded are not connected to each other. As a result, the plurality of second trim spaces TS2 may be formed.

In some example embodiments, the horizontal width of the footprint occupied by the two second trim spaces TS2, which are provided in each of the first insulating layer 210 and the second insulating layer 230 in the first horizontal direction (X direction) and the second horizontal direction (Y direction) and adjacent to each other in the first horizontal direction (X direction), may have substantially the same as the horizontal width of the first expansion space ES1 of the semiconductor layer 220.

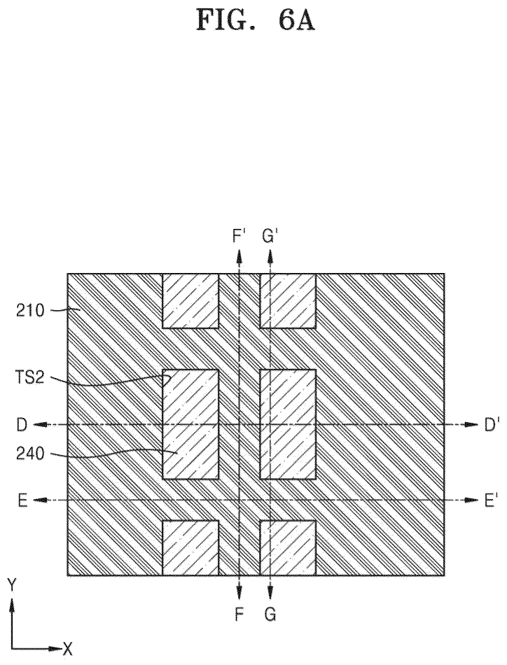

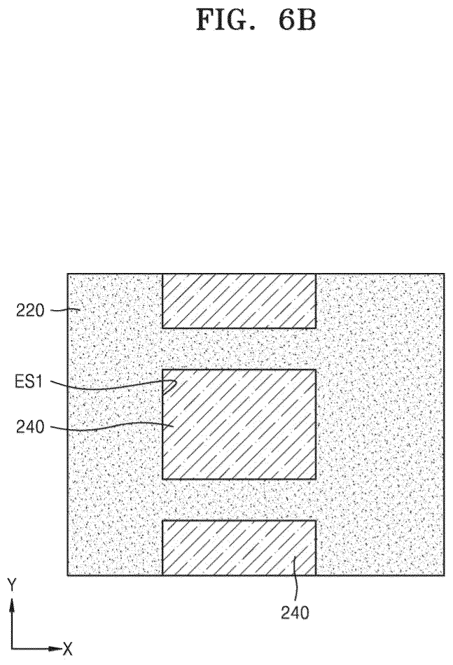

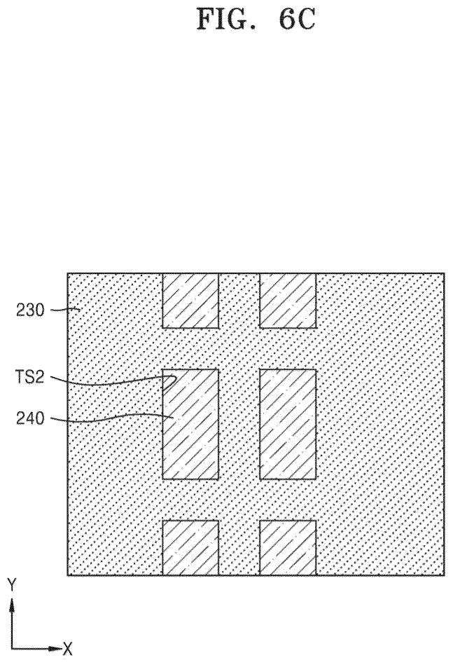

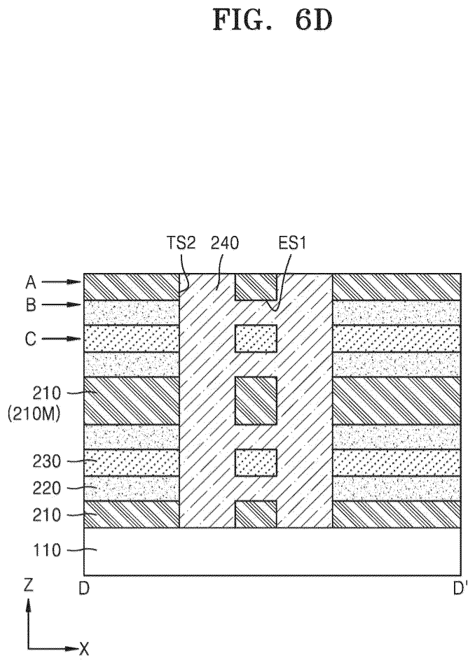

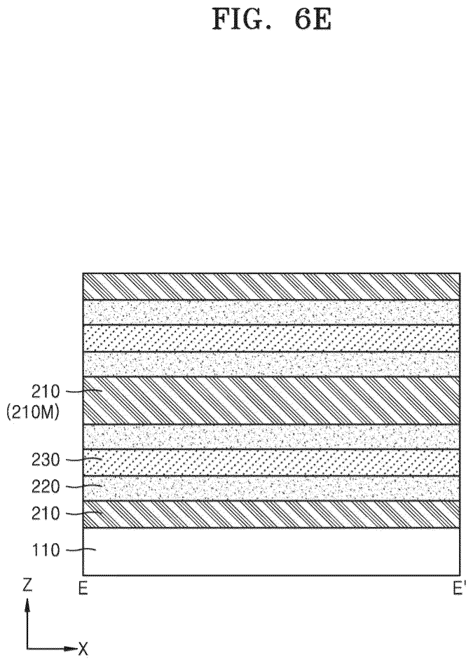

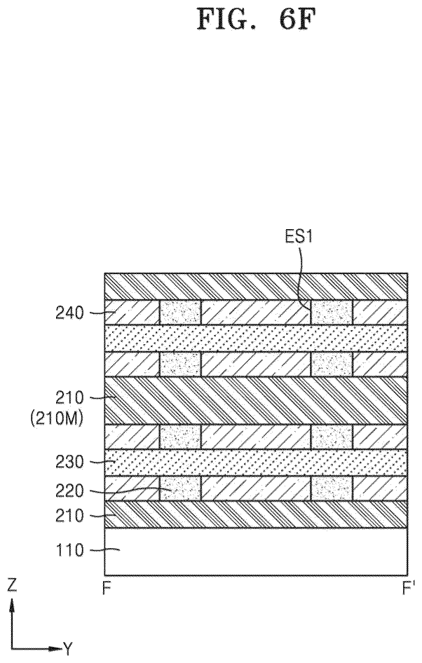

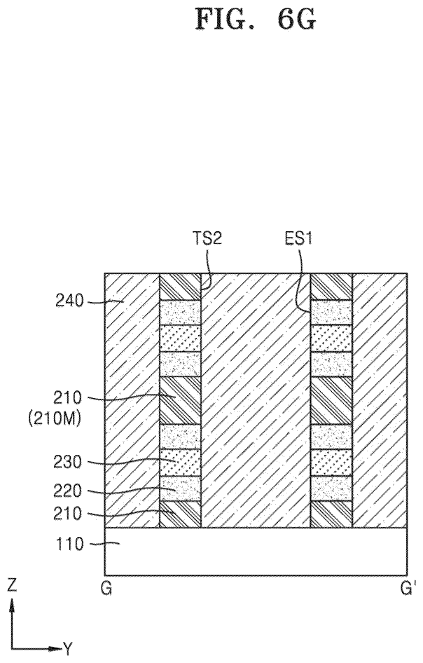

Referring to FIGS. 6A to 6G together, a sacrificial layer 240 is provided to fill the plurality of second trim spaces TS2 and the plurality of first expansion spaces ES1. The sacrificial layer 240 may fill all of the plurality of second trim spaces TS2 and the plurality of first expansion spaces ES1.

The sacrificial layer 240 may include a semiconductor material. The sacrificial layer 240 may include a semiconductor material having an etch selectivity with respect to the semiconductor layer 220. For example, the sacrificial layer 240 and the semiconductor layer 220 may be etched using difference etch recipes. In some example embodiments, the sacrificial layer 240 may have an etch selectivity with respect to the substrate 110. For example, the sacrificial layer 240 and the substrate 110 may be etched using difference etch recipes. In some example embodiments, for example, when each of the plurality of semiconductor layers 220 includes Si, the sacrificial layer 240 may include SiGe.

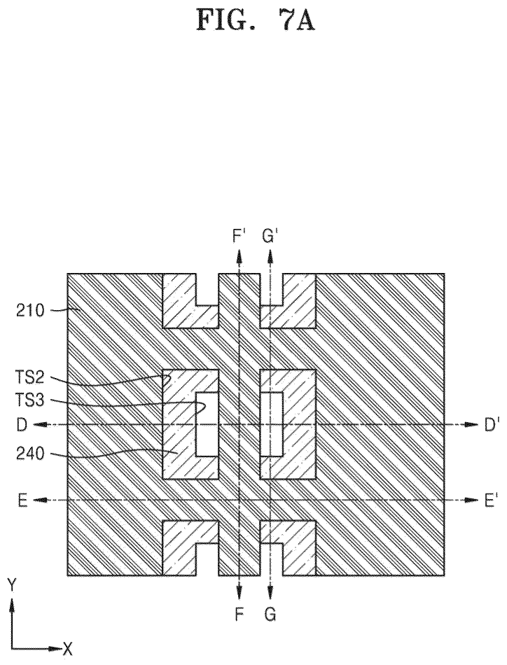

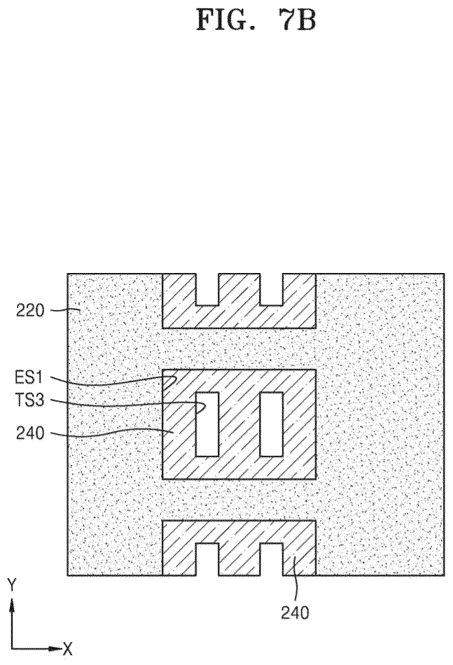

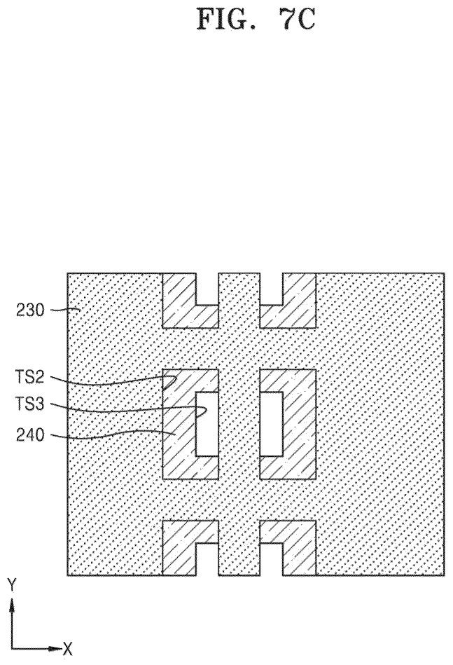

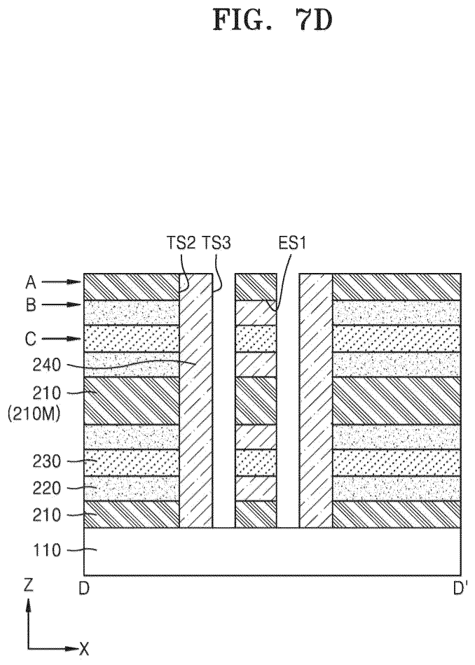

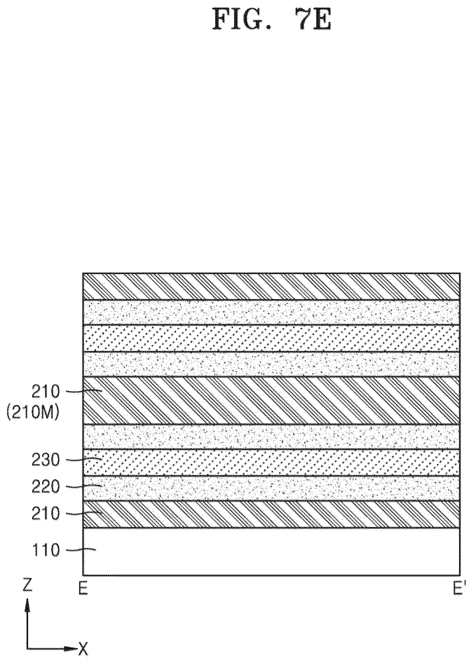

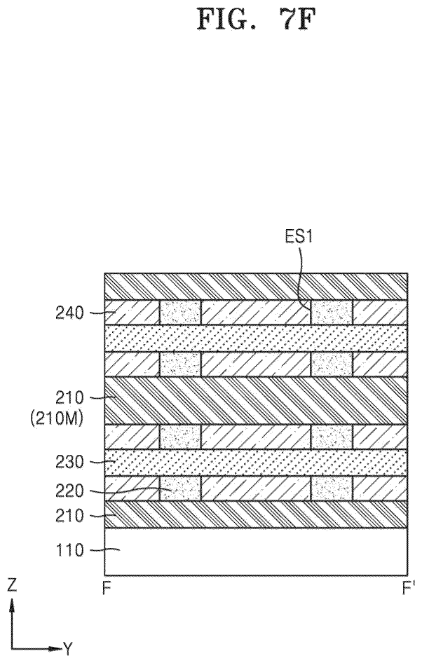

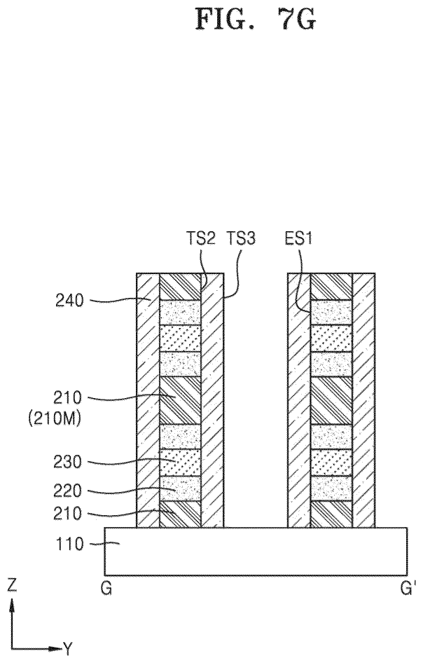

Referring to FIGS. 7A to 7G, portions of the sacrificial layer 240 are removed to form a plurality of third trim spaces TS3. Portions of the sacrificial layer 240 located in regions adjacent to each of the two second trim spaces TS2 adjacent to each other in the first horizontal direction (X direction) in a plan view may be removed to form the plurality of third trim spaces TS3.

In each of the first horizontal direction (X direction) and the second horizontal direction (Y direction), the horizontal width of each of the plurality of third trim spaces TS3 may be less than the horizontal width of each of the plurality of second trim spaces TS2. For example, in a plan view, the sacrificial layer 240 may be exposed from three edges, other than each of edges facing each other, among the four edges of each of the two third trim spaces TS3 adjacent to each other in the first horizontal direction (X direction).

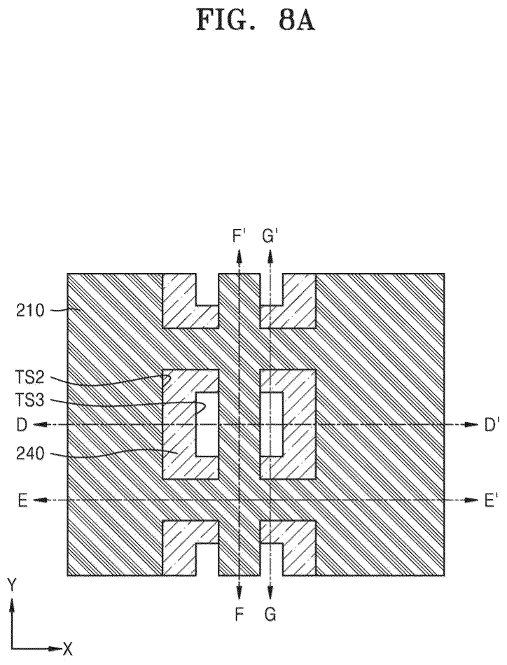

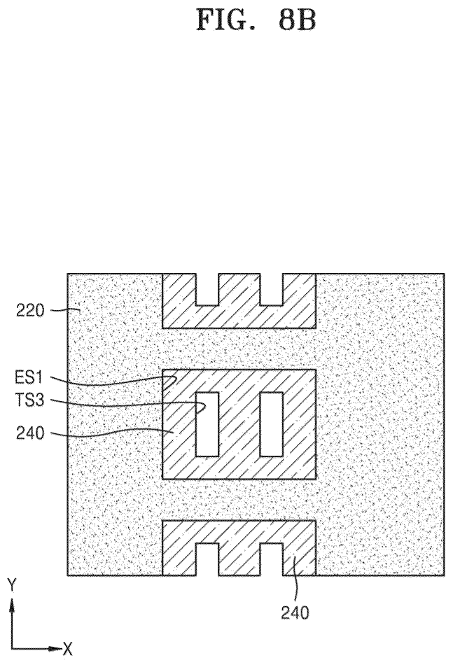

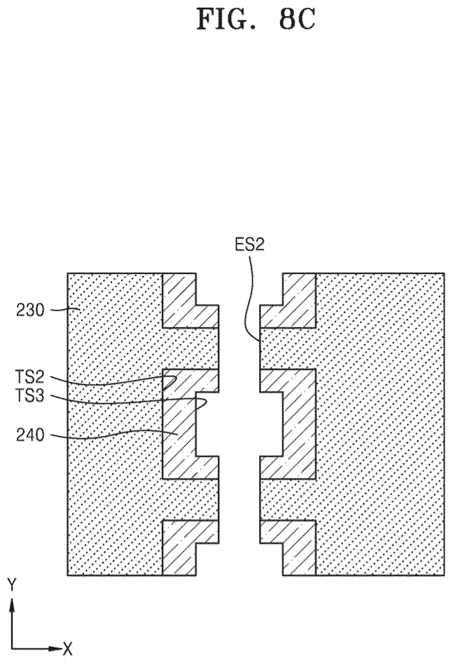

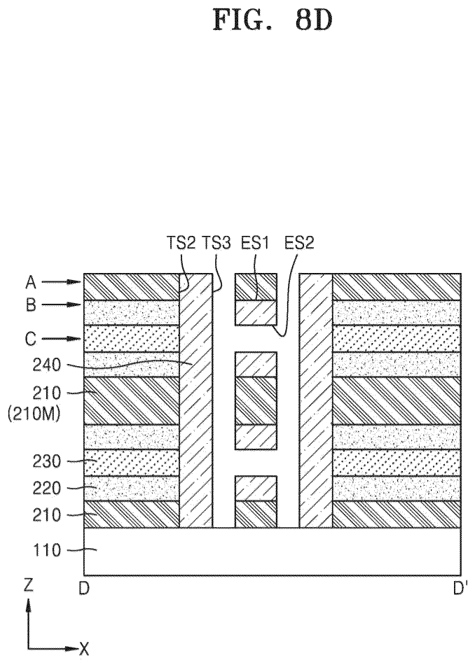

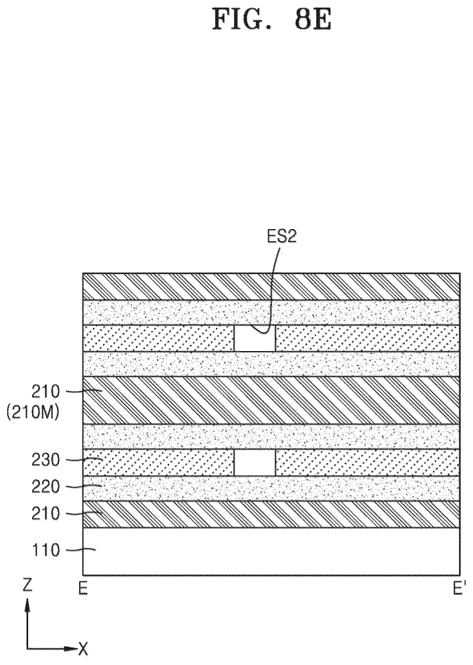

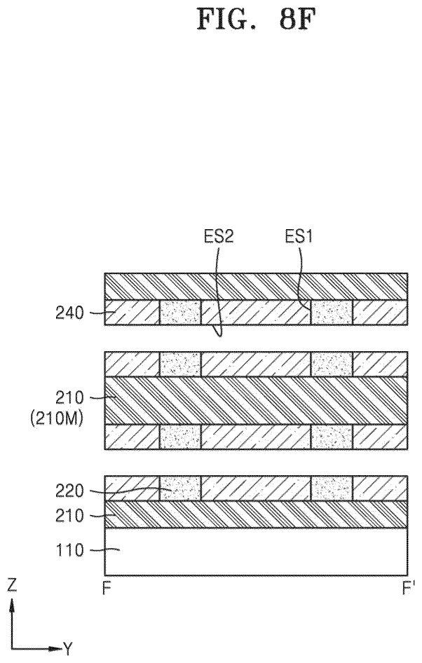

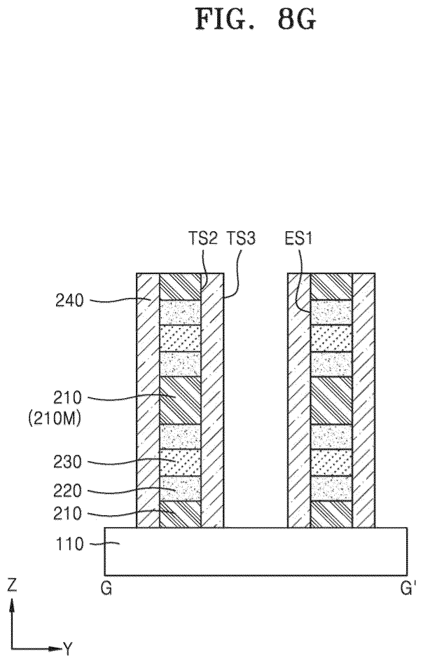

Referring to FIGS. 8A to 8G together, a portion of each of the plurality of second insulating layers 230 is removed through the plurality of third trim spaces TS3 to form a plurality of second expansion spaces ES2. For example, the portion of each of the plurality of second insulating layers 230 may be removed through an etching operation. In a plan view, each of the plurality of second expansion spaces ES2 may extend in the second horizontal direction (Y direction). For example, the second expansion space ES2 may extend, in the second horizontal direction (Y direction), between two second trim spaces TS2 adjacent to each other or between two third trim spaces TS3 adjacent to each other in the first horizontal direction (X direction) in a plan view.

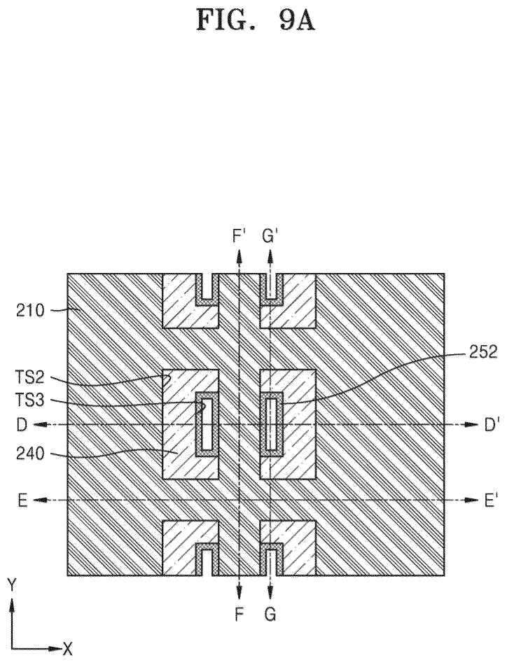

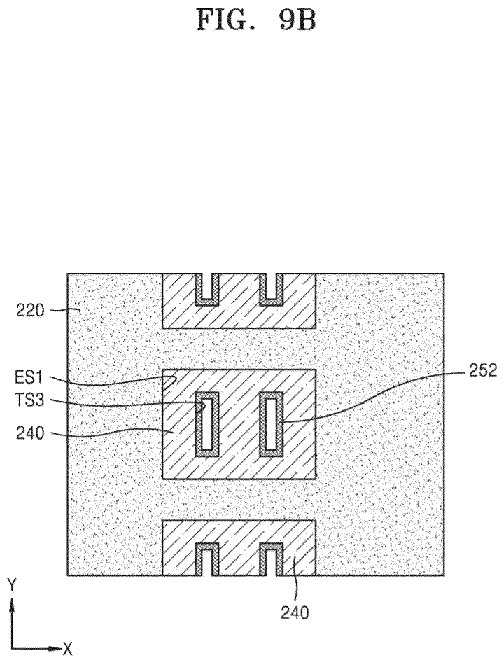

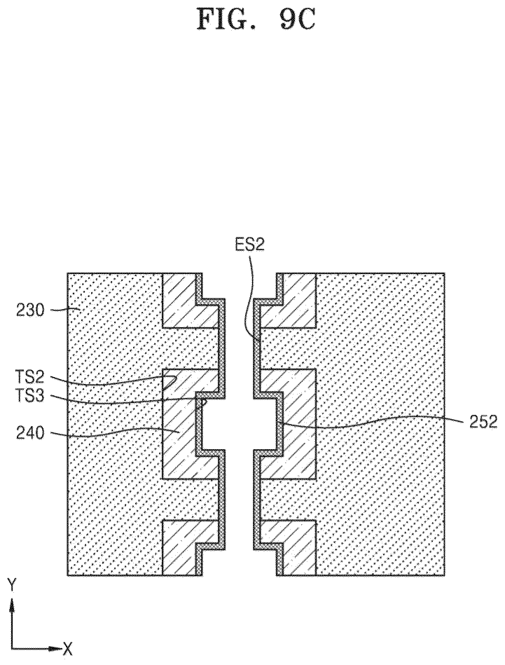

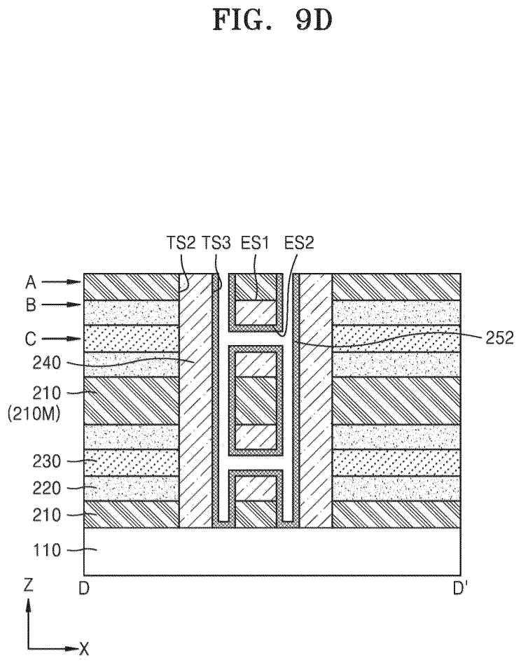

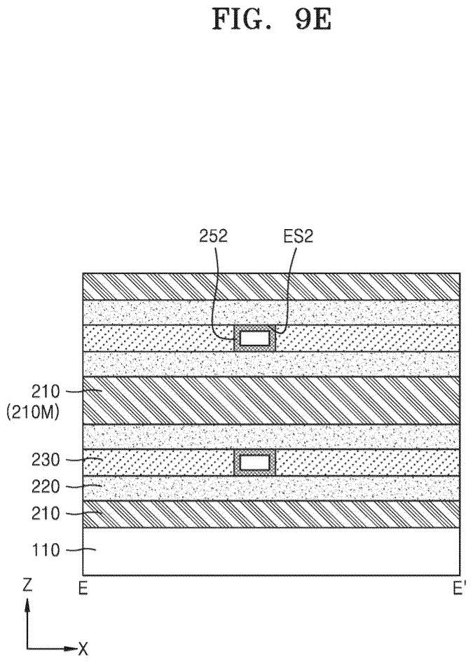

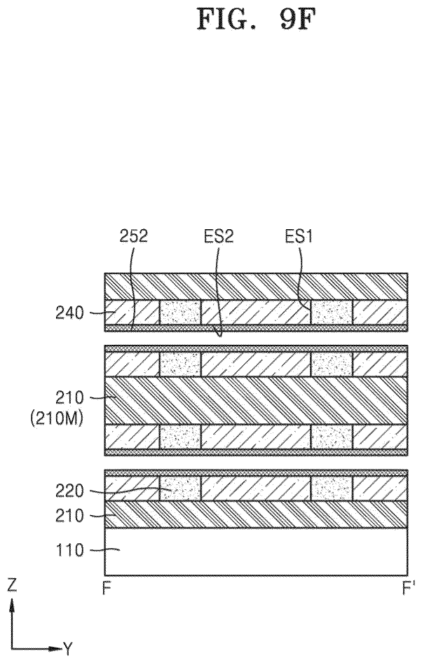

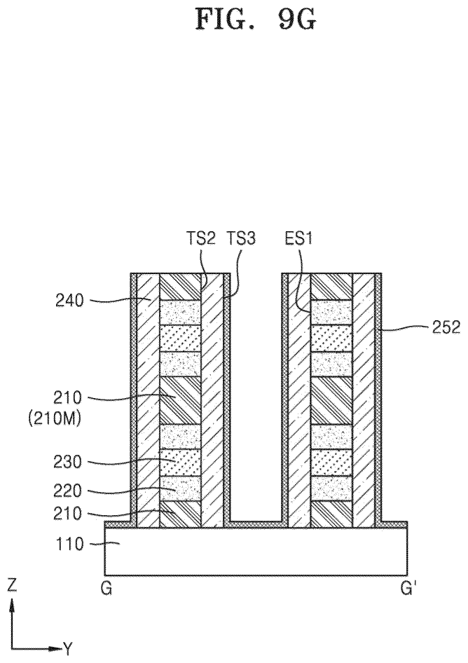

Referring to FIGS. 9A to 9G together, a back gate dielectric film 252 is formed covering each surface of the first insulating layer 210, the semiconductor layer 220, the second insulating layer 230, and the sacrificial layer 240, which are exposed in the plurality of second expansion spaces ES2 and the plurality of third trim spaces TS3.

The back gate dielectric film 252 may include at least one selected from a group consisting of silicon oxide, a high-k dielectric material having a higher dielectric constant than silicon oxide, and a ferroelectric material. In some example embodiments, the back gate dielectric film 252 may have a stack structure of a first dielectric film including silicon oxide and a second dielectric film including at least one selected from a group consisting of a high dielectric material and a ferroelectric material. For example, the high-k dielectric material and the ferroelectric material may include at least one selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

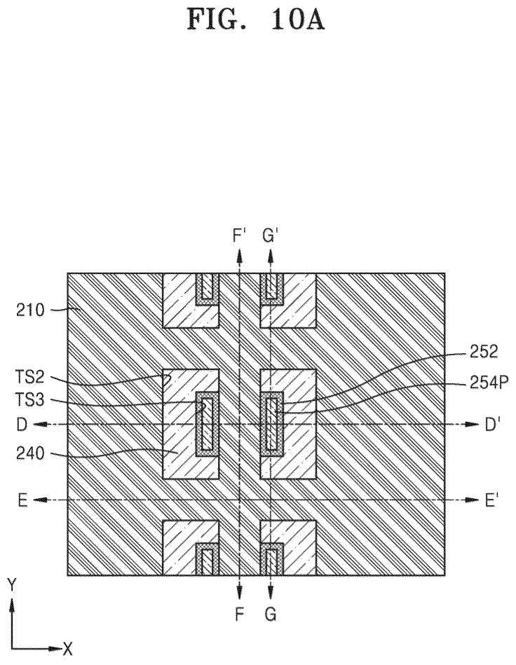

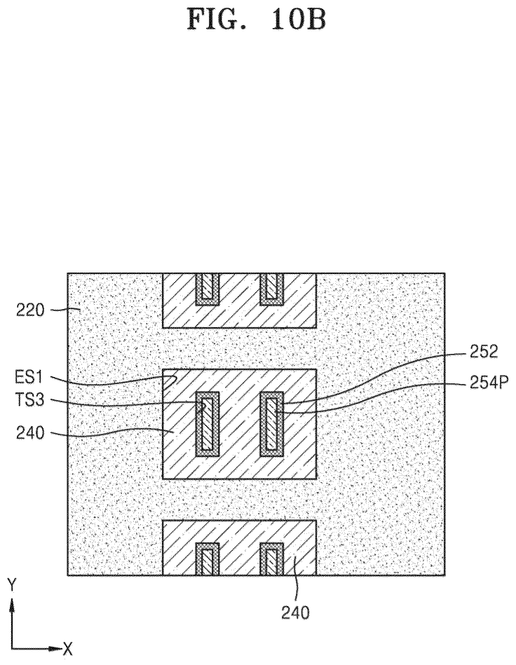

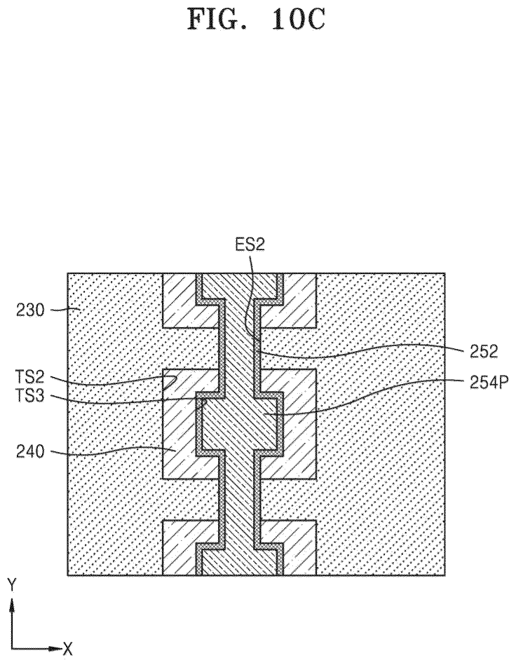

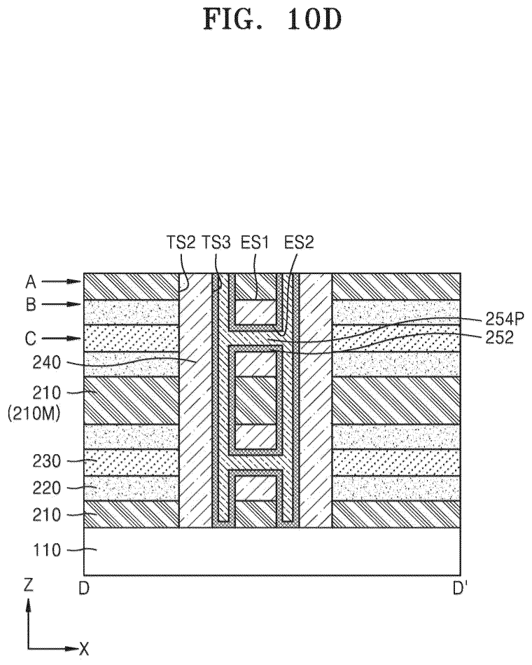

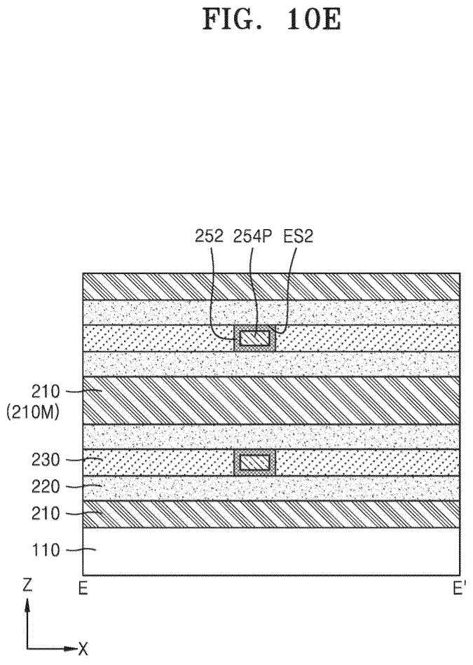

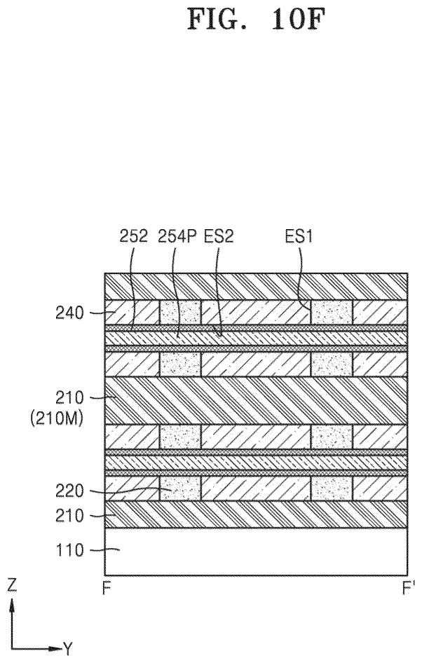

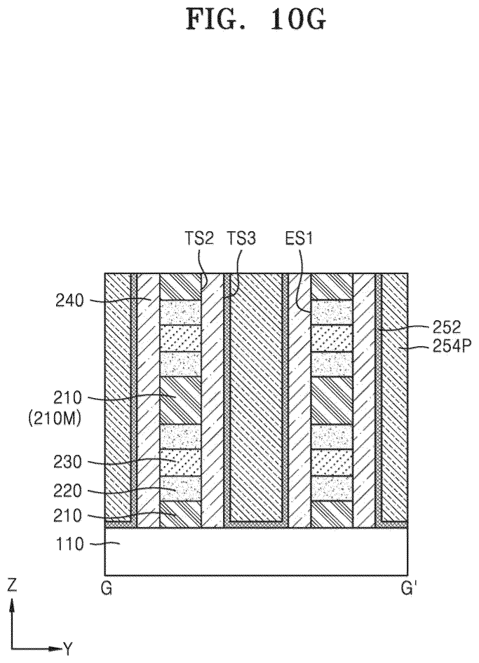

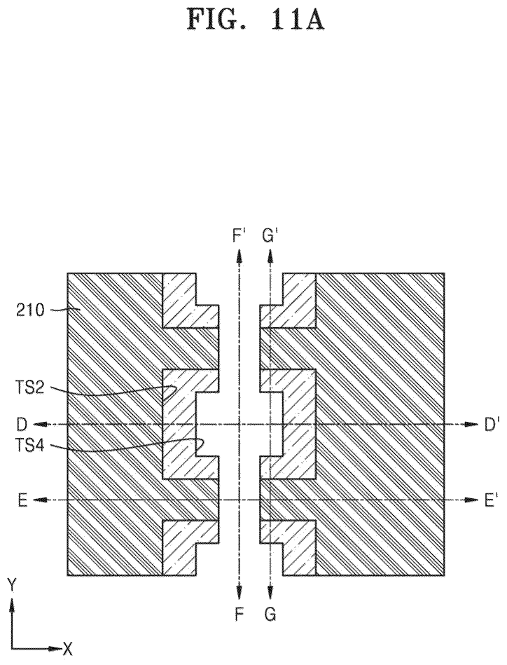

Referring to FIGS. 10A to 10G together, a back gate material layer 254P is provided to cover the back gate dielectric film 252 and fill the plurality of second expansion spaces ES2 and the plurality of third trim spaces TS3.

In some example embodiments, the back gate material layer 254P may include a conductive barrier film covering the back gate dielectric film 252 and a conductive filling layer covering the conductive barrier film. The conductive barrier film may include, for example, metal, conductive metal nitride, conductive metal silicide, or a combination thereof. For example, the conductive barrier film may include TiN. The conductive filling layer may include, for example, doped silicon, Ru, RuO, Pt, PtO, Ir, IrO, SRO(SrRuO), BSRO((Ba,Sr) RuO), CRO(CaRuO), BaRuO, La(Sr, Co)O, Ti, TiN, W, WN, Ta, TaN, TiAlN, TiSİN, TaAlN, TaSiN, or a combination thereof. In some example embodiments, the conductive filling layer may include W.

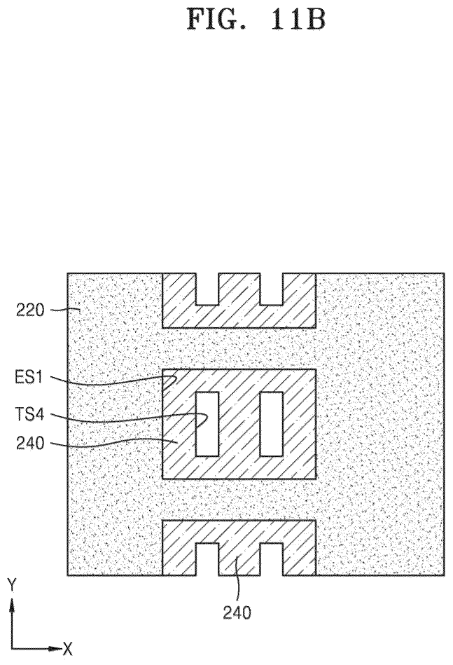

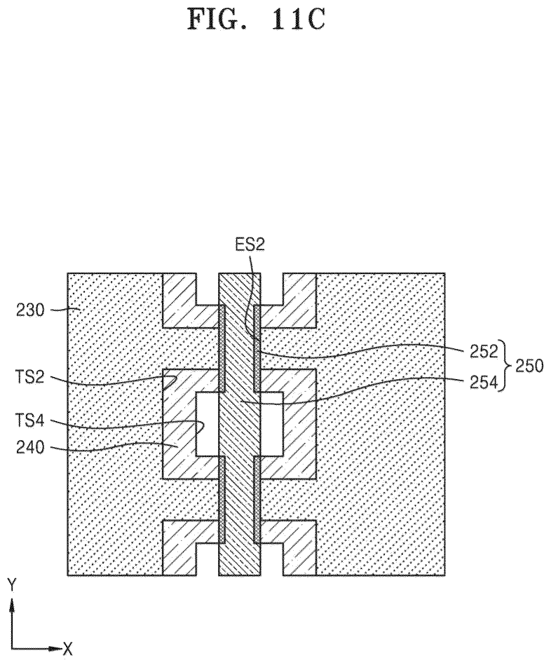

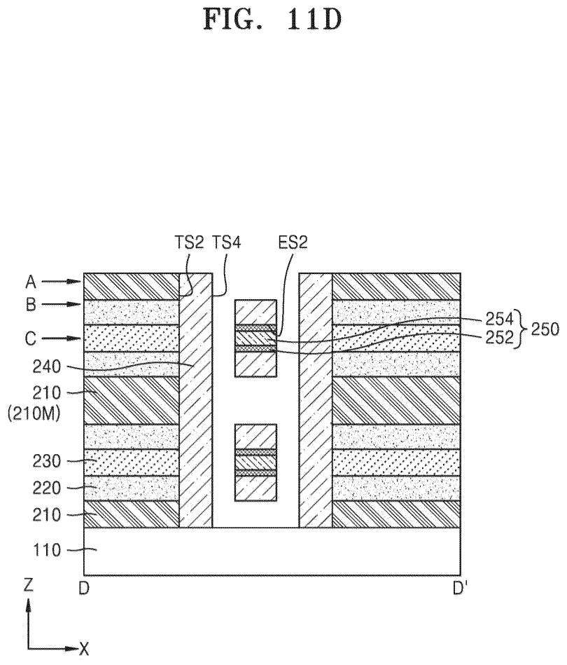

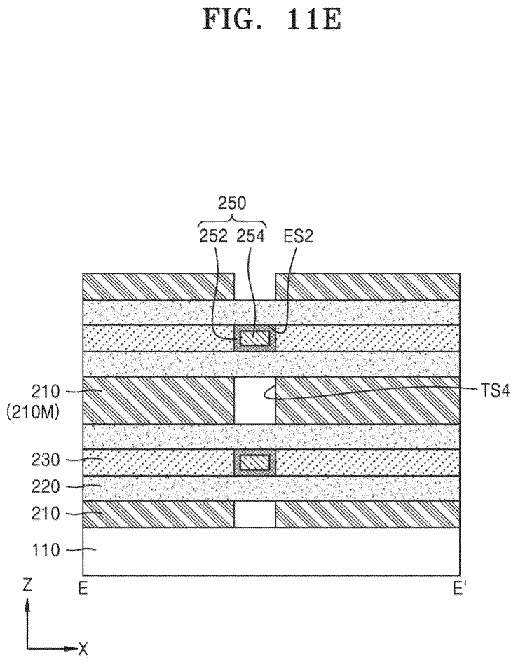

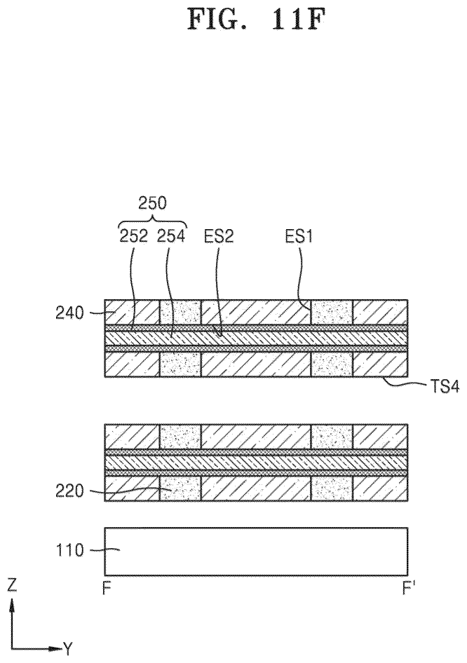

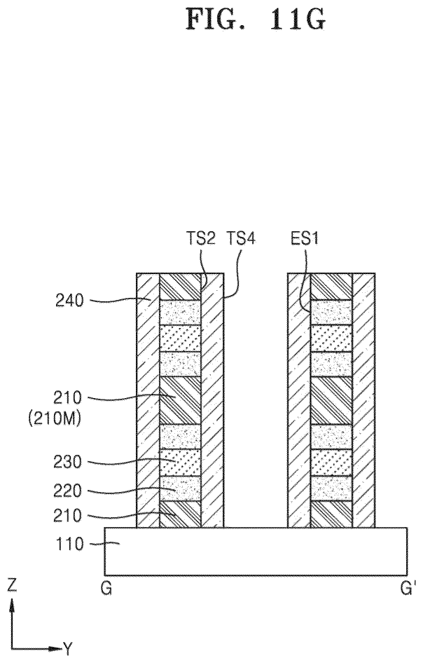

Referring to FIGS. 10A to 10G and FIGS. 11A to 11G together, a portion of the back gate dielectric film 252 and a portion of the back gate material layer 254P filling the plurality of third trim spaces TS3 are removed, and a portion of the first insulating layer 210 that overlaps the plurality of second expansion spaces ES2 in the vertical direction (Z direction) is removed, thereby forming a fourth trim space TS4. For example, the portion of the back gate dielectric film 252 and the portion of the back gate material layer 254P may be removed through an etching operation. The fourth trim space TS4 may correspond to a space, in which a portion of the first insulating layer 210 that overlaps the plurality of second expansion spaces ES2 in the vertical direction (Z direction) is removed, and the plurality of third trim spaces TS3.

The remaining portions of the back gate dielectric film 252 and the back gate material layer 254P may form the back gate dielectric film 252 and a back gate electrode film 254, respectively, which fill the plurality of second expansion spaces ES2. That is, portions, filling the plurality of third trim spaces TS3, of the back gate dielectric film 252 and the back gate material layer 254P shown in FIGS. 10A to 10G are removed, and thus, the back gate dielectric film 252 and the back gate electrode film 254, filling each of the plurality of second expansion spaces ES2, may remain. The back gate dielectric film 252 and the back gate electrode film 254 may constitute a back gate structure 250. A plurality of back gate structures 250 may extend in the second horizontal direction (Y direction) and be spaced apart from each other in the vertical direction (Z direction). The back gate electrode film 254 may correspond to the back gate line BG shown in FIG. 1.

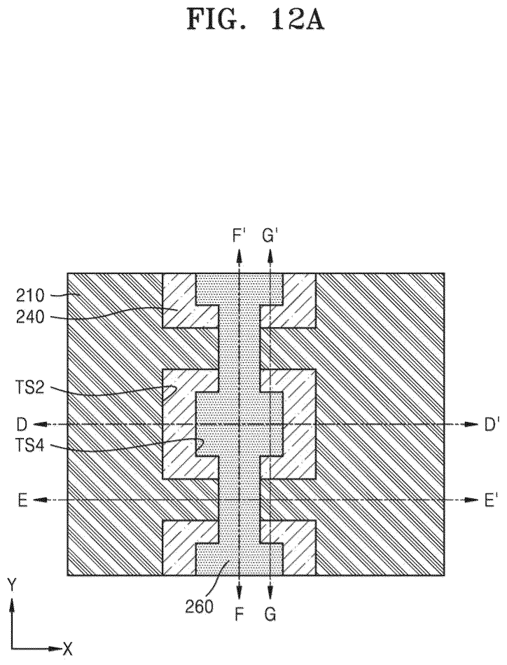

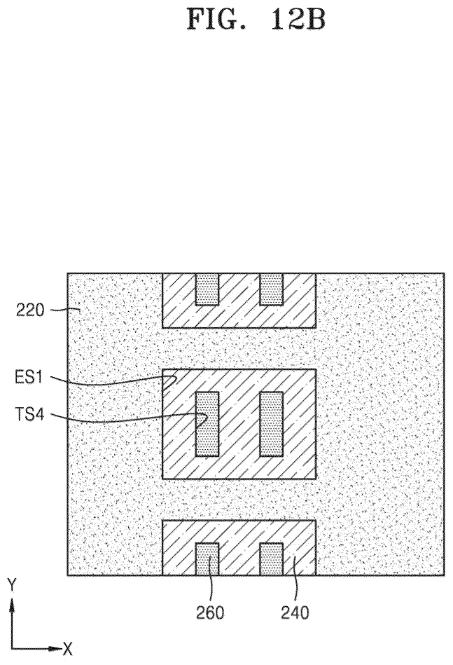

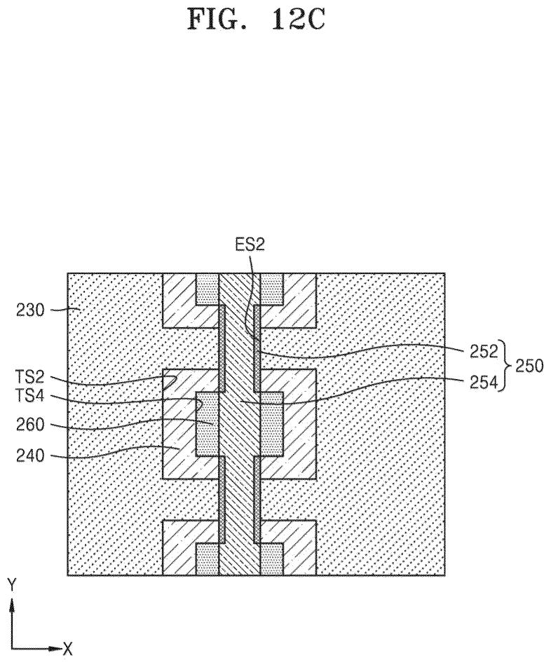

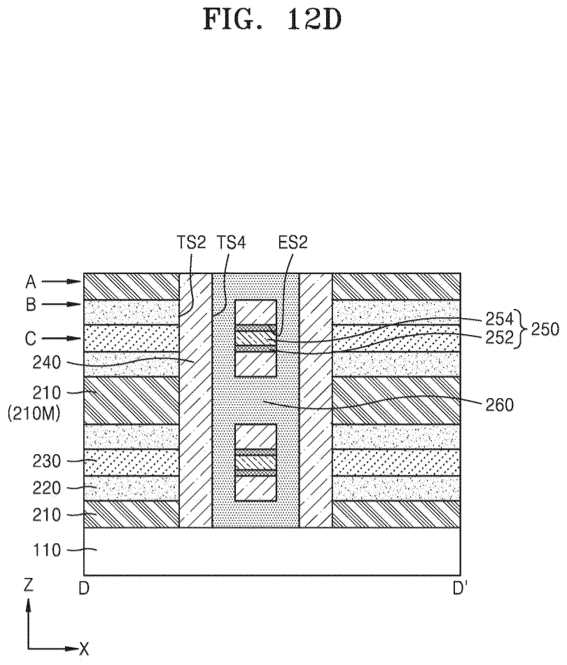

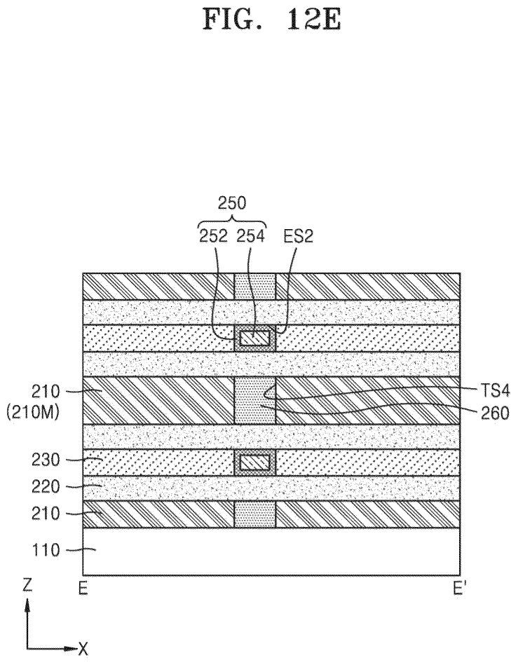

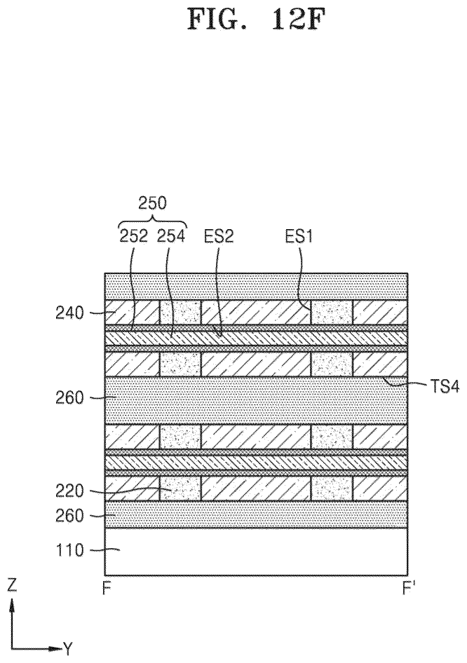

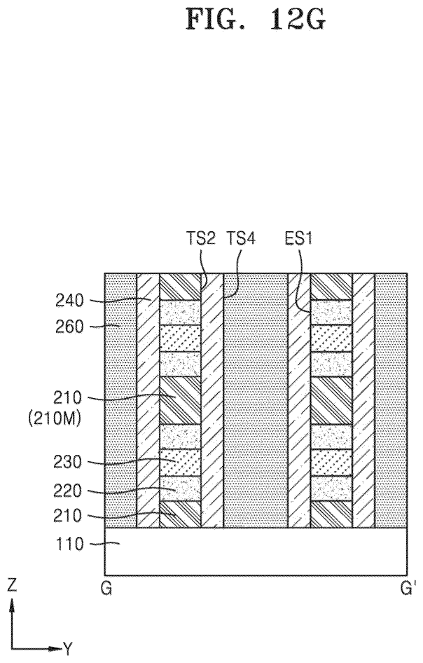

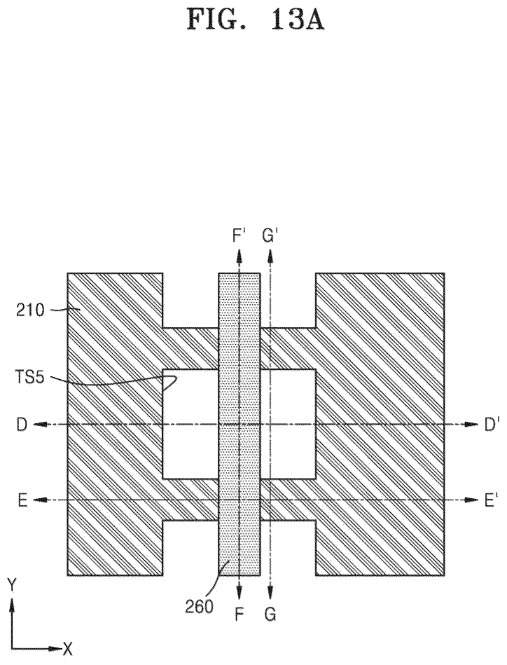

Referring to FIGS. 12A to 12G together, a first filling insulating layer 260 is provided to fill the fourth trim space TS4. The first filling insulating layer 260 may include oxide. For example, the first filling insulating layer 260 may include silicon oxide.

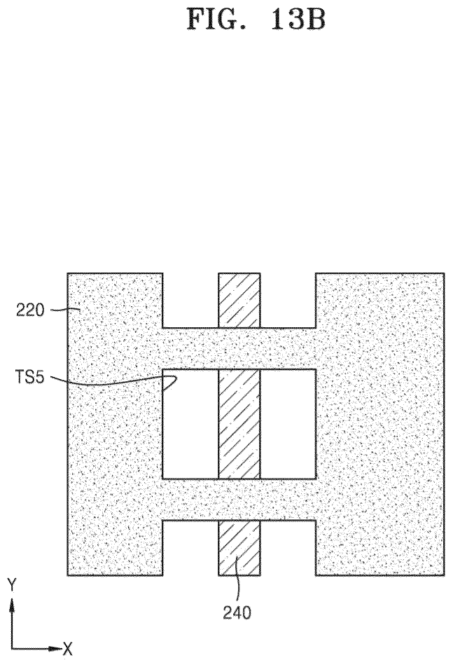

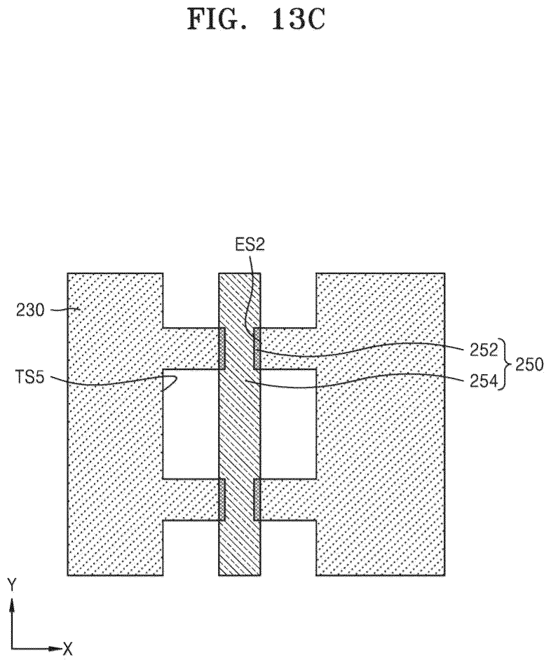

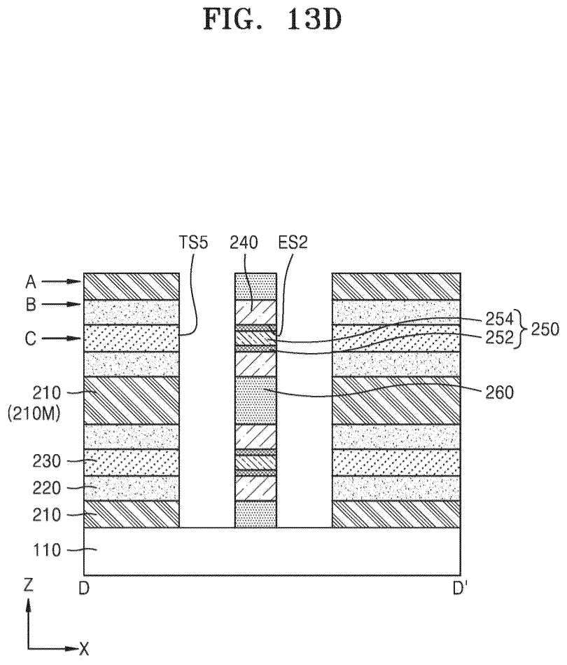

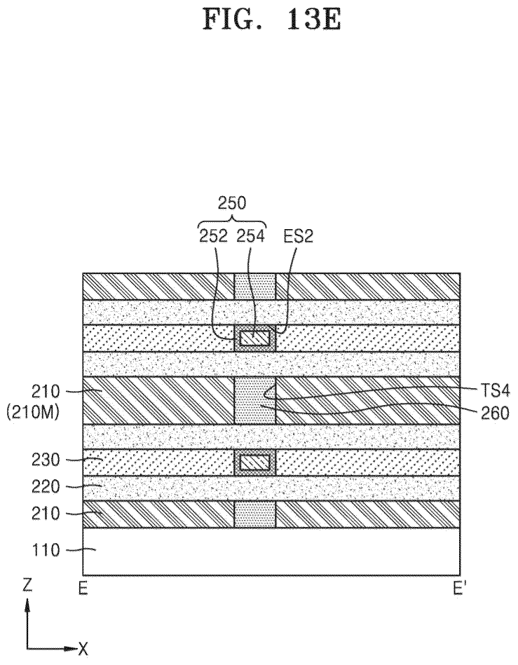

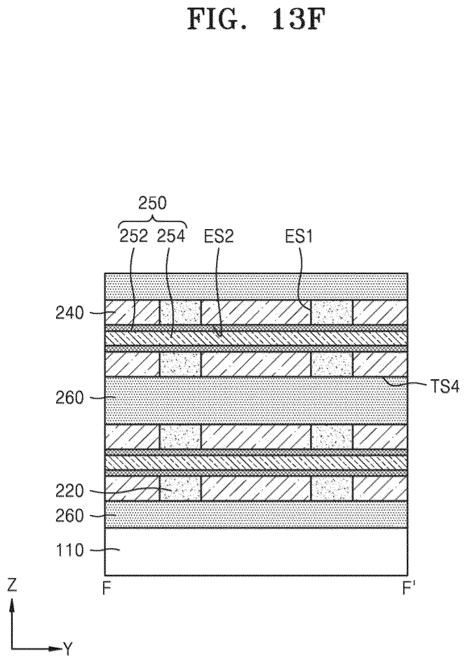

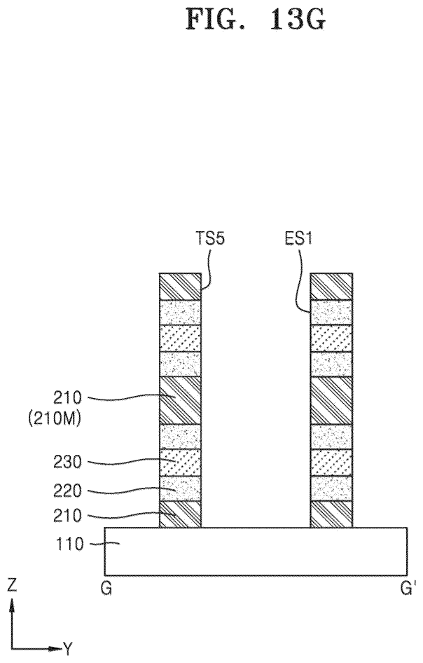

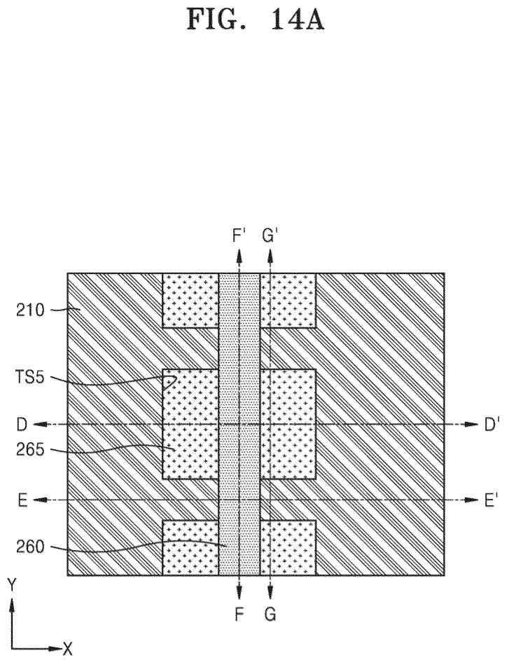

Referring to FIGS. 13A to 13G together, a portion of the sacrificial layer 240 and a portion of the first filling insulating layer 260 are removed to form a plurality of fifth trim spaces TS5. For example, the portion of the sacrificial layer 240 and the portion of the first filling insulating layer 260 may be removed through an etching operation. The plurality of fifth trim spaces TS5 may overlap the plurality of second trim spaces TS2 shown in FIGS. 5A to 5G in a plan view. For example, the plurality of fifth trim spaces TS5 may be formed by removing a portion of the sacrificial layer 240 and a portion of the first filling insulating layer 260, which do not overlap the second expansion space ES2 in the vertical direction (Z direction). That is, the plurality of fifth trim spaces TS5 may be formed by removing a portion of the sacrificial layer 240 and a portion of the first filling insulating layer 260, which do not overlap the plurality of back gate structures 250 in the vertical direction (Z direction).

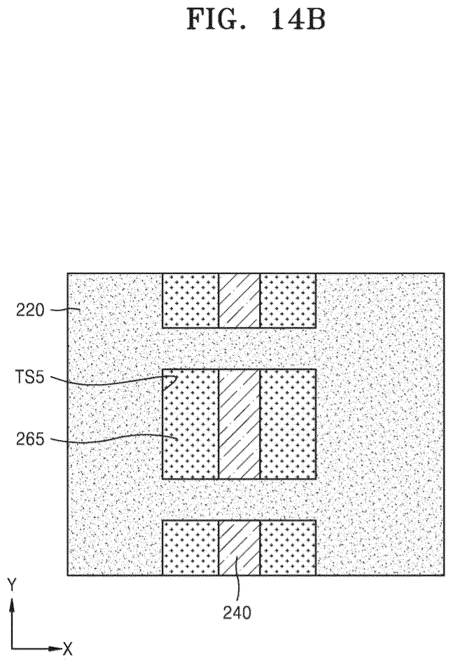

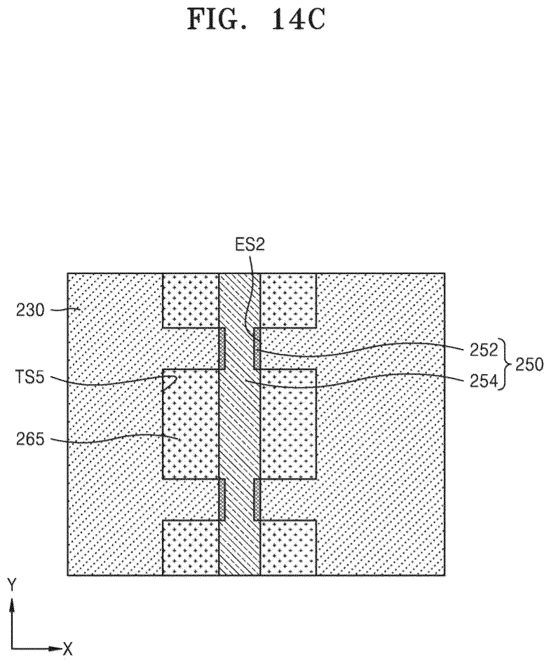

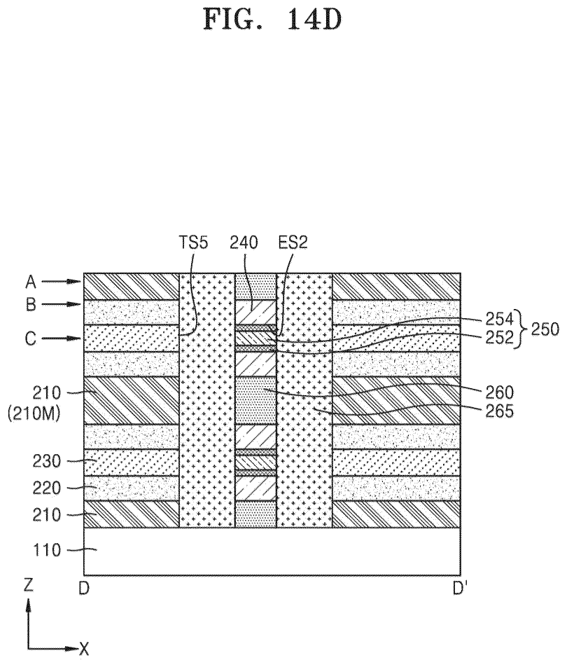

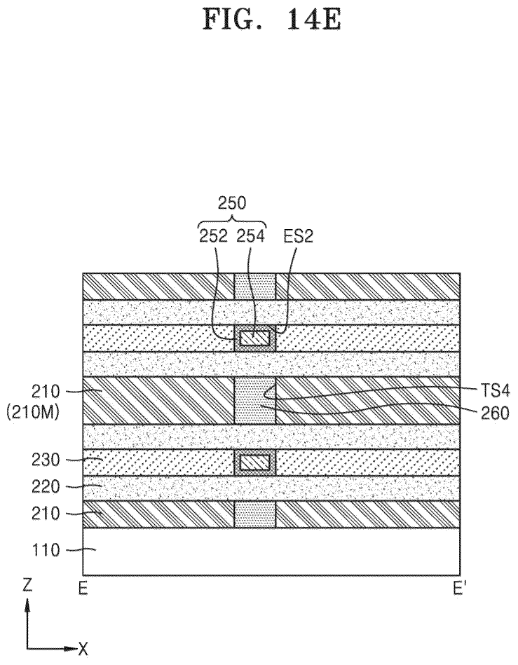

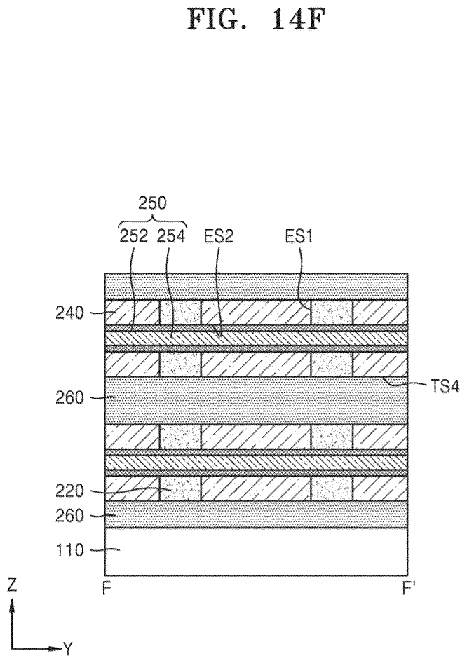

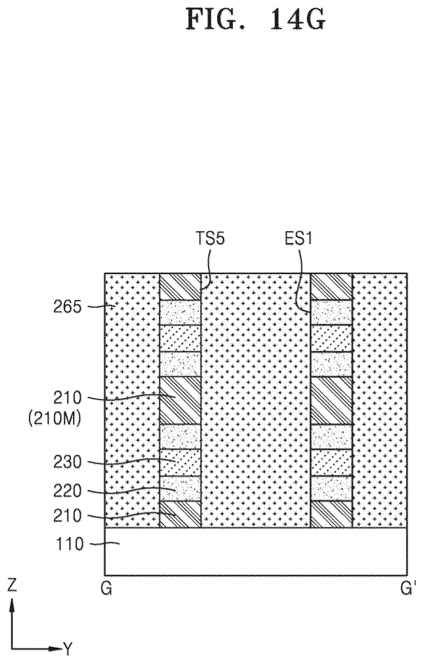

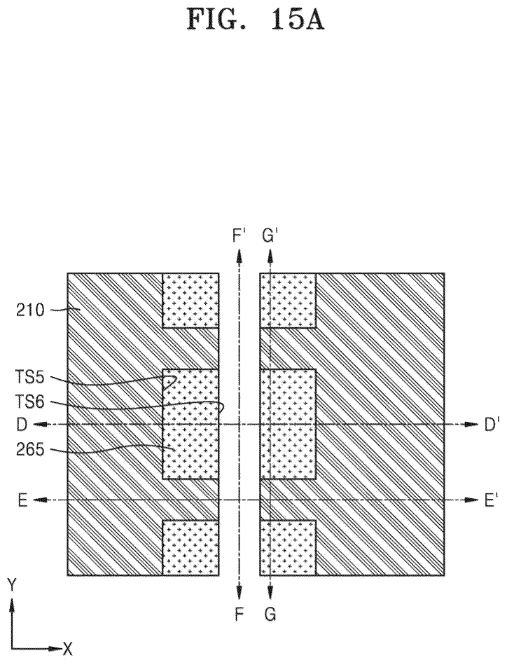

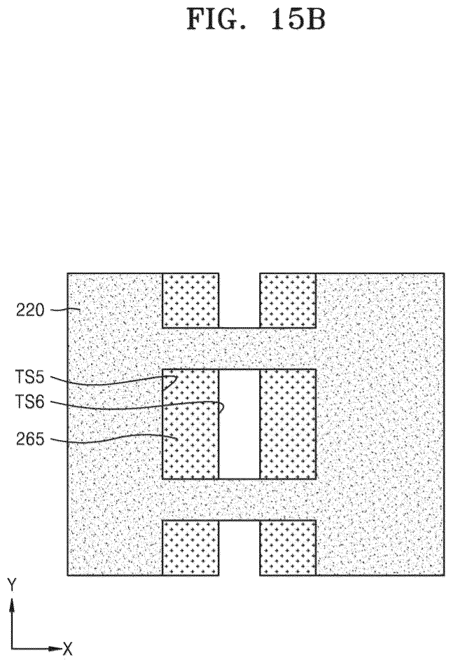

Referring to FIGS. 14A to 14G together, a plurality of second filling insulating layers 265 are provided to fill the plurality of fifth trim spaces TS5. Each of the second filling insulating layers 265 may include nitride. For example, the second filling insulating layer 265 may include silicon nitride.

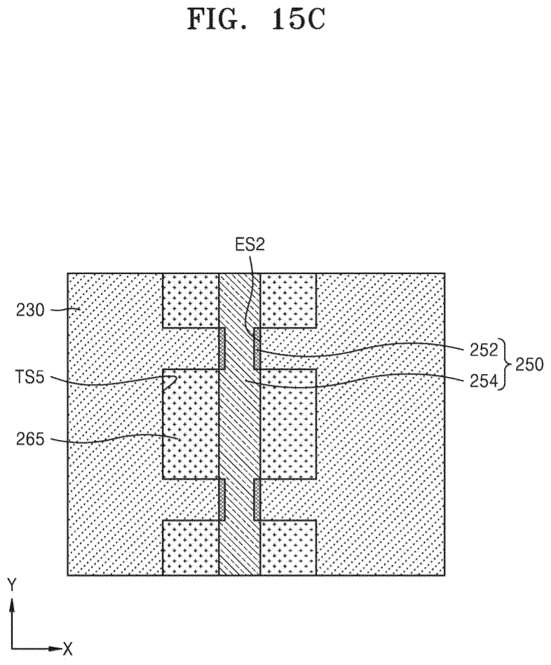

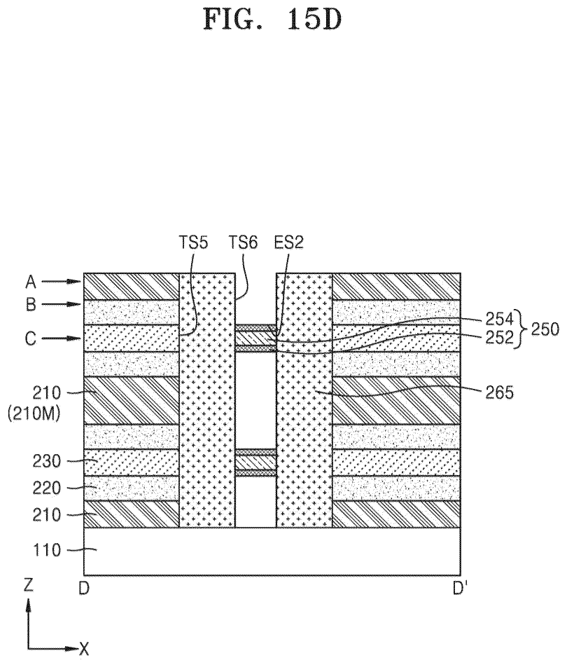

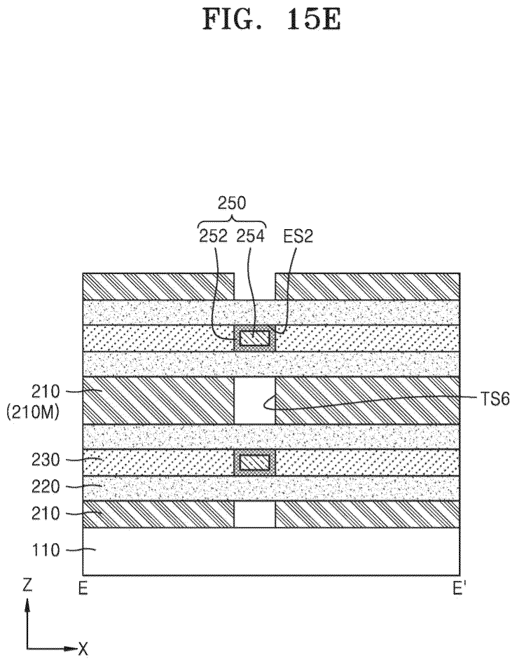

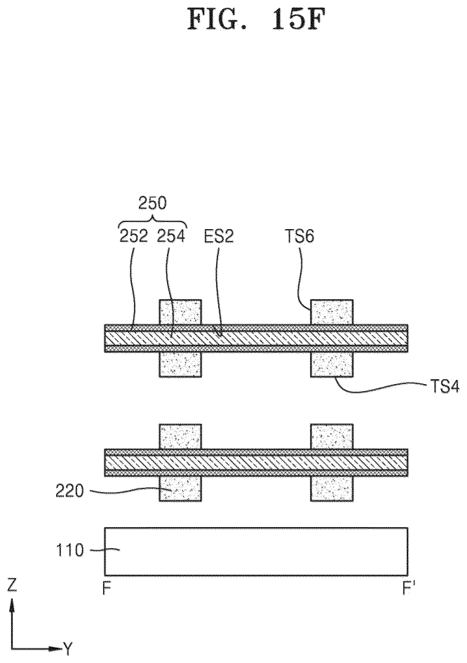

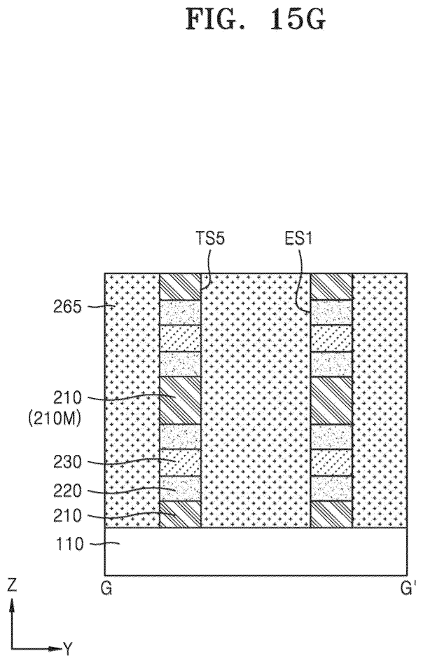

Referring to FIGS. 15A to 15G, the sacrificial layer 240 and the first filling insulating layer 260 are removed to form a plurality of sixth trim spaces TS6. For example, the sacrificial layer 240 and the first filling insulating layer 260 may be removed through an etching operation. The plurality of sixth trim spaces TS6 may overlap the plurality of second expansion spaces ES2 in the vertical direction (Z direction). The plurality of sixth trim spaces TS6 may overlap the plurality of back gate structures 250 in the vertical direction (Z direction).

Between two sixth trim spaces TS6 adjacent to each other in the vertical direction (Z direction), the back gate structure 250 may be located, or the back gate structure 250 and two semiconductor layers 220 covering the top and bottom of the back gate structure 250 may be arranged.

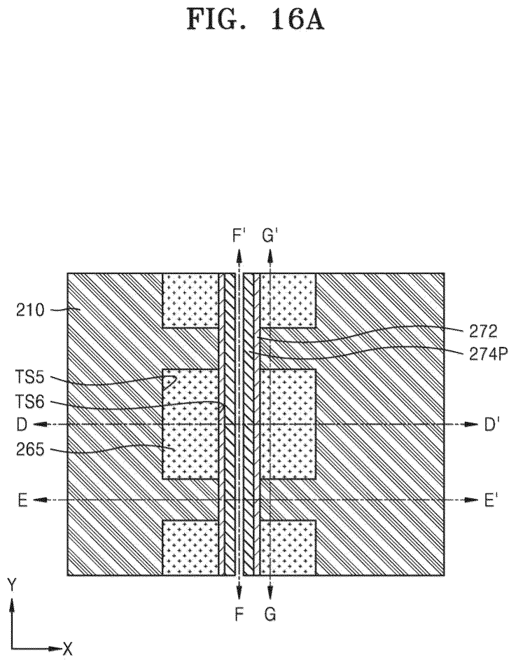

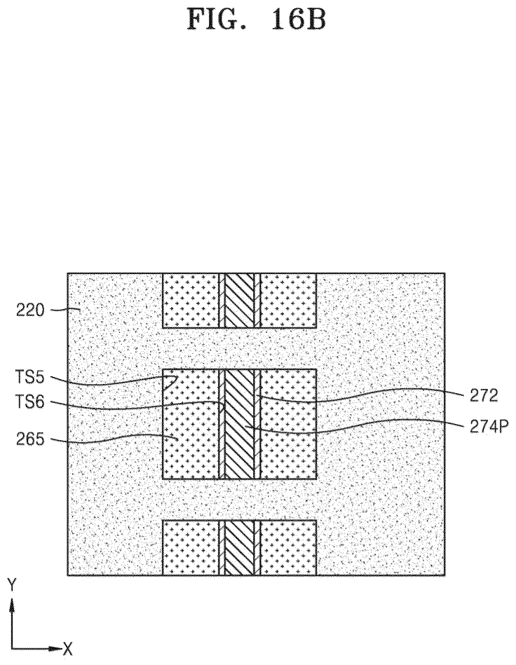

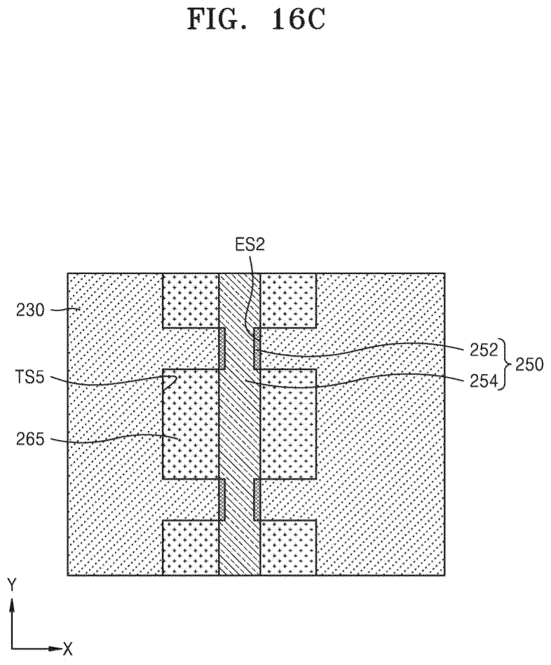

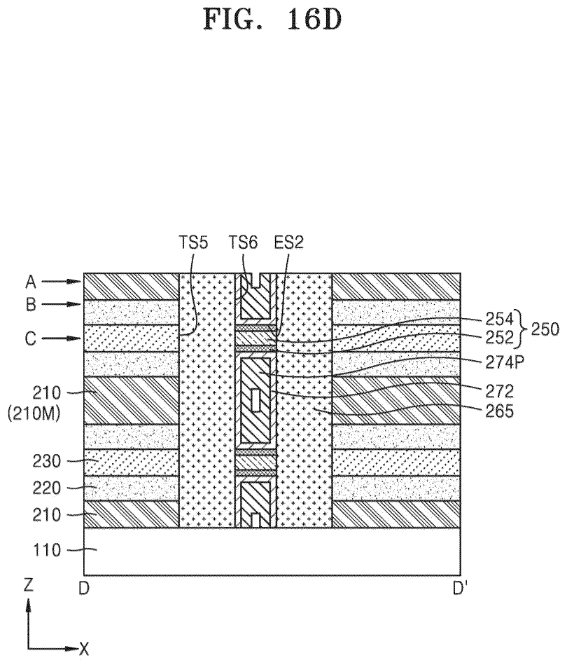

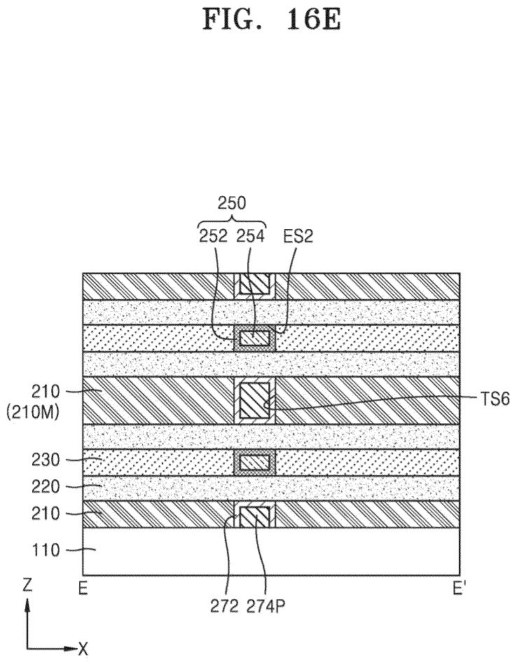

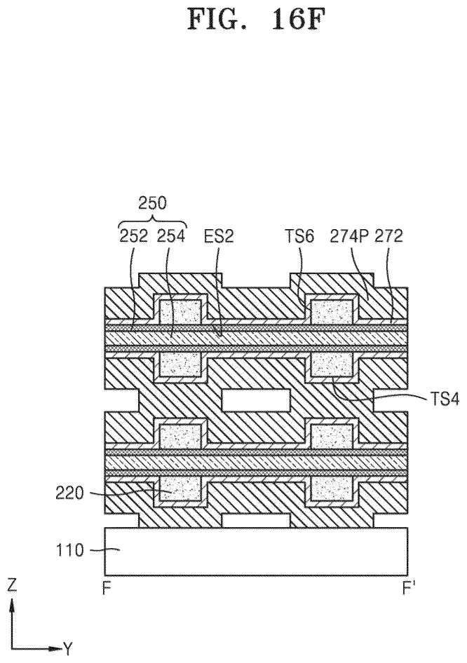

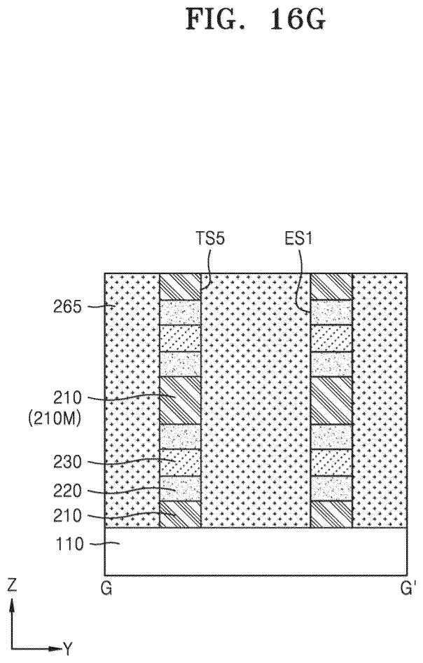

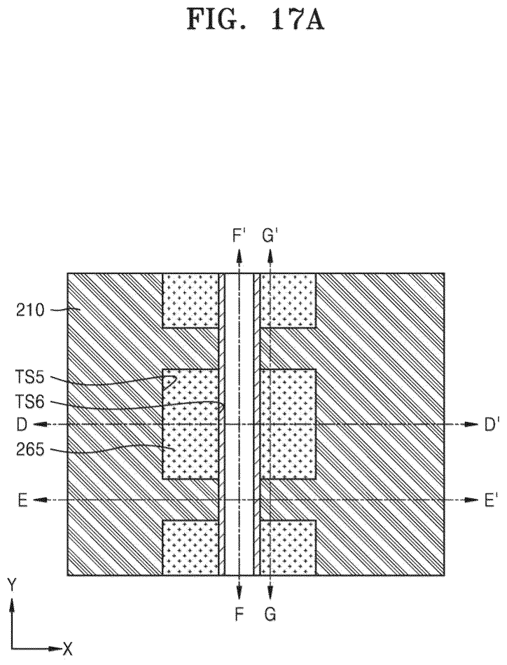

Referring to FIGS. 16A to 16G together, a gate dielectric film 272 is provided to cover the surface exposed in each of the plurality of fourth trim spaces TS4 and the plurality of sixth trim spaces TS6, and a gate material layer 274P is provided to cover the gate dielectric film 272. The gate dielectric film 272 may conformally cover surfaces of each of the first insulating layer 210, the semiconductor layer 220, the back gate dielectric film 252, and the second filling insulating layer 265, which are exposed in the plurality of fourth trim spaces TS4 and sixth trim spaces TS6. In some example embodiments, the gate material layer 274P may fill portions of the plurality of fourth trim spaces TS4 and the sixth trim spaces TS6 but may not completely fill the sixth trim spaces TS6.

The gate dielectric film 272 may include at least one selected from a group consisting of silicon oxide, a high-k dielectric material having a higher dielectric constant than silicon oxide, and a ferroelectric material. In some example embodiments, the gate dielectric film 272 may have a stack structure of a first dielectric film including silicon oxide and a second dielectric film including at least one selected from a group consisting of a high dielectric material and a ferroelectric material. For example, the high-k dielectric material and the ferroelectric material may include at least one selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In some example embodiments, the gate material layer 274P may include a conductive barrier film covering the gate dielectric film 272 and a conductive filling layer covering the conductive barrier film. The conductive barrier film may include, for example, metal, conductive metal nitride, conductive metal silicide, or a combination thereof. For example, the conductive barrier film may include TiN. The conductive filling layer may include, for example, doped silicon, Ru, RuO, Pt, PtO, Ir, IrO, SRO (SrRuO), BSRO((Ba,Sr) RuO), CRO (CaRuO), BaRuO, La (Sr, Co)O, Ti, TiN, W, WN, Ta, TaN, TiAlN, TiSiN, TaAlN, TaSiN, or a combination thereof. In some example embodiments, the conductive filling layer may include W.

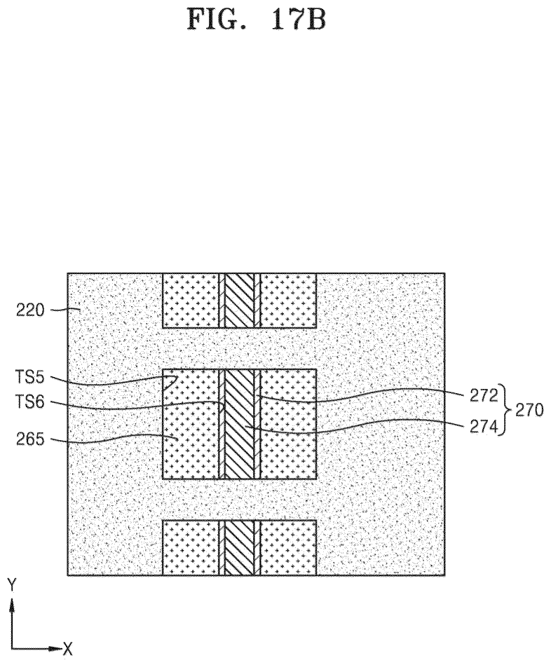

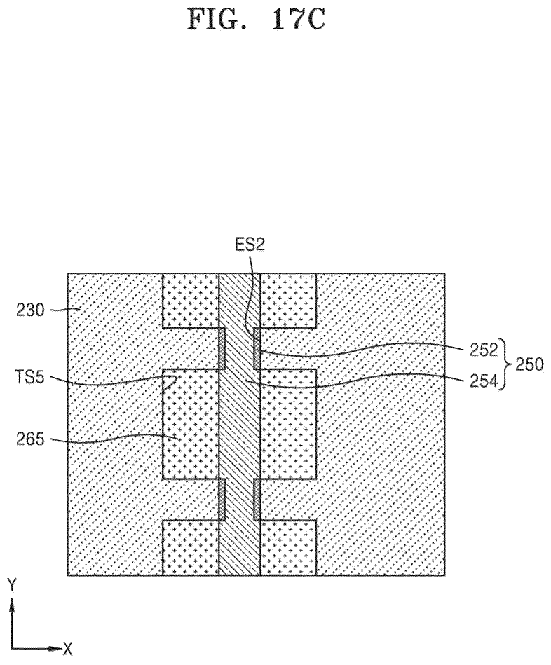

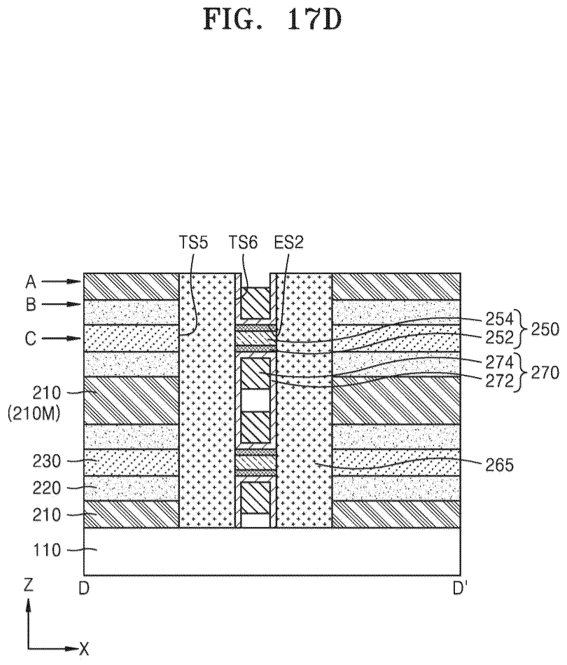

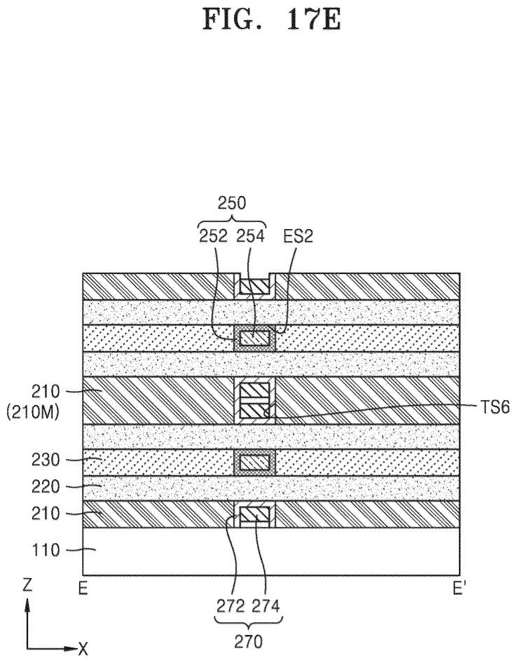

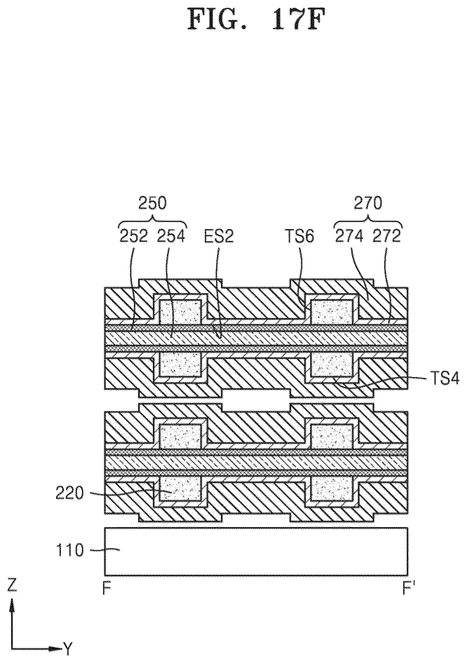

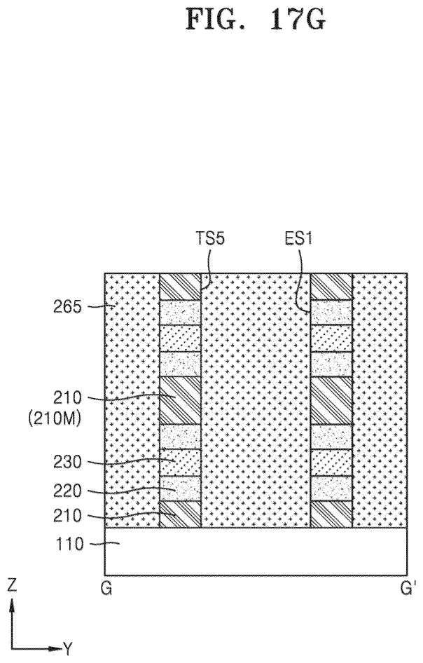

Referring to FIGS. 16A to 16G and FIGS. 17A to 17G together, a portion of the gate material layer 274P is removed to form a plurality of gate structures 270 each including the gate dielectric film 272 and the gate electrode film 274 that is the remaining portion of the gate material layer 274P. For example, the gate dielectric film 272 and the gate material layer 274P arranged between the two back gate structures 250 spaced apart from each other in the vertical direction (Z direction) form the gate dielectric film 272 and the gate electrode film 274, respectively, as a portion of the gate material layer 274P is removed. Accordingly, two gate structures 270 may be formed, which are spaced apart from each other in the vertical direction (Z direction). The gate electrode film 274 may correspond to the word line WL shown in FIG. 1. In some example embodiments, during the process of removing a portion of the gate material layer 274P, a portion of the gate dielectric film 272 may also be removed together.

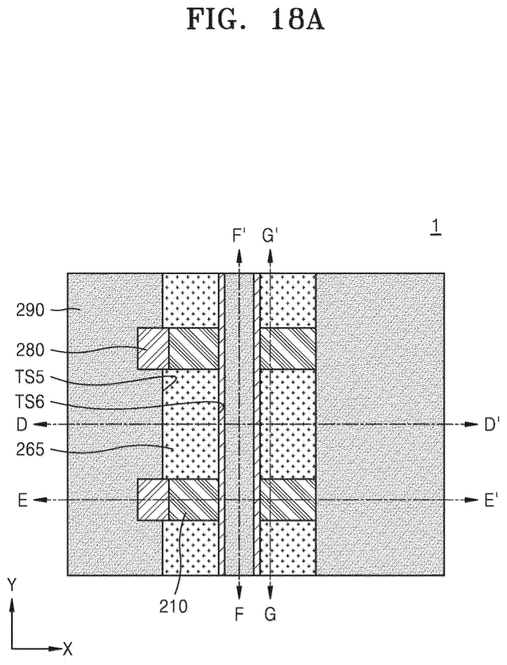

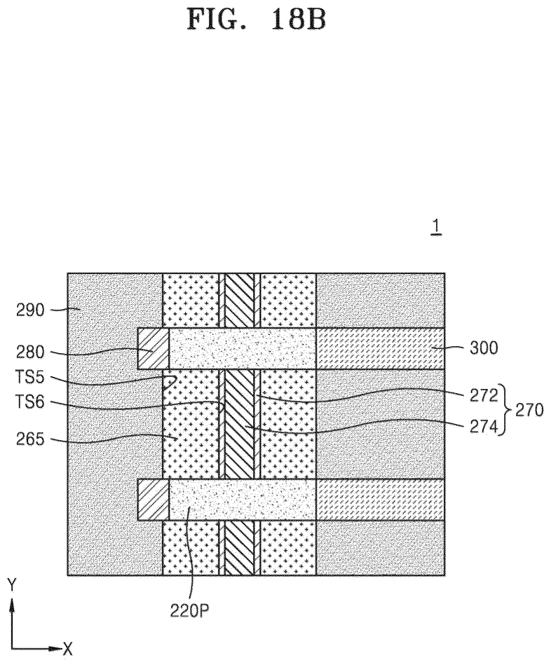

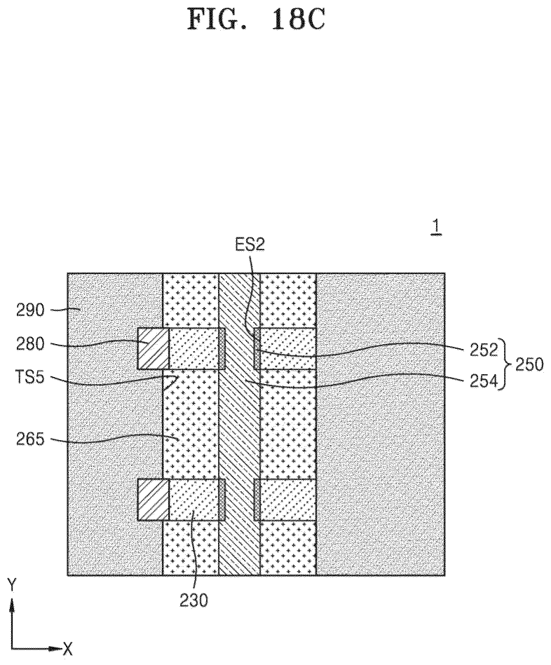

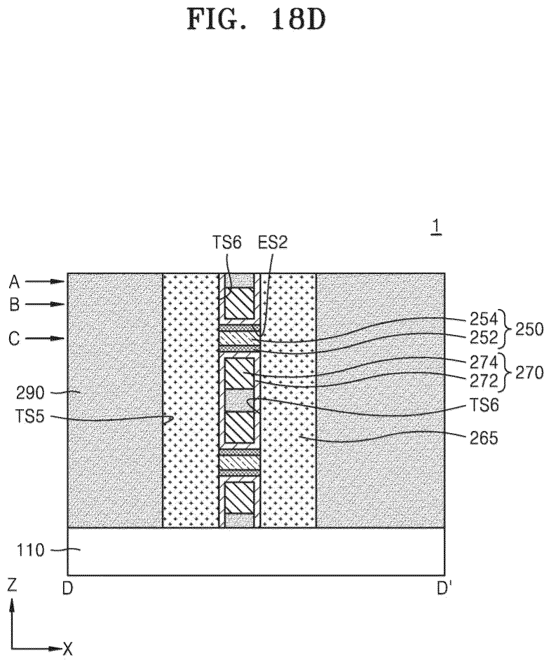

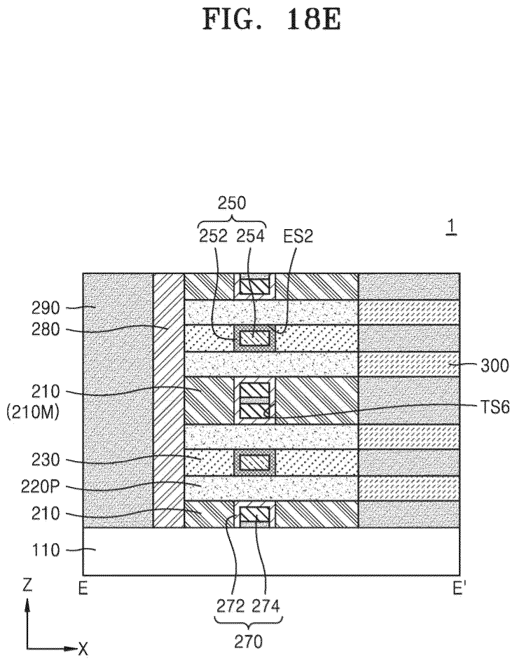

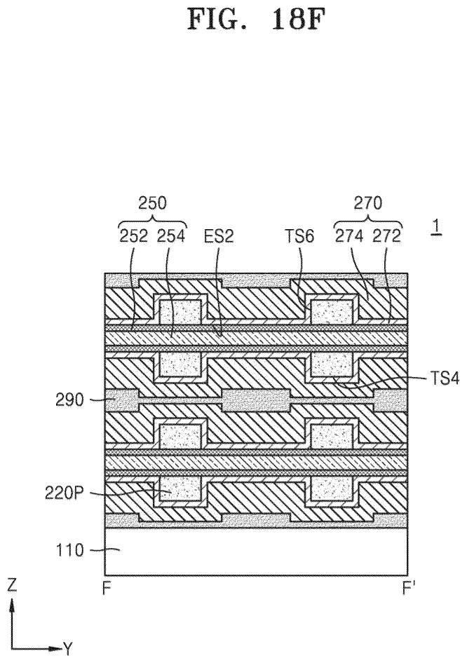

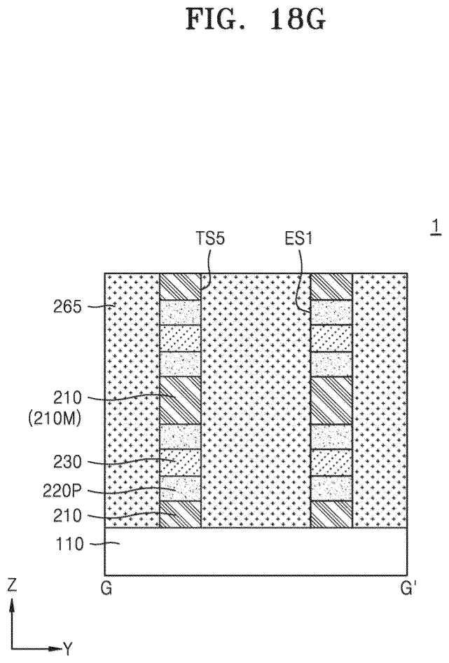

FIG. 18A to 18G are diagrams showing the semiconductor memory device 1 according to example embodiments. Specifically, FIG. 18A is a horizontal cross-sectional view showing a portion of the semiconductor memory device 1 taken along vertical level A of FIG. 18D, FIG. 18B is a horizontal cross-sectional view showing a portion of the semiconductor memory device 1 taken along vertical level B of FIG. 18D, FIG. 18C is a horizontal cross-sectional view showing a portion of the semiconductor memory device 1 taken along vertical level C of FIG. 18D, FIG. 18D is a vertical cross-sectional view showing a portion of the semiconductor memory device 1 taken along line D-D′ of FIG. 18A, FIG. 18E is a vertical cross-sectional view showing a portion of the semiconductor memory device 1 taken along line E-E′ of FIG. 18A, FIG. 18F is a vertical cross-sectional view showing a portion of the semiconductor memory device 1 taken along line F-F′ of FIG. 18A, and FIG. 18G is a vertical cross-sectional view showing a portion of the semiconductor memory device 1 taken along line G-G′ in FIG. 18A.

Referring to FIGS. 17A to 17G and FIGS. 18A to 18G together, a portion of each of the first insulating layer 210, the semiconductor layer 220, and the second insulating layer 230 is removed, which are arranged on the opposite side of the gate structure 270 and the back gate structure 250 in the first horizontal direction (X direction) from the second filling insulating layer 265. For example, the portion of each of the first insulating layer 210, the semiconductor layer 220, and the second insulating layer 230 may be removed through an etching operation. The remaining portions of the semiconductor layer 220 may form a plurality of semiconductor patterns 220P. The plurality of semiconductor patterns 220P may extend in the first horizontal direction (X direction) and be spaced apart from each other in each of the vertical direction (Z direction) and the second horizontal direction (Y direction).

In the first horizontal direction (X direction), a plurality of bit lines 280 are formed on one side of the plurality of semiconductor patterns 220P, a plurality of cell capacitors 300 are formed on the other side of the plurality of semiconductor patterns 220P, and a third filling insulating layer 290 surrounds the plurality of bit lines 280 and the plurality of cell capacitors 300. Consequently, the semiconductor memory device 1 may be formed. In some example embodiments, the third filling insulating layer 290 may fill a region from which a portion of the gate material layer 274P described with reference to FIGS. 16A to 16G and 17A to 17G has been removed. For example, a portion of the third filling insulating layer 290 may be located between two gate structures 270 that are between two back gate structures 250 spaced apart from each other in the vertical direction (Z direction).

In some example embodiments, the plurality of cell capacitors 300 may be formed before the third filling insulating layer 290 is formed, and thus, the third filling insulating layer 290 may surround the plurality of cell capacitors 300. The plurality of bit lines 280 are formed after the third filling insulating layer 290 is formed, and thus, the plurality of bit lines 280 may pass through the third filling insulating layer 290.

The plurality of bit lines 280 may extend in the vertical direction (Z direction) and be spaced apart from each other in the second horizontal direction (Y direction). Each of the plurality of bit lines 280 may be connected to one side of each of the semiconductor patterns 220P that are spaced apart from each other in the vertical direction (Z direction). The bit line 280 may correspond to the bit line BL shown in FIG. 1. The plurality of cell capacitors 300 may extend in the first horizontal direction (X direction) and be spaced apart from each other in each of the vertical direction (Z direction) and the second horizontal direction (Y direction). The plurality of cell capacitors 300 may be connected to the other side of the plurality of semiconductor patterns 220P. The bit line 280, the semiconductor pattern 220P, and the cell capacitor 300, which are connected to each other in a plan view, may be sequentially arranged in the first horizontal direction (X direction). The cell capacitor 300 may correspond to the cell capacitor CAP shown in FIG. 1.

The bit line 280 may include a conductive barrier film in contact with one end of the semiconductor pattern 220P and a conductive filling layer covering the conductive barrier film. The conductive barrier film may include, for example, metal, conductive metal nitride, conductive metal silicide, or a combination thereof. For example, the conductive barrier film may include TiN. The conductive filling layer may include, for example, doped silicon, Ru, RuO, Pt, PtO, Ir, IrO, SRO(SrRuO), BSRO((Ba,Sr) RuO), CRO(CaRuO), BaRuO, La (Sr, Co)O, Ti, TiN, W, WN, Ta, TaN, TiAlN, TiSiN, TaAlN, TaSiN, or a combination thereof. In some example embodiments, the conductive filling layer may include W.

The cell capacitor 300 may include a lower electrode layer connected to the other side of the semiconductor pattern 220P and extending in the first horizontal direction (X direction), a capacitor dielectric film covering the lower electrode layer, and an upper electrode layer covering the capacitor dielectric film. The lower electrode layer and the upper electrode layer of the cell capacitor 300 may correspond to the first electrode and the second electrode of the cell capacitor CAP, respectively, shown in FIG. 1. The capacitor dielectric film may be located between the lower electrode layer and the upper electrode layer. The lower electrode layer may include, for example, metal, conductive metal nitride, conductive metal silicide, or a combination thereof. In some example embodiments, the lower electrode layer may include a metal film having a high melting point, such as cobalt, titanium, nickel, tungsten, and molybdenum. For example, the lower electrode layer may include a metal nitride film, such as a titanium nitride film, a titanium silicon nitride film, a titanium aluminum nitride film, a tantalum nitride film, a tantalum silicon nitride film, a tantalum aluminum nitride film, and a tungsten nitride film. The capacitor dielectric film may include at least one selected from a group consisting of silicon oxide, a high-k dielectric material having a higher dielectric constant than silicon oxide, and a ferroelectric material. For example, the capacitor dielectric film may include at least one of metal oxide and a dielectric material having a perovskite structure. In some example embodiments, the capacitor dielectric film includes at least one selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The upper electrode layer may include, for example, doped silicon, Ru, RuO, Pt, PtO, Ir, IrO, SRO(SrRuO), BSRO((Ba,Sr)RuO), CRO(CaRuO), BaRuO, La(Sr, Co)O, Ti, TiN, W, WN, Ta, TaN, TiAlN, TiSiN, TaAlN, TaSiN, or a combination thereof. In some example embodiments, the upper electrode layer may include W.

In some example embodiments, first impurities having a first conductivity type may be implanted into the plurality of semiconductor patterns 220P. Also, before the plurality of bit lines 280 and the plurality of cell capacitors 300 are formed, second impurities having a second conductivity type different from the first conductivity type may be implanted into each of one end and the other end of the plurality of semiconductor patterns 220P. The one end and the other end of the plurality of semiconductor patterns 220P, into which the second impurities are implanted, may be referred to as a source region and a drain region, respectively. Also, a portion between the source region and the drain region, into which the first impurities are implanted, may be referred to as a channel region. In some example embodiments, the first conductivity type may be p-type, and the second conductivity type may be n-type. The bit line 280 may be connected to the source region, and the lower electrode of the cell capacitor 300 may be connected to the drain region. The source region, the channel region, and the drain region may be sequentially arranged in the first horizontal direction (X direction). The semiconductor pattern 220P, the gate dielectric film 272, and the gate electrode film 274 may constitute the cell transistor CTR shown in FIG. 1.

The plurality of semiconductor patterns 220P may be spaced apart from each other in the vertical direction (Z direction). Two gate structures 270 may be arranged between one semiconductor pattern 220P among the plurality of semiconductor patterns 220P and another semiconductor pattern 220P above the one semiconductor pattern 220P. Also, one back gate structure 250 may be located between one semiconductor pattern 220P and another semiconductor pattern 220P below the one semiconductor pattern 220P.

In some example embodiments, a portion of the back gate dielectric film 252 and a portion of the gate dielectric film 272 may be in contact with each other. For example, the back gate dielectric film 252 and the gate dielectric film 272 covering the two semiconductor patterns 220P adjacent to each other in the second horizontal direction (Y direction) may be in contact with each other between the two semiconductor patterns 220P adjacent to each other in the second horizontal direction (Y direction).

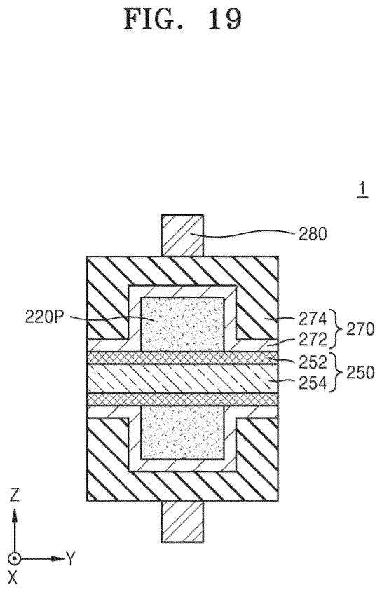

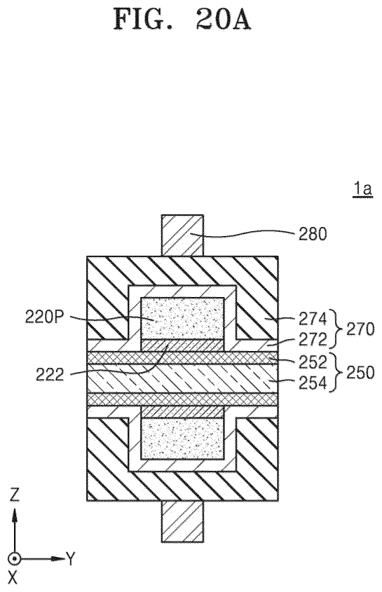

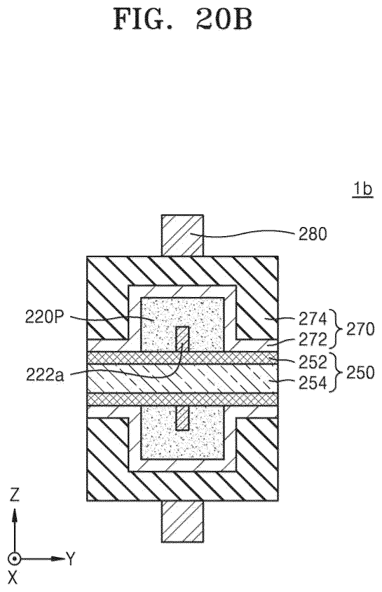

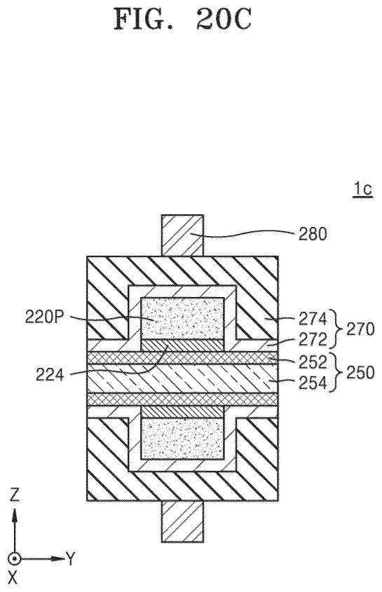

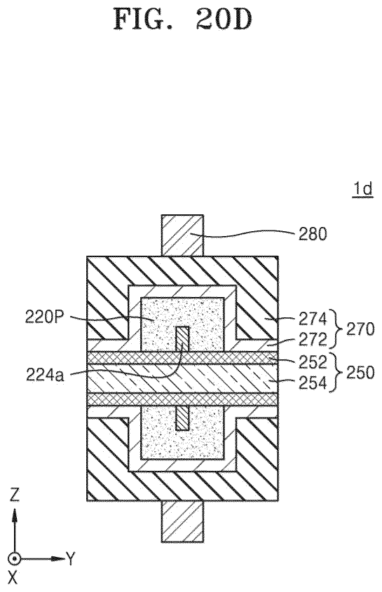

FIG. 19 and FIGS. 20A to 20D are partial enlarged views of semiconductor memory devices according to example embodiments.

Referring to FIGS. 18A to 18G and FIG. 19 together, the semiconductor memory device 1 may include the plurality of gate structures 270 extending in the second horizontal direction (Y direction), the plurality of bit lines 280 extending in the vertical direction (Z direction), and the plurality of semiconductor patterns 220P connected to the plurality of bit lines 280 and extending in the first horizontal direction (X direction). The semiconductor memory device 1 may include a plurality of cell capacitors 300. One end of the plurality of semiconductor patterns 220P is connected to the plurality of bit lines 280, and the other end of the plurality of semiconductor patterns 220P, which is opposite to the one end of the plurality of semiconductor patterns 220P, is connected to the plurality of cell capacitors 300. The semiconductor memory device 1 may further include the plurality of back gate structures 250 each located between two gate structures 270 adjacent to each other in the vertical direction (Z direction) and extending in the second horizontal direction (Y direction).

The back gate structure 250 may cover one side surface of the semiconductor pattern 220P and the gate structure 270 may cover the remaining side surfaces of the semiconductor pattern 220P. For example, the back gate dielectric film 252 may be in contact with one side surface of the semiconductor pattern 220P, and the gate dielectric film 272 may be in contact with the remaining side surfaces of the semiconductor pattern 220P. For example, the back gate electrode film 254 may cover one side surface of the semiconductor pattern 220P with the back gate dielectric film 252 therebetween, and the gate electrode film 274 may cover the other side surfaces of the semiconductor pattern 220P with the gate dielectric film 272 therebetween.

For example, in a cross-section perpendicular to the direction in which the semiconductor pattern 220P extends, that is, the Y-Z cross-section perpendicular to the first horizontal direction (X direction), the back gate structure 250 may cover one of the edges of the semiconductor pattern 220P, and the gate structure 270 may cover the remaining edges of the semiconductor pattern 220P other than the one edge of the semiconductor pattern 220P. The back gate structure 250 may be in contact with each of the two semiconductor patterns 220P adjacent to each other in the vertical direction (Z direction).

For example, the lower surface of one semiconductor pattern 220P located above the back gate structure 250 may be in contact with the upper surface of the back gate structure 250. Also, the remaining surfaces of the one semiconductor pattern 220P, that is, the upper surface of the one semiconductor pattern 220P and both side surfaces of the one semiconductor pattern 220P in the second horizontal direction (Y direction), may be in contact with one gate structure 270 located above the back gate structure 250. For example, the upper surface of another semiconductor pattern 220P located below the back gate structure 250 may be in contact with the lower surface of the back gate structure 250. Also, the remaining surfaces of another semiconductor pattern 220P, that is, the lower surface of another semiconductor pattern 220P and both side surfaces of another semiconductor pattern 220P in the second horizontal direction (Y direction), may be in contact with another gate structure 270 located below the back gate structure 250. Therefore, the back gate structure 250 may be shared by one semiconductor pattern 220P and one gate structure 270, which are arranged above the back gate structure 250, and another semiconductor pattern 220P and another gate structure 270, which are arranged below the back gate structure 250.

Referring to FIG. 20A, a semiconductor memory device 1a may further include a sub insulating layer 222, in contrast to the semiconductor memory device 1 shown in FIG. 19. The sub insulating layer 222 may be located between the back gate structure 250 and the semiconductor pattern 220P. For example, the back gate structure 250 and the semiconductor pattern 220P may be spaced apart from each other with the sub insulating layer 222 therebetween. The sub insulating layer 222 may be formed by depositing, on a lower portion or upper portion of the semiconductor layer 220, an insulating material layer corresponding to the sub insulating layer 222 during the process of forming the semiconductor layer 220 shown in FIGS. 2A to 2G.

The semiconductor memory device 1a may include a semiconductor pattern 220P having a relatively small thickness due to the sub insulating layer 222. In some example embodiments, the semiconductor pattern 220P may have a thickness of about 5 nm or less. The semiconductor memory device 1a includes the semiconductor pattern 220P having a relatively small thickness, and thus, the occurrence of a floating body effect may be prevented to improve the operation reliability.

Referring to FIG. 20B, a semiconductor memory device 1b may further include a sub insulating layer 222a, in contrast to the semiconductor memory device 1 shown in FIG. 19. The sub insulating layer 222a may be located between the back gate structure 250 and the semiconductor pattern 220P. The sub insulating layer 222a extends from the back gate structure 250 into the semiconductor pattern 220P but may not extend to the gate structure 270. For example, the semiconductor pattern 220P may cover one of the upper surface and the lower surface of the sub insulating layer 222a and both side surfaces of the sub insulating layer 222a in the second horizontal direction (Y direction). The sub insulating layer 222a may be formed by depositing, on a lower portion or upper portion of the semiconductor layer 220, an insulating material layer corresponding to the sub insulating layer 222a during the process of forming the semiconductor layer 220 shown in FIGS. 2A to 2G.

The semiconductor memory device 1b may include a semiconductor pattern 220P having a relatively small thickness due to the sub insulating layer 222a. In some example embodiments, the semiconductor pattern 220P may have a thickness of about 5 nm or less between the sub insulating layer 222a and the gate structure 270. The semiconductor memory device 1b includes the semiconductor pattern 220P having a relatively small thickness, and thus, the occurrence of a floating body effect may be prevented to improve the operation reliability.

Referring to FIG. 20C, a semiconductor memory device 1c may further include a sub semiconductor layer 224, in contrast to the semiconductor memory device 1 shown in FIG. 19. The sub semiconductor layer 224 may be located between the back gate structure 250 and the semiconductor pattern 220P. For example, the back gate structure 250 and the semiconductor pattern 220P may be spaced apart from each other with the sub semiconductor layer 224 therebetween. The sub semiconductor layer 224 may be formed by depositing, on a lower portion or upper portion of the semiconductor layer 220, a semiconductor material layer corresponding to the sub semiconductor layer 224 during the process of forming the semiconductor layer 220 shown in FIGS. 2A to 2G. The sub semiconductor layer 224 may include a different semiconductor material from the semiconductor pattern 220P.

In some example embodiments, the sub semiconductor layer 224 may include a semiconductor material having a band gap smaller than that of the semiconductor material of the semiconductor pattern 220P. For example, the sub semiconductor layer 224 may include SiGe, AlGaAs, GaAs, InGaP, or ZnSe. When the semiconductor pattern 220P and the sub semiconductor layer 224 come into contact with each other, the band gap of a balance band becomes smaller than the band gap of a conduction band. Accordingly, the movement of holes from the semiconductor pattern 220P to the sub semiconductor layer 224 may be facilitated, and the operation reliability of the semiconductor memory device 1c may be improved.

Referring to FIG. 20D, a semiconductor memory device 1d may further include a sub semiconductor layer 224a, in contrast to the semiconductor memory device 1 shown in FIG. 19. The sub semiconductor layer 224a may be located between the back gate structure 250 and the semiconductor pattern 220P. The sub semiconductor layer 224a extends from the back gate structure 250 into the semiconductor pattern 220P but may not extend to the gate structure 270. For example, the semiconductor pattern 220P may cover one of the upper surface and the lower surface of the sub semiconductor layer 224a and both side surfaces of the sub semiconductor layer 224a in the second horizontal direction (Y direction). The sub semiconductor layer 224a may be formed by depositing, on a lower portion or upper portion of the semiconductor layer 220, a semiconductor material layer corresponding to the sub semiconductor layer 224a during the process of forming the semiconductor layer 220 shown in FIGS. 2A to 2G. The sub semiconductor layer 224a may include a different semiconductor material from the semiconductor pattern 220P.

In some example embodiments, the sub semiconductor layer 224a may include a semiconductor material having a band gap smaller than that of the semiconductor material of the semiconductor pattern 220P. For example, the sub semiconductor layer 224a may include SiGe. When the semiconductor pattern 220P and the sub semiconductor layer 224a come into contact with each other, the band gap of a balance band becomes smaller than the band gap of a conduction band. Accordingly, the movement of holes from the semiconductor pattern 220P to the sub semiconductor layer 224a may be facilitated, and the operation reliability of the semiconductor memory device 1d may be improved.

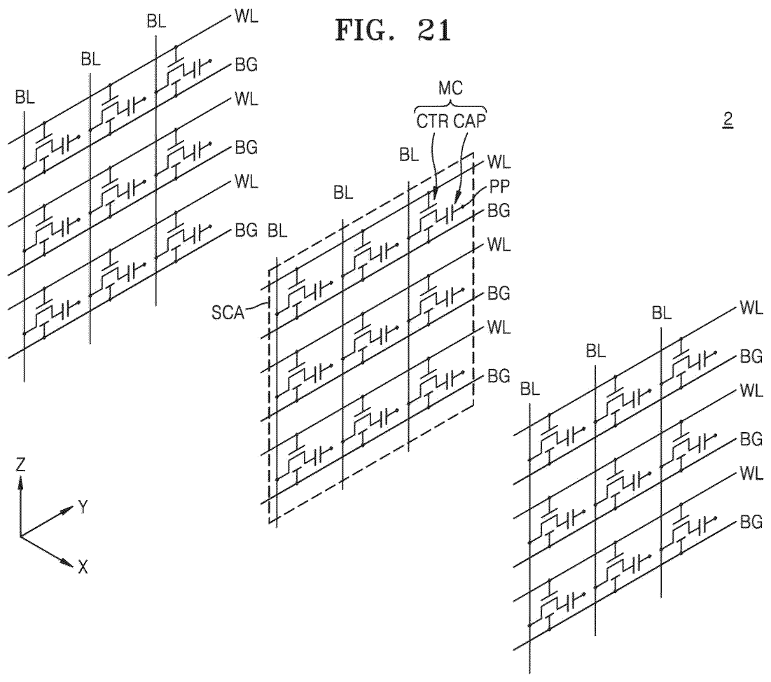

FIG. 21 is an equivalent circuit diagram showing a cell array of a semiconductor memory device 2 according to an example embodiment.

Referring to FIG. 21, the cell array of the semiconductor memory device 2 according to example embodiments may include a plurality of sub cell arrays SCA. The plurality of sub cell arrays SCA may be arranged in a first horizontal direction (X direction). Each of the sub cell arrays SCA may include a plurality of bit lines BL, a plurality of word lines WL, a plurality of back gate lines BG, and a plurality of cell transistors CTR. One cell transistor CTR may be located between one word line WL and one bit line BL.

The plurality of word lines WL may extend in a second horizontal direction (Y direction). The word lines WL in one sub cell array SCA may be spaced apart from each other in a vertical direction (Z direction). The plurality of back gate lines BG may extend in the second horizontal direction (Y direction). The back gate lines BG in one sub cell array SCA may be spaced apart from each other in the vertical direction (Z direction). The word lines WL and the back gate lines BG in one sub cell array SCA may be spaced apart from each other in the vertical direction (Z direction) and extend parallel to each other in the second horizontal direction (Y direction). In one sub cell array SCA, the number of word lines WL may be equal or substantially similar to the number of back gate lines BG. For example, the word lines WL and the back gate lines BG in one sub cell array SCA may be alternately arranged in the vertical direction (Z direction). The bit lines BL in one sub cell array SCA may be spaced apart from each other in the second horizontal direction (Y direction).

The plurality of bit lines BL may extend in the vertical direction (Z direction). The bit lines BL in one sub cell array SCA may be spaced apart from each other in the second horizontal direction (Y direction).

A gate of the cell transistor CTR may be connected to the word line WL and a source of the cell transistor CTR may be connected to the bit line BL. The cell transistor CTR may be connected to a cell capacitor CAP. A drain of the cell transistor CTR may be connected to a first electrode of the cell capacitor CAP, and a second electrode of the cell capacitor CAP may be connected to a ground wire PP.

The semiconductor memory device 2 may include the plurality of sub cell arrays SCA, each of which includes a plurality of memory cells MC spaced apart from each other in the second horizontal direction (Y direction) and the vertical direction (Z direction) and arranged in rows and columns, the plurality of bit lines BL connected to the cell transistors CTR of the memory cells MC arranged in the vertical direction (Z direction), extending in the vertical direction (Z direction), and spaced apart from each other in the second horizontal direction (Y direction), and the plurality of word lines WL extending in the second horizontal direction (Y direction) and spaced apart from each other in the vertical direction (Z direction). The plurality of sub cell arrays SCA may be arranged in the first horizontal direction (X direction).

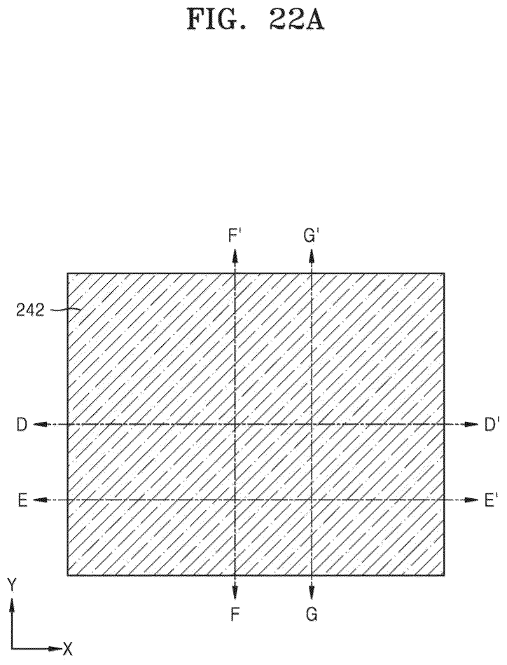

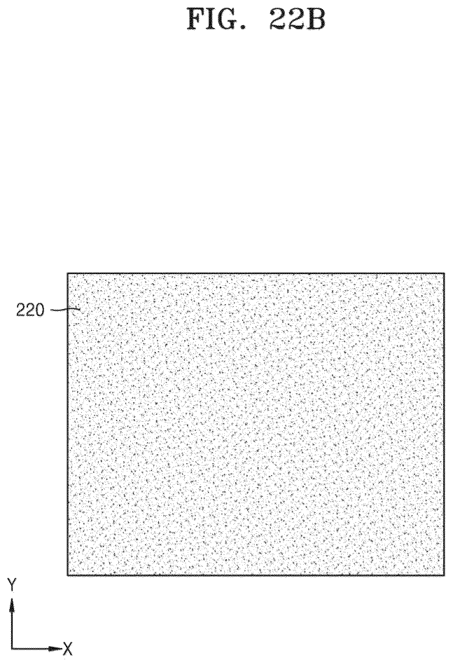

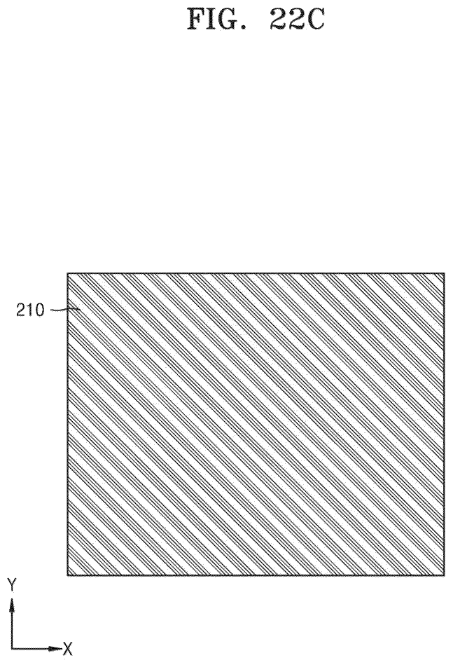

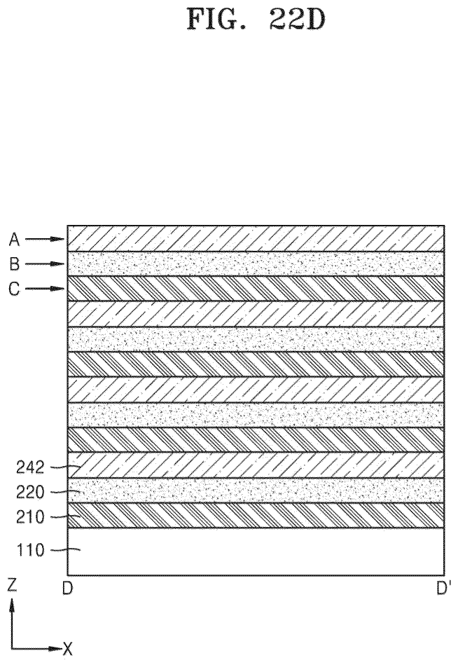

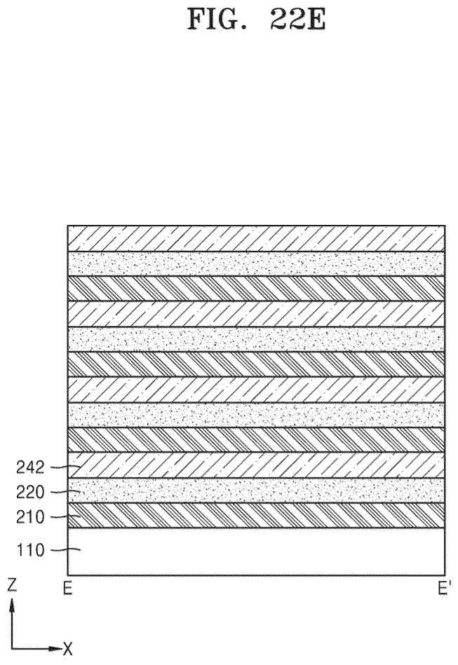

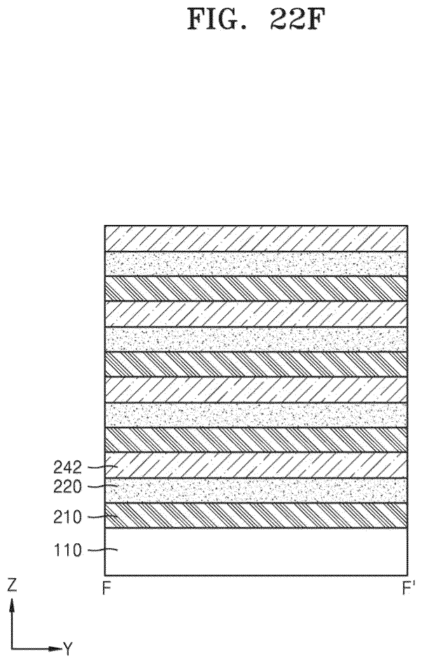

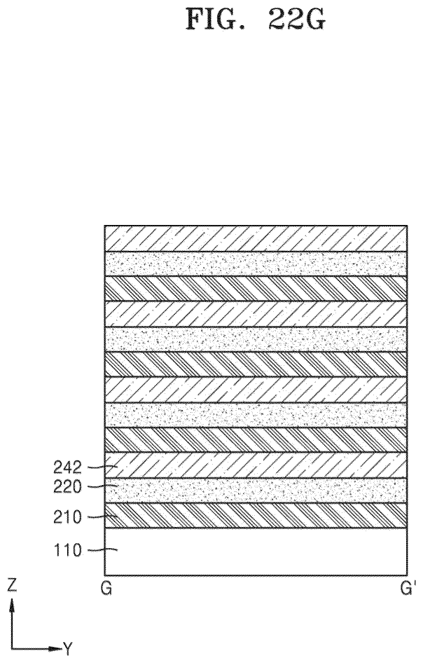

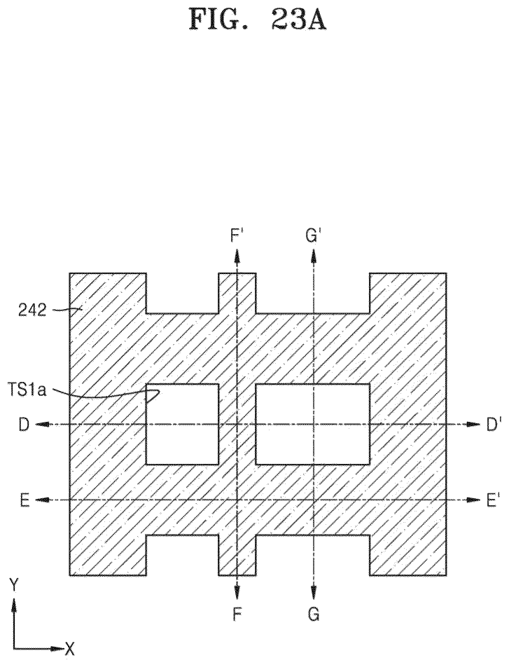

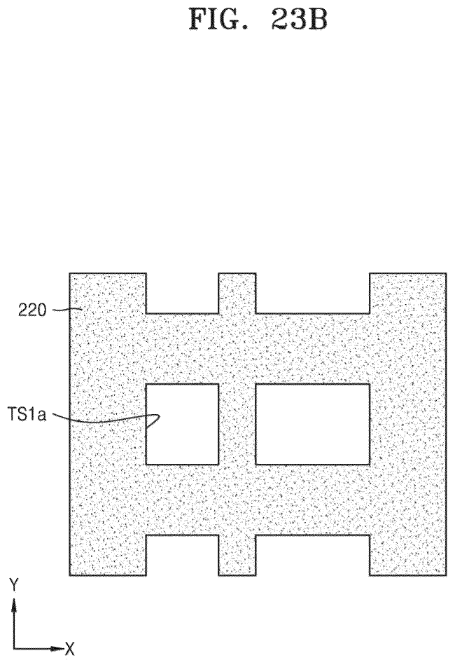

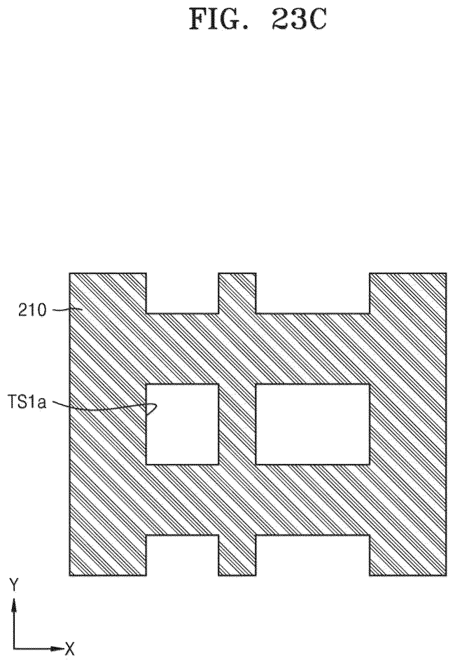

FIGS. 22A to 32G are diagrams showing a method of manufacturing a semiconductor memory device in a process order, according to example embodiments. Specifically, FIGS. 22A, 23A, 24A, 25A, 26A, 27A, 28A, 29A, 30A, 31A, and 32A are horizontal cross-sectional views of the semiconductor memory device taken along vertical level A of FIGS. 22D, 23D, 24D, 25D, 26D, 27D, 28D, 29D, 30D, 31D, and 32D. Also, FIGS. 22B, 23B, 24B, 25B, 26B, 27B, 28B, 29B, 30B, 31B, and 32B are horizontal cross-sectional views of the semiconductor memory device taken along vertical level B of FIGS. 22D, 23D, 24D, 25D, 26D, 27D, 28D, 29D, 30D, 31D, and 32D. Also, FIGS. 22C, 23C, 24C, 25C, 26C, 27C, 28C, 29C, 30C, 31C, and 32C are horizontal cross-sectional views of the semiconductor memory device taken along vertical level C of FIGS. 22D, 23D, 24D, 25D, 26D, 27D, 28D, 29D, 30D, 31D, and 32D. Also, FIGS. 22D, 23D, 24D, 25D, 26D, 27D, 28D, 29D, 30D, 31D, and 32D are vertical cross-sectional views of the semiconductor memory device taken along line D-D′ of FIGS. 22A, 23A, 24A, 25A, 26A, 27A, 28A, 29A, 30A, 31A, and 32A. Also, FIGS. 22E, 23E, 24E, 25E, 26E, 27E, 28E, 29E, 30E, 31E, and 32E are vertical cross-sectional views of the semiconductor memory device taken along line E-E′ of FIGS. 22A, 23A, 24A, 25A, 26A, 27A, 28A, 29A, 30A, 31A, and 32A. Also, FIGS. 22F, 23F, 24F, 25F, 26F, 27F, 28F, 29F, 30F, 31F, and 32F are vertical cross-sectional views of the semiconductor memory device taken along line F-F′ of FIGS. 22A, 23A, 24A, 25A, 26A, 27A, 28A, 29A, 30A, 31A, and 32A. Also, FIGS. 22G, 23G, 24G, 25G, 26G, 27G, 28G, 29G, 30G, 31G, and 32G are vertical cross-sectional views of the semiconductor memory device taken along line G-G′ of FIGS. 22A, 23A, 24A, 25A, 26A, 27A, 28A, 29A, 30A, 31A, and 32A.

Referring to FIGS. 22A to 22G together, a plurality of first insulating layers 210, a plurality of semiconductor layers 220, and a plurality of sacrificial layers 242 are formed on a substrate 110. A sub stack structure including the first insulating layer 210, the semiconductor layer 220, and the sacrificial layer 242 may be repeatedly stacked on the substrate 110.

The first insulating layer 210, the semiconductor layer 220, and the sacrificial layer 242 may include materials having etch selectivities relative to each other. For example, each of the first insulating layer 210, the semiconductor layer 220, and the second insulating layer 230 may be etched using difference etch recipes. In some example embodiments, the first insulating layer 210 may include nitride. For example, the first insulating layer 210 may include silicon nitride. In some example embodiments, the semiconductor layer 220 may include a material having the same or similar etch characteristics as the substrate 110 or include the same material as the substrate 110. In some example embodiments, the semiconductor layer 220 may include Si. In some example embodiments, the sacrificial layer 242 may include a semiconductor material different from that of the semiconductor layer 220. In some example embodiments, the sacrificial layer 242 may include SiGe. In some example embodiments, each of the semiconductor layer 220 and the sacrificial layer 242 may include a single crystalline semiconductor material. For example, the semiconductor layer 220 may include single crystalline Si and the sacrificial layer 242 may include single crystalline SiGe.

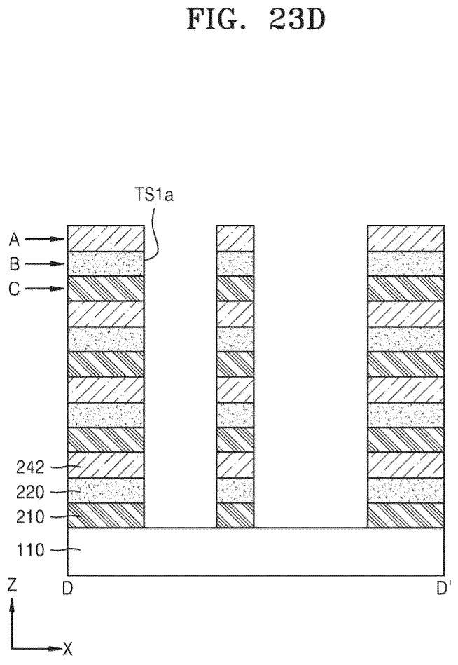

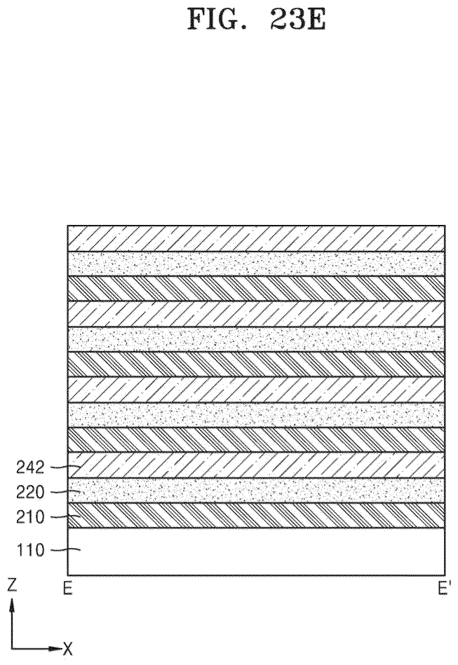

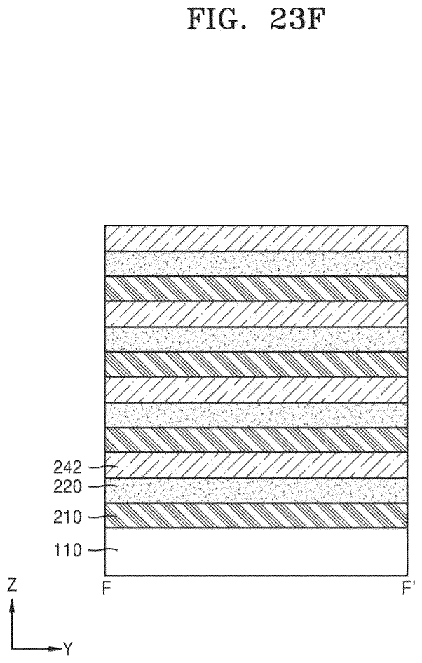

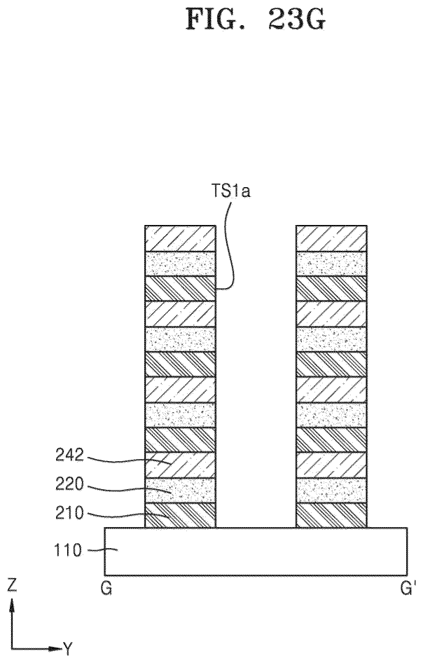

Referring to FIGS. 23A to 23G together, a plurality of first trim spaces TSla are formed, which pass through the plurality of first insulating layers 210, the plurality of semiconductor layers 220, and the plurality of sacrificial layers 242 but are spaced apart from each other in a plan view. Two of the plurality of first trim spaces TS1a may be arranged in the first horizontal direction (X direction), and the first trim spaces TS1a may be arranged in a row in the second horizontal direction (Y direction). The substrate 110 may be exposed from the bottom surface of each of the plurality of first trim spaces TSla.

The horizontal widths and horizontal areas of the two first trim spaces TSla arranged in the first horizontal direction (X direction) may be different from each other. In some example embodiments, among the two first trim spaces TS1a arranged in the first horizontal direction (X direction), the horizontal width of the first trim space TS1a located on the right in the first horizontal direction (X direction) may be greater than the horizontal width of the first trim space TS1a located on the left in the first horizontal direction (X direction). In some example embodiments, the horizontal widths of the plurality of first trim spaces TS1a in the second horizontal direction (Y direction) may be substantially equal to each other.

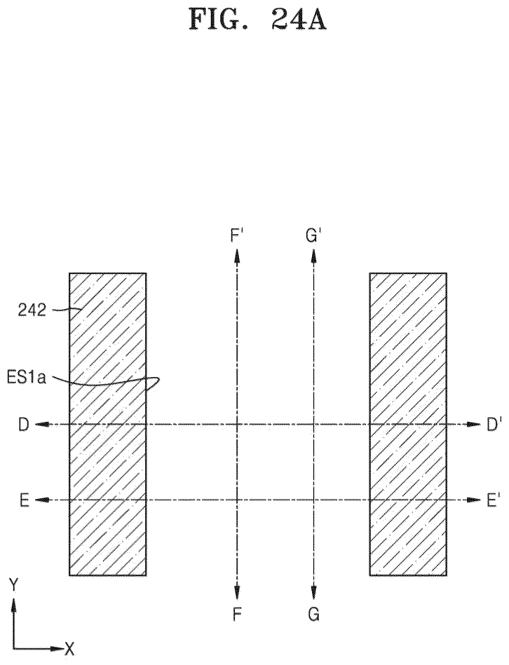

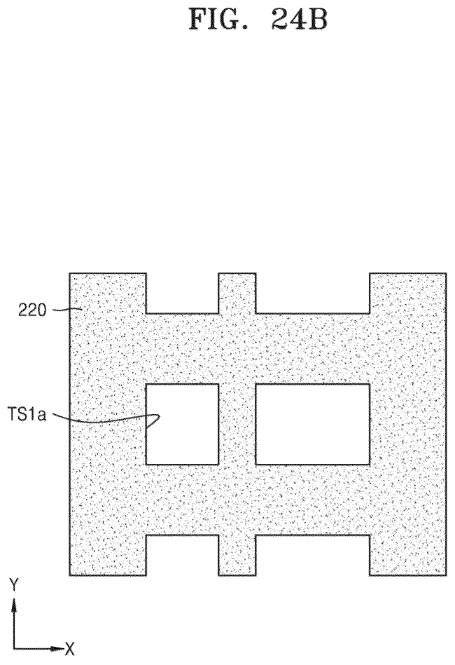

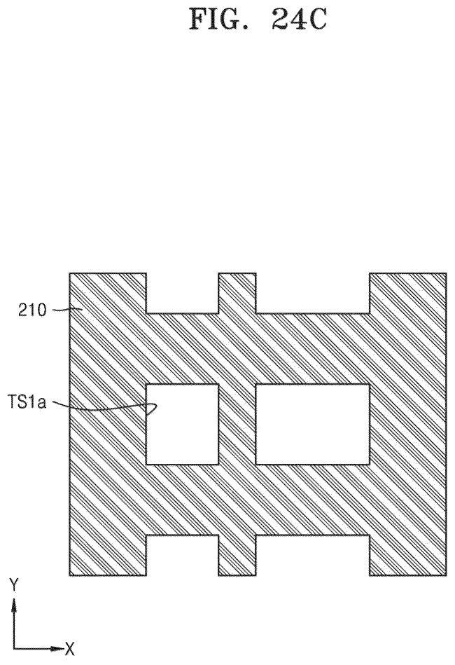

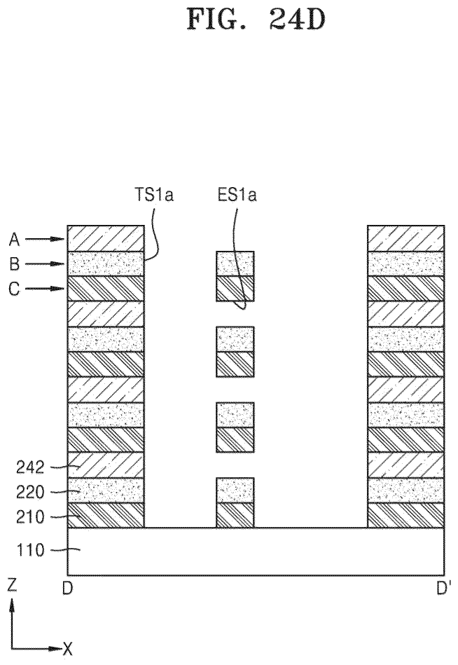

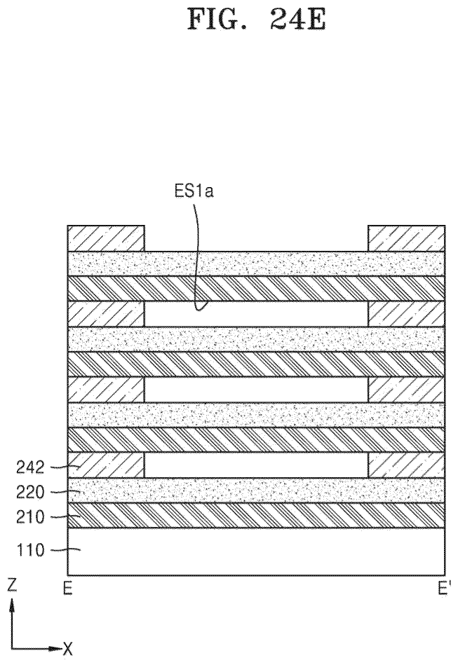

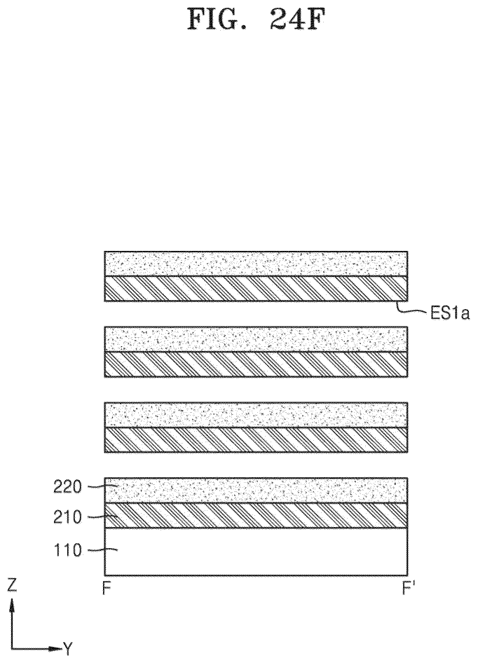

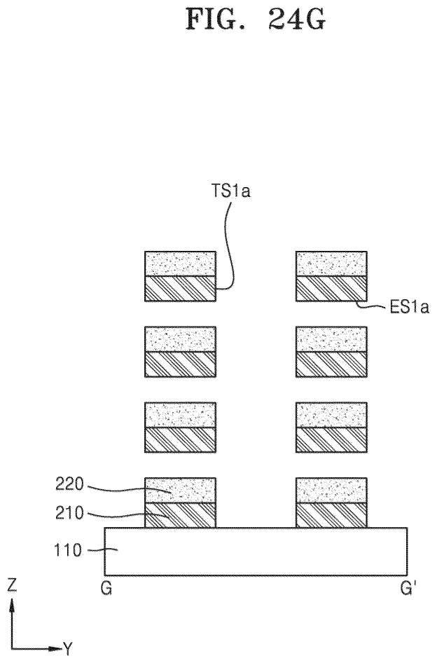

Referring to FIGS. 24A to 24G together, a portion of the plurality of sacrificial layers 242 is removed through the plurality of first trim spaces TS1a to form a plurality of first expansion spaces ES1a in each of the plurality of sacrificial layers 242. For example, the portion of the sacrificial layers may be removed through an etching operation. Each of the plurality of first expansion spaces ES1a may be formed such that the plurality of first trim spaces TS1a in each of the plurality of sacrificial layers 242 are connected to each other.

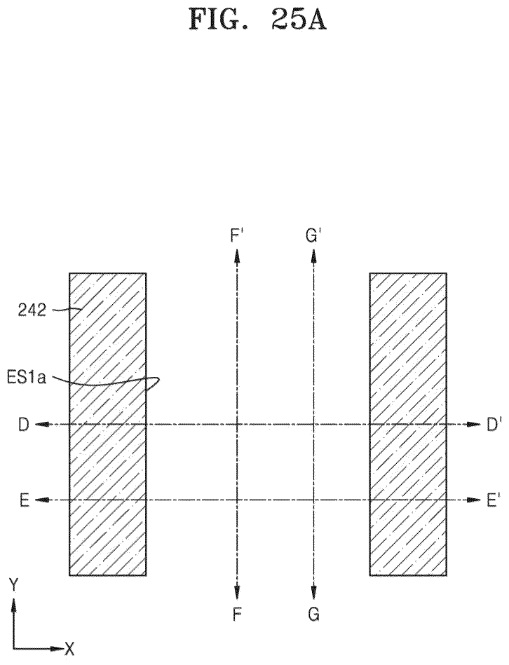

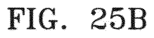

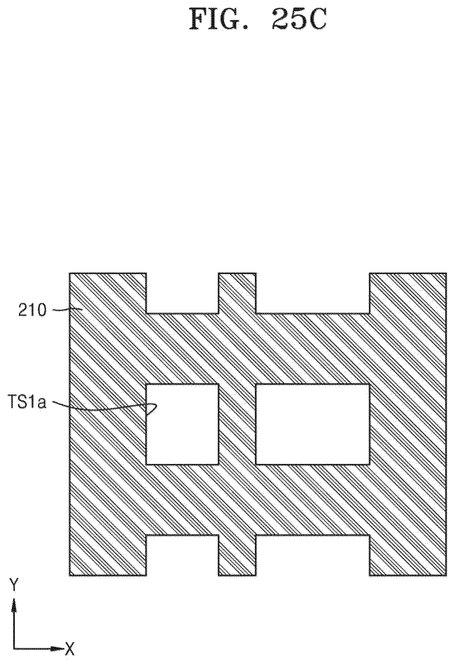

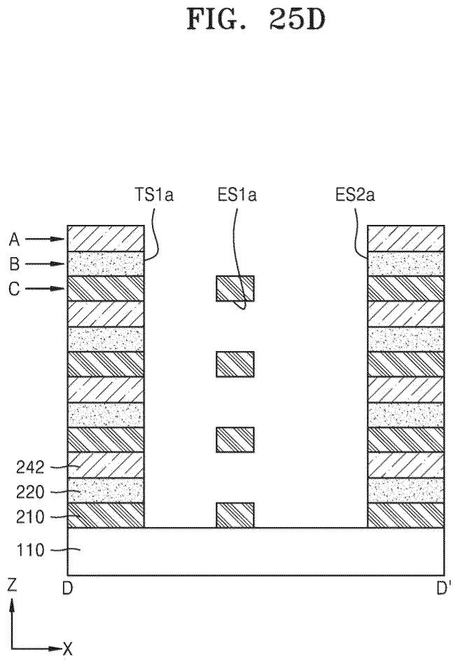

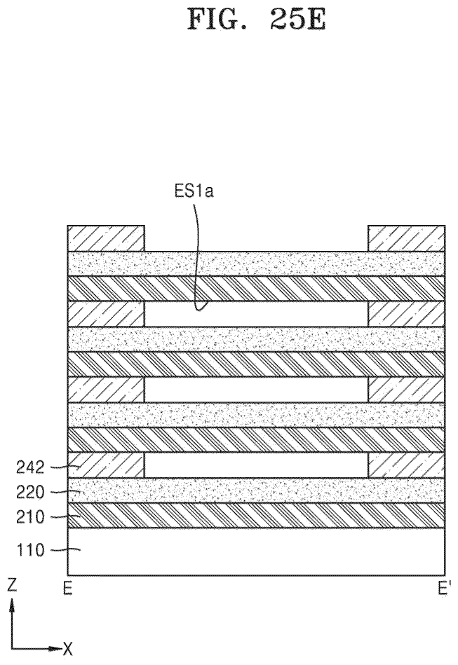

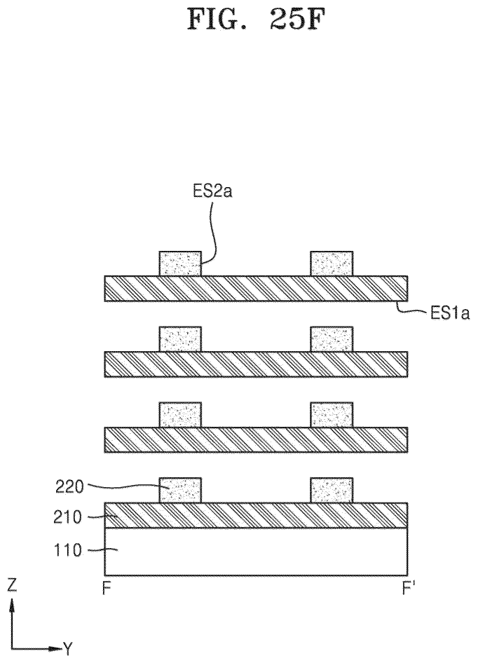

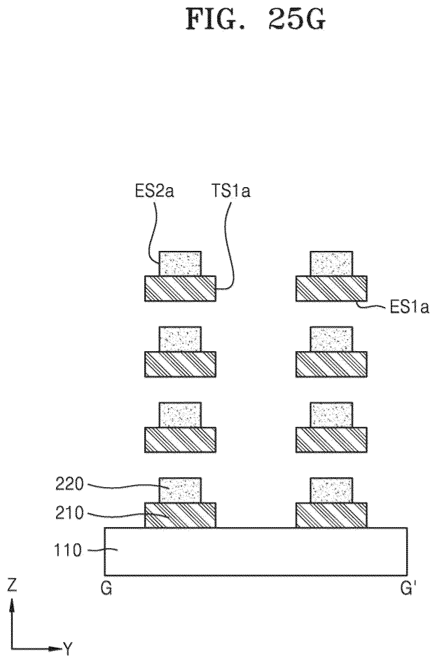

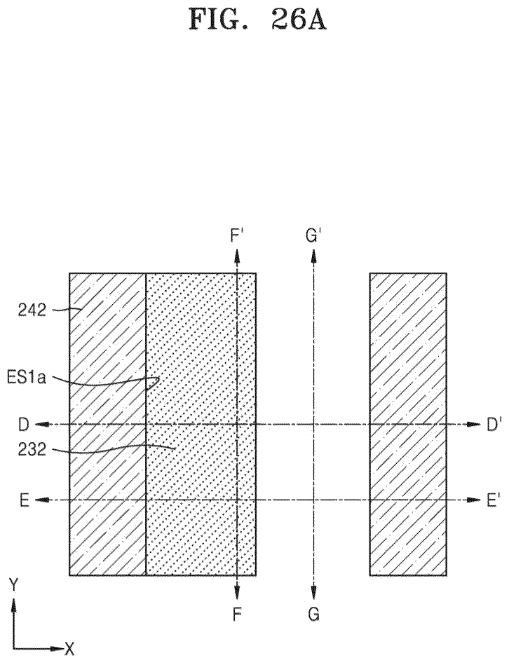

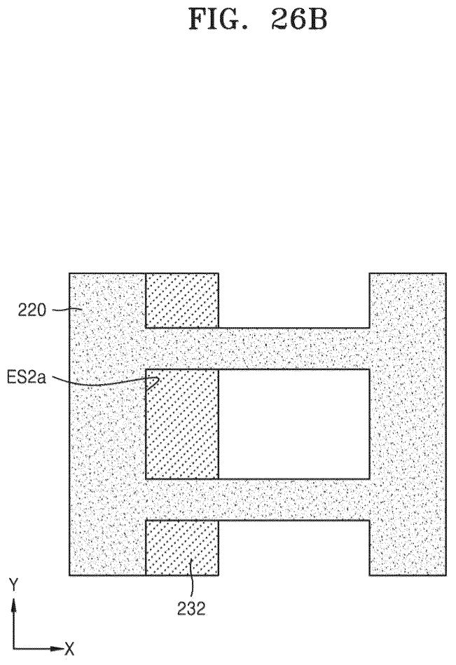

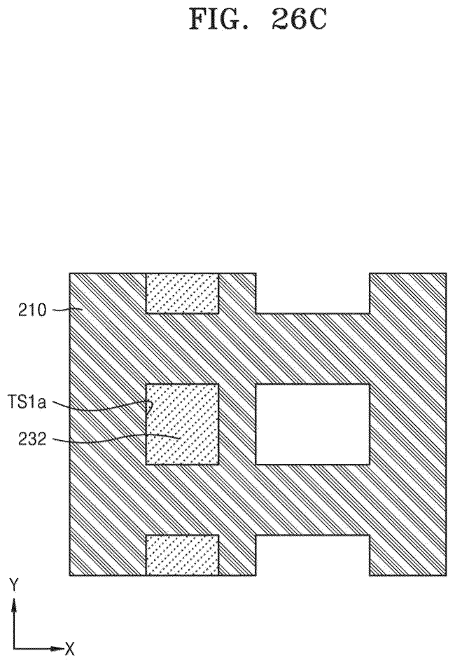

Referring to FIGS. 25A to 25G together, a portion of each of the plurality of semiconductor layers 220 is removed to form a plurality of second expansion spaces ES2a in each of the plurality of semiconductor layers 220. For example, the portion of each of the plurality of semiconductor layers 220 may be removed through an etching operation. Each of the plurality of second expansion spaces ES2a may be formed such that two first trim spaces TS1a adjacent to each other in the first horizontal direction (X direction) in each of the plurality of semiconductor layers 220 are connected. In some example embodiments, the horizontal width of each of the plurality of second expansion spaces ES2a in the second horizontal direction (Y direction) may be greater than the horizontal width of each of the plurality of first trim spaces TS1a in the second horizontal direction (Y direction).

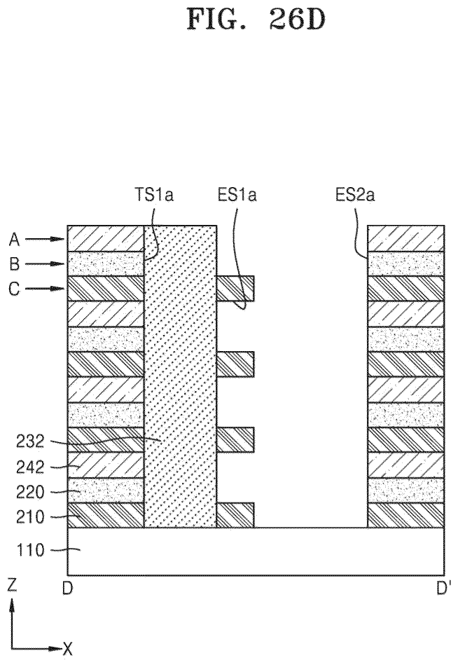

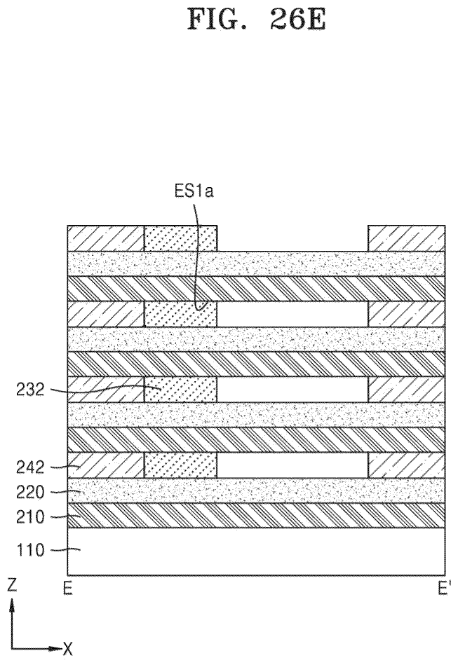

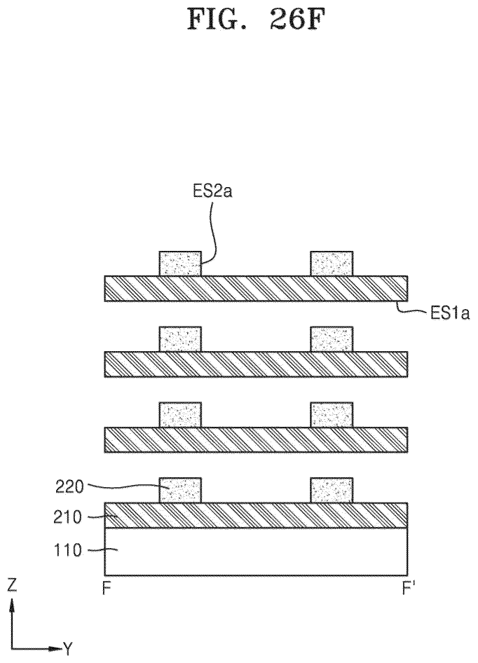

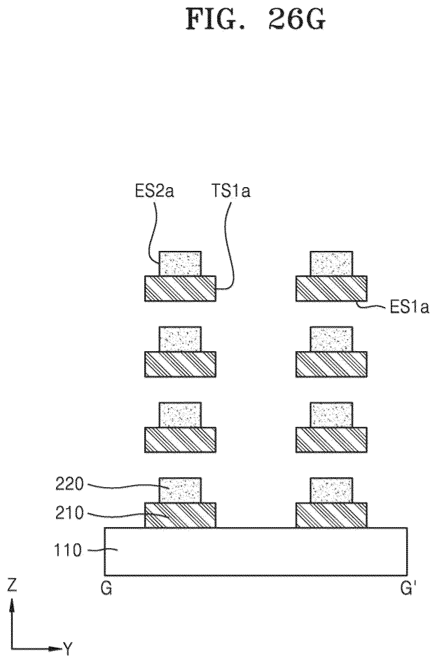

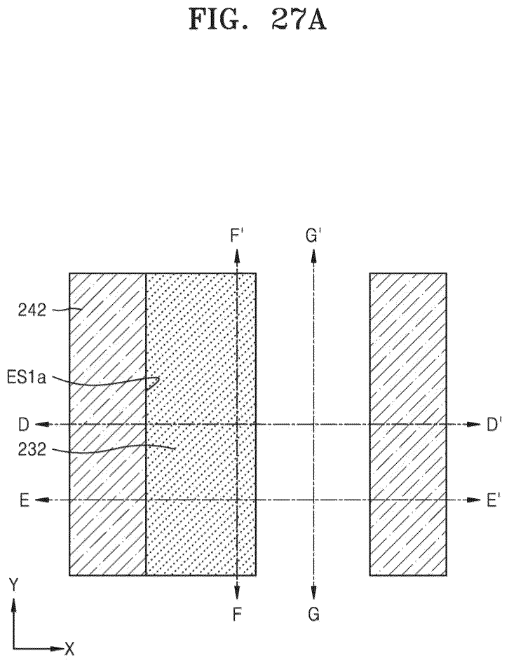

Referring to FIGS. 26A to 26G together, a second insulating layer 232 is provided to fill the first trim spaces TS1a, which are located on the left side in the first horizontal direction (X direction) among the plurality of first trim spaces TS1a and arranged in a row in the second horizontal direction (Y direction), and the spaces between the first trim spaces TSla. In a plan view, the second insulating layer 232 may overlap the first trim spaces TSla, which are located on the left side in the first horizontal direction (X direction) among the plurality of first trim spaces TS1a and arranged in a row in the second horizontal direction (Y direction), and may extend in the second horizontal direction (Y direction). The second insulating layer 232 may include oxide. For example, the second insulating layer 232 may include silicon oxide.

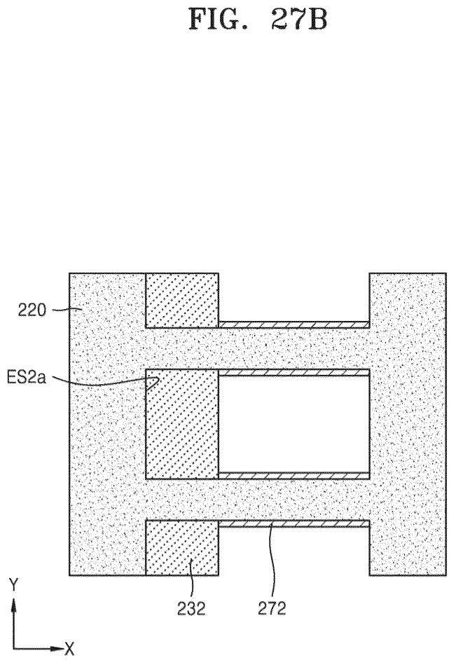

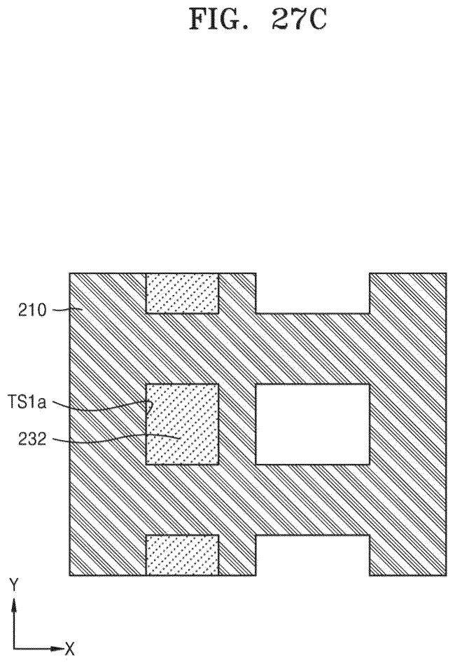

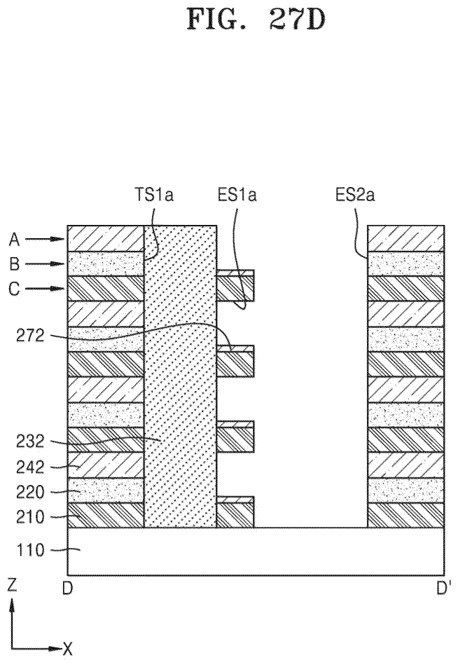

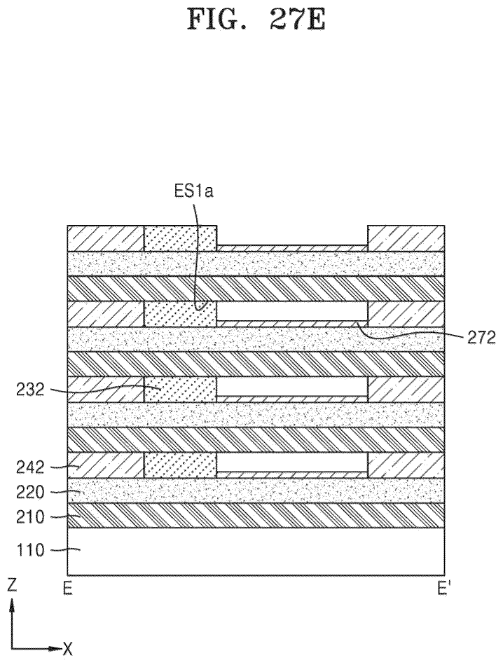

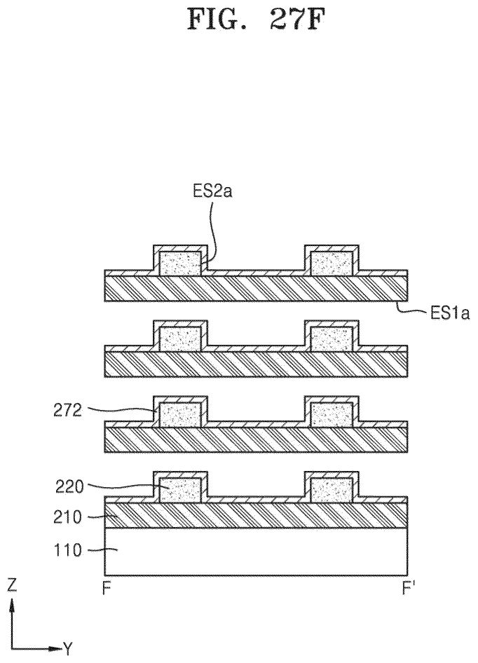

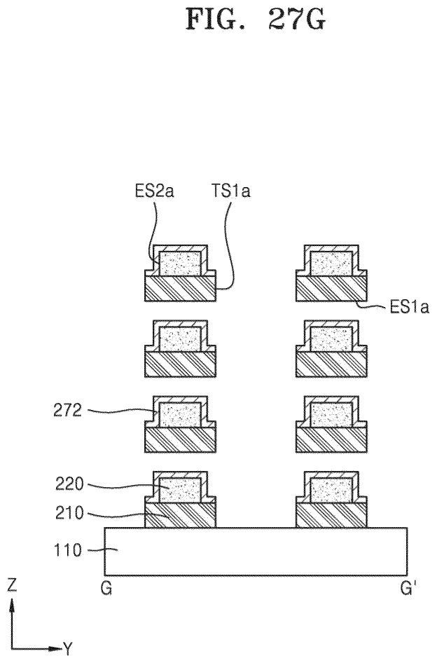

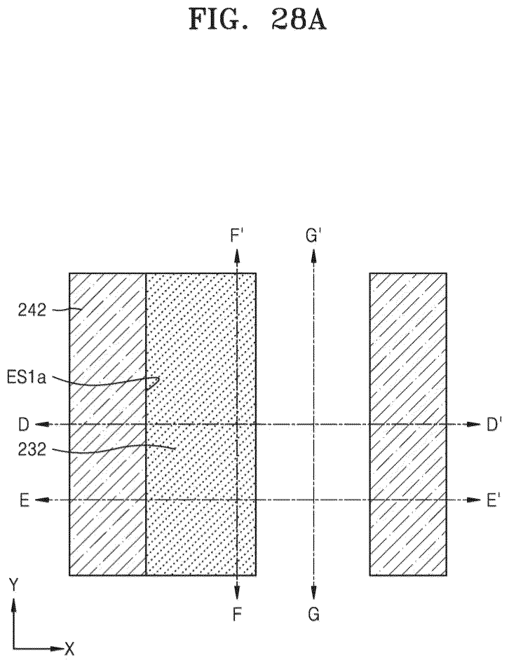

Referring to FIGS. 27A to 27G together, a gate dielectric film 272 is provided to cover the surfaces of the plurality of semiconductor layers 220, which are not covered by the plurality of sacrificial layers 242 and the second insulating layer 232. The gate dielectric film 272 may cover the upper surface of each of the plurality of semiconductor layers 220 and both sides of each of the plurality of semiconductor layers 220 in the second horizontal direction (Y direction). In some example embodiments, the gate dielectric film 272 may further cover the upper surfaces of the plurality of first insulating layers 210, which are not covered by the plurality of semiconductor layers 220, the plurality of sacrificial layers 242, and the second insulating layer 232.

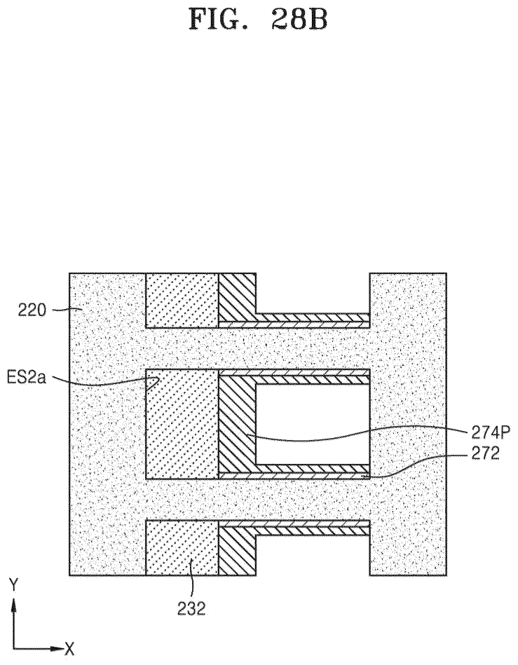

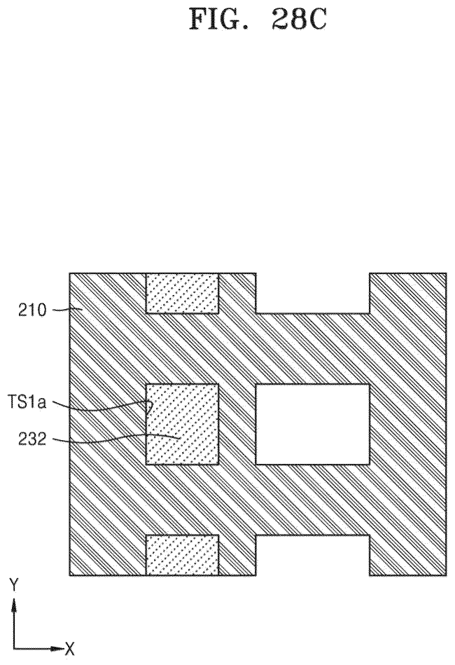

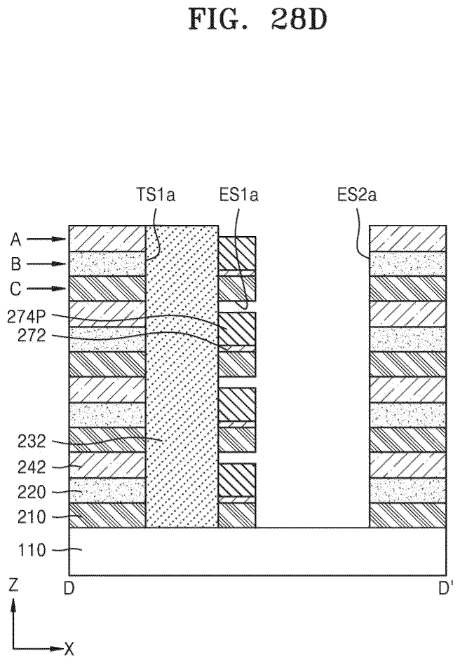

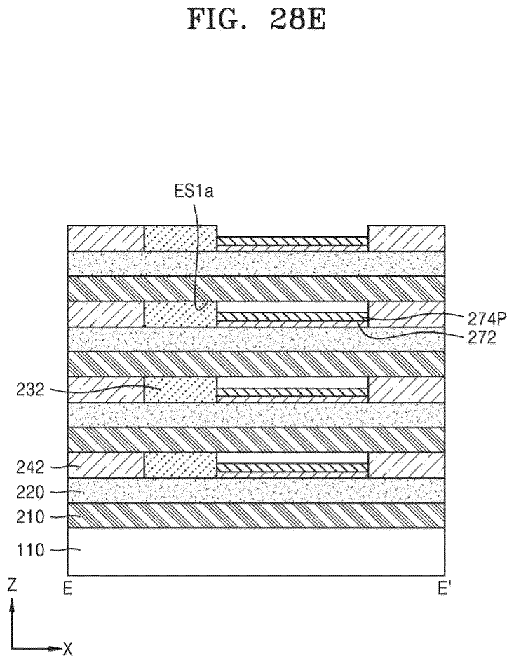

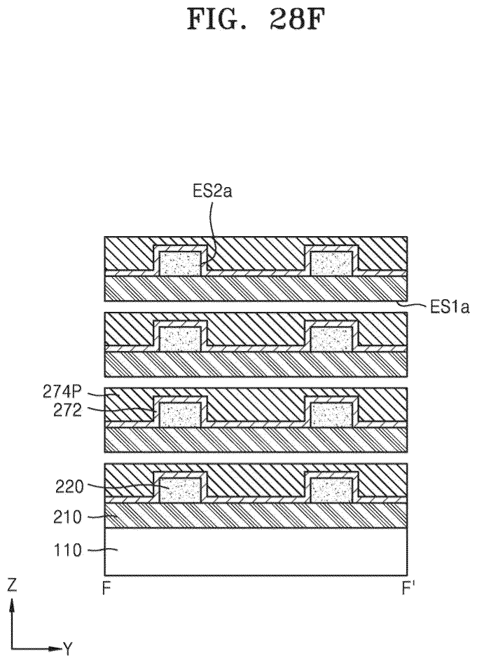

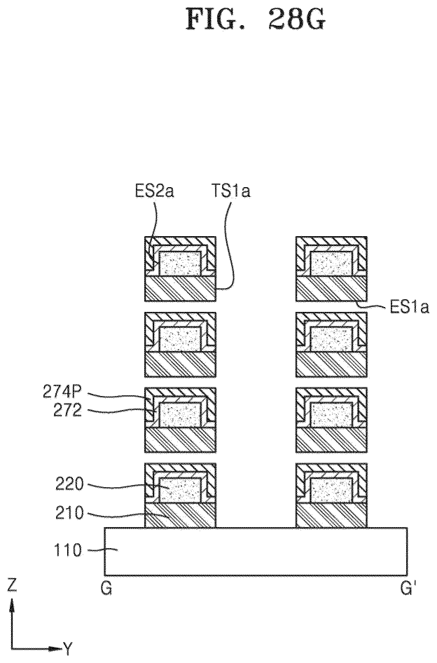

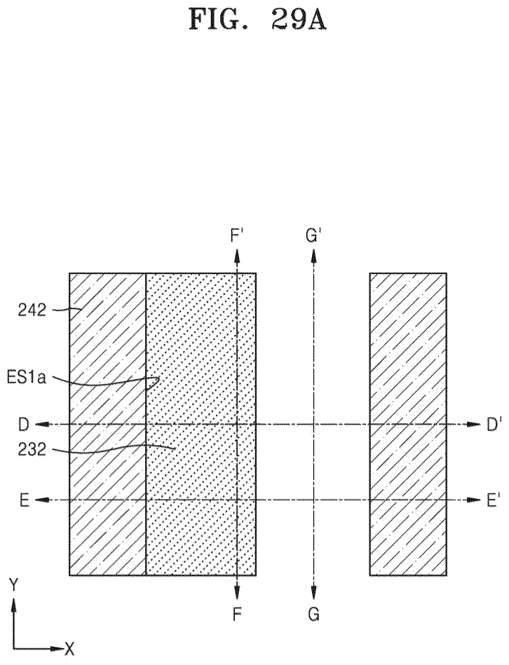

Referring to FIGS. 28A to 28G together, a gate material layer 274P is provided to cover the gate dielectric film 272. The gate material layer 274P may cover, with the gate dielectric film 272 therebetween, the upper surface of each of the plurality of semiconductor layers 220 and both sides of each of the plurality of semiconductor layers 220 in the second horizontal direction (Y direction). In some example embodiments, the gate material layer 274P may further cover a portion of the gate dielectric film 272 which covers the upper surfaces of the plurality of first insulating layers 210.

The gate material layer 274P may cover the semiconductor layer 220 disposed on one first insulating layer 210 among the plurality of first insulating layers 210 but may not be in contact with the lower surface of another first insulating layer 210 located above the semiconductor layer 220. For example, the gate material layer 274P is located between two first insulating layers 210 adjacent to each other in the vertical direction (Z direction), and the gate material layer 274P may have the upper surface at a lower vertical level than the lower surface of the upper first insulating layer 210 and may thus not be in contact with the upper first insulating layer 210.

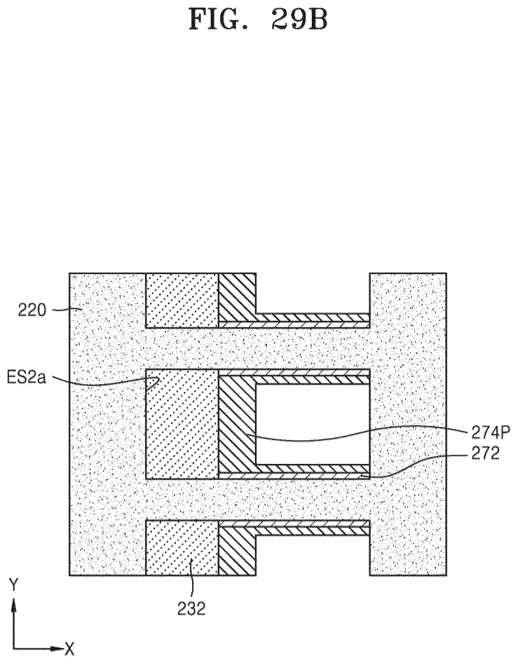

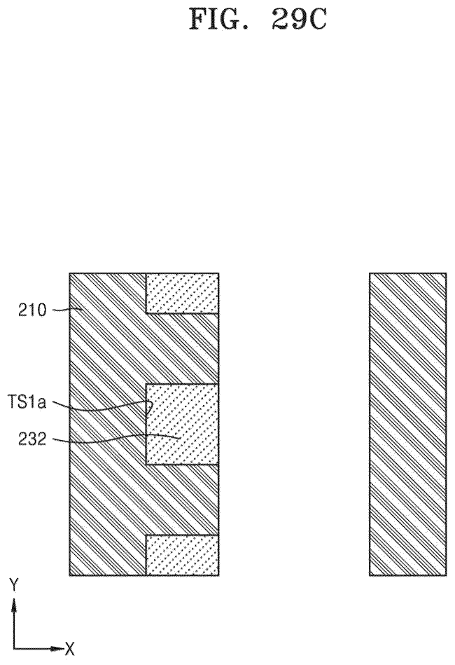

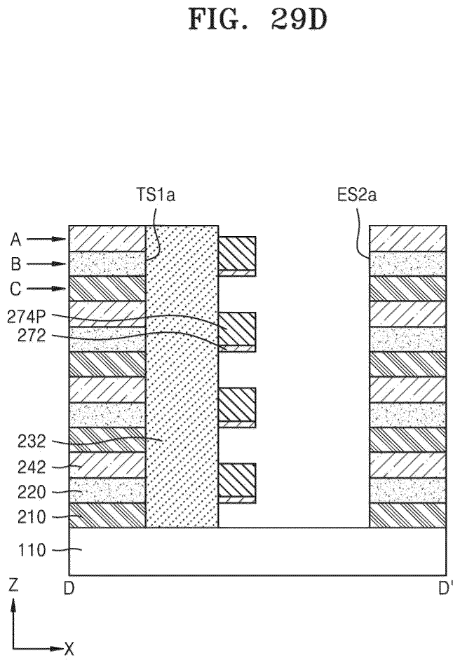

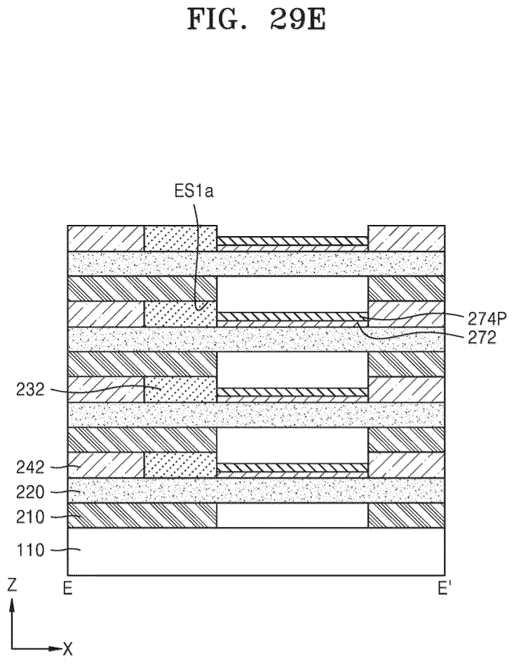

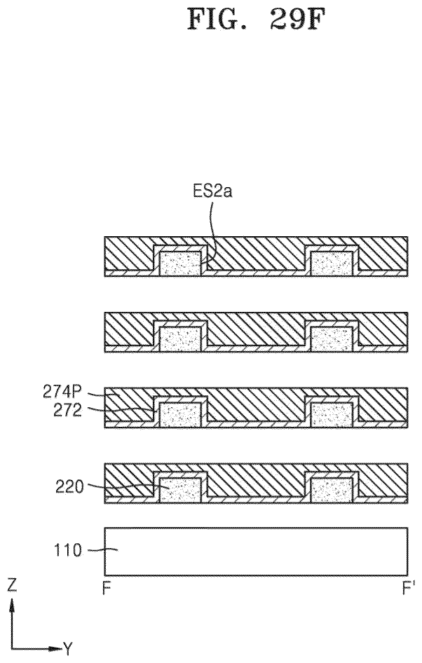

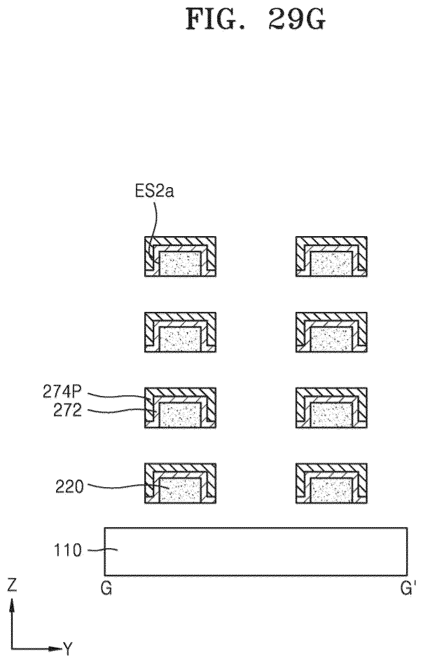

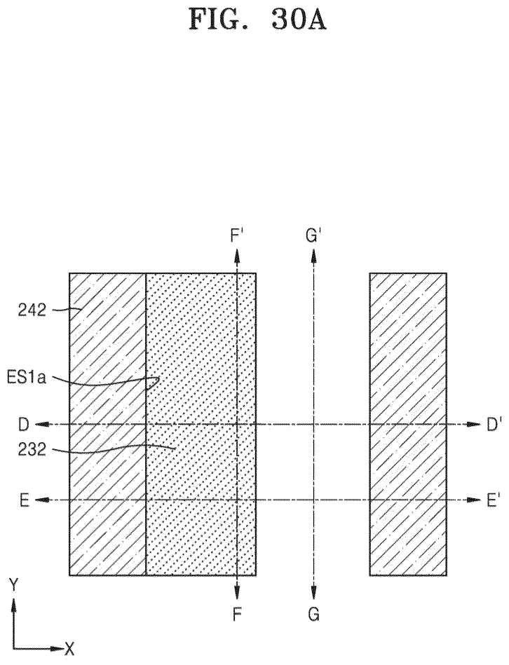

Referring to FIGS. 29A to 29G together, each of the gate dielectric film 272, the gate material layer 274P, and the plurality of first insulating layers 210 located below the portion of the semiconductor layer 220 covered by the gate dielectric film 272 and the gate material layer 274P is partially removed. For example, through an etching operation. As a portion of each of the plurality of first insulating layers 210 is removed, the lower surface of the gate dielectric film 272 and the lower surface of the portion of the semiconductor layer 220 covered by the gate dielectric film 272 and the gate material layer 274P may be exposed.

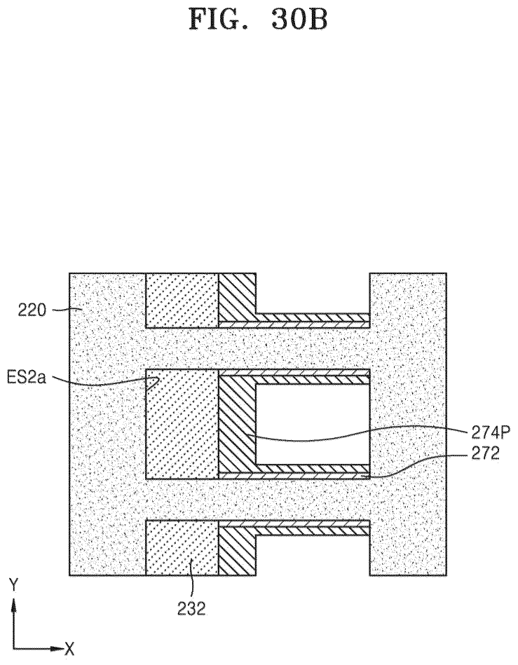

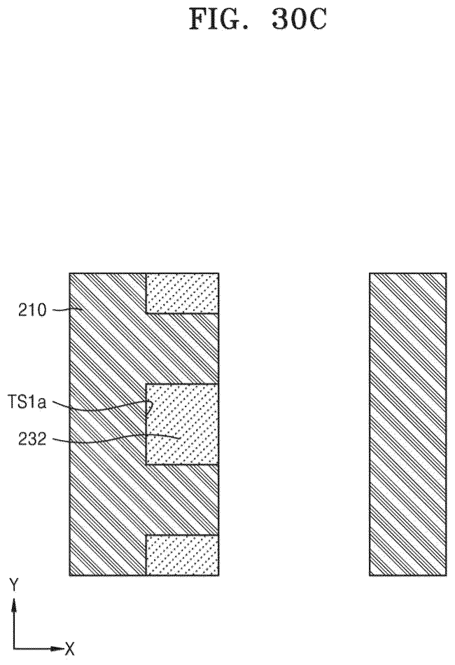

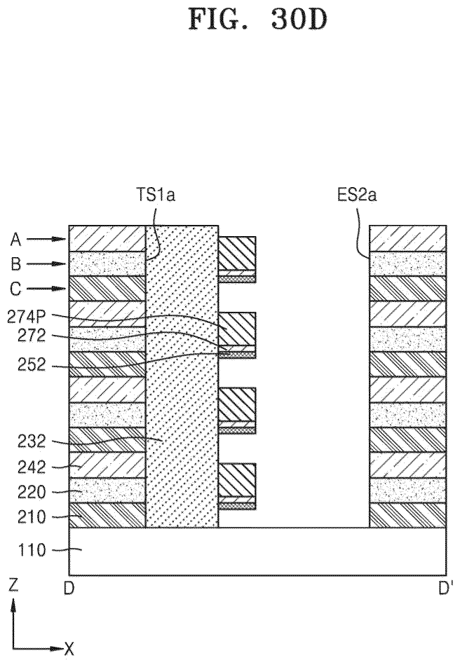

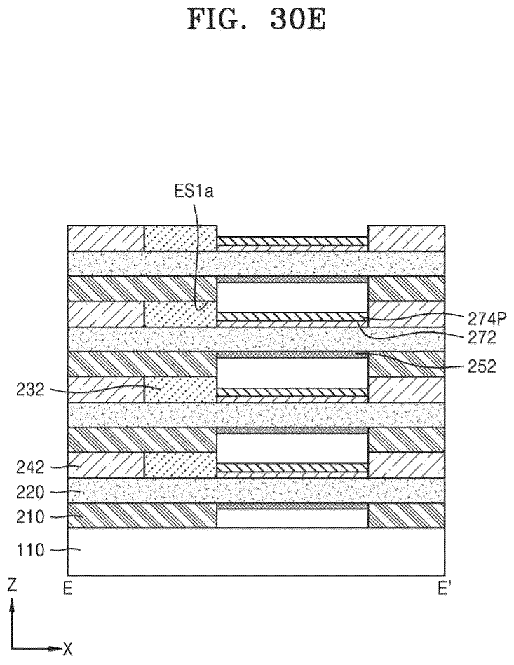

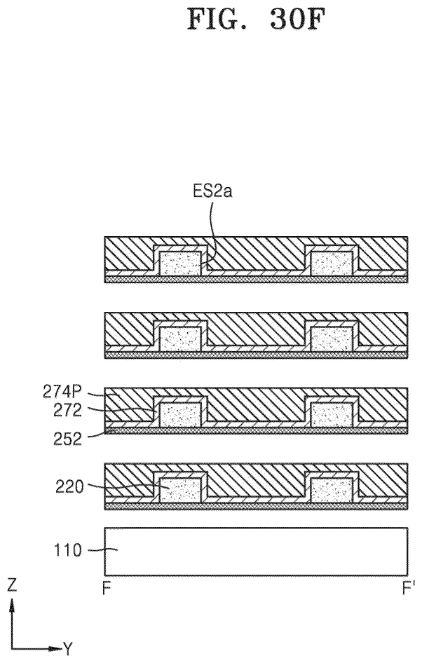

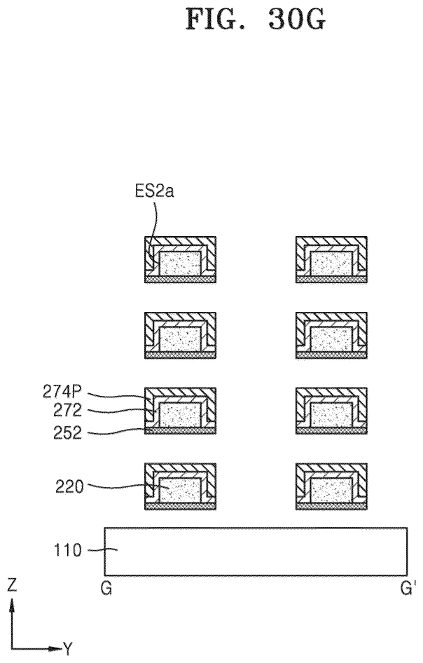

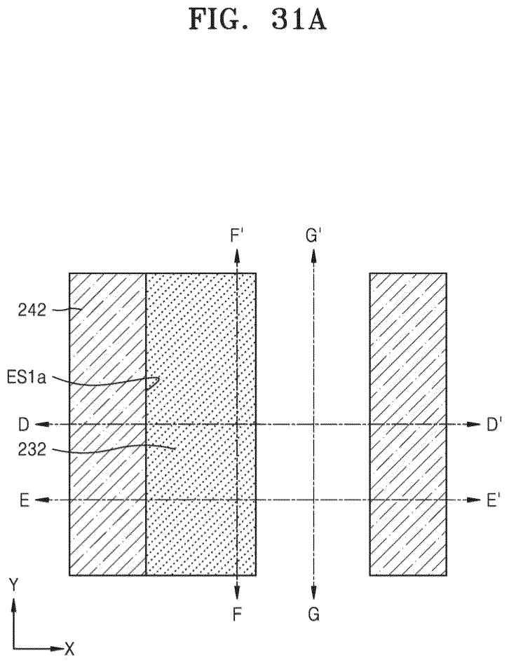

Referring to FIGS. 30A to 30G, a back gate dielectric film 252 is formed below the lower surface of the gate dielectric film 272 and the lower surface of the portion of the semiconductor layer 220 covered by the gate dielectric film 272 and the gate material layer 274P. The back gate dielectric film 252 may cover the lower surface of each of the plurality of semiconductor layers 220. In some example embodiments, the back gate dielectric film 252 may further cover the lower surface of the gate dielectric film 272.

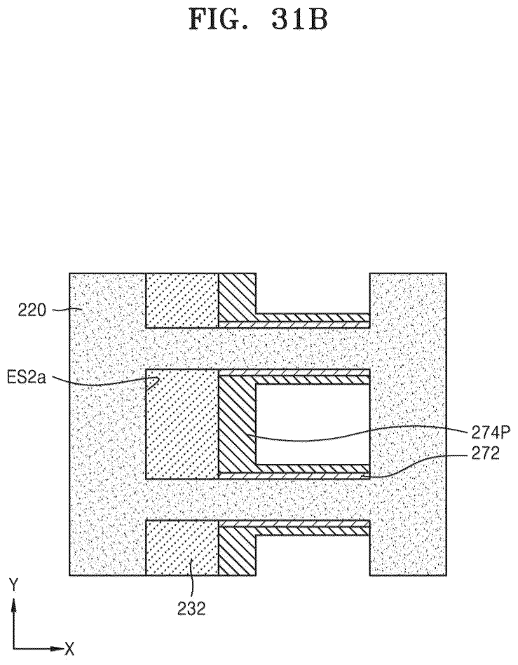

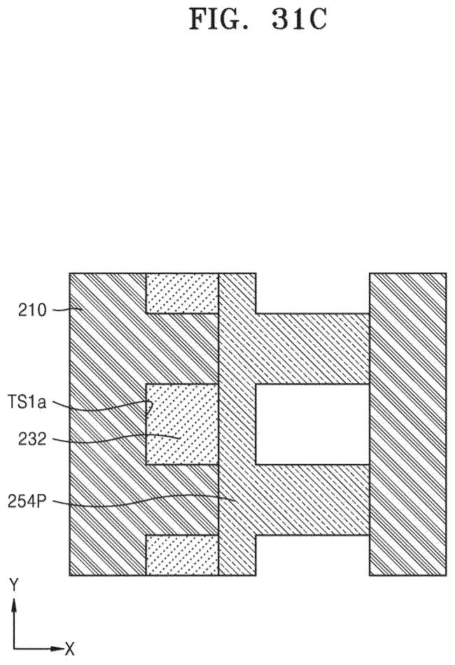

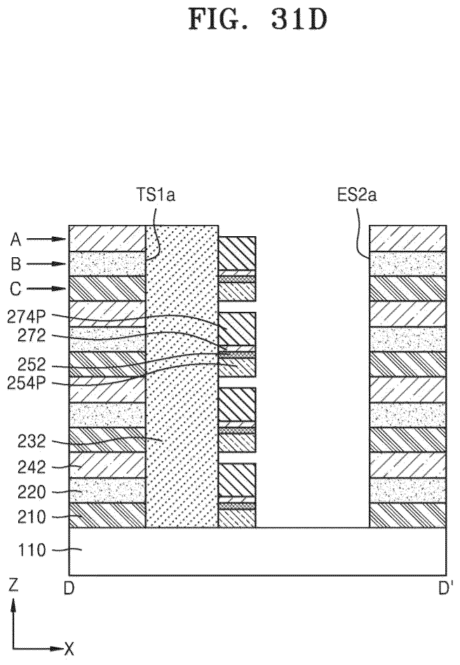

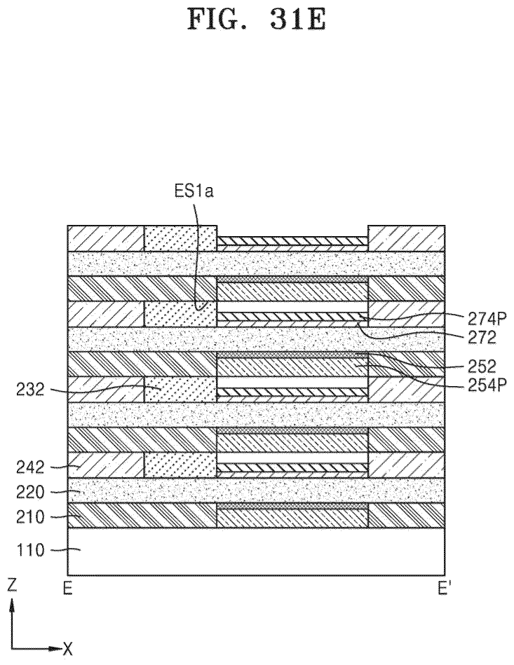

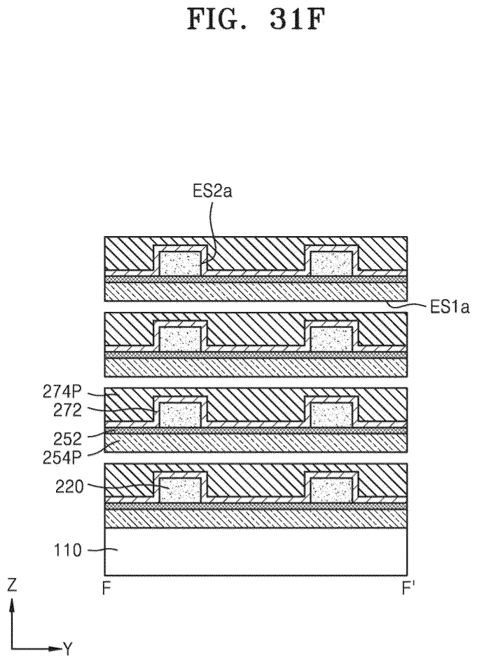

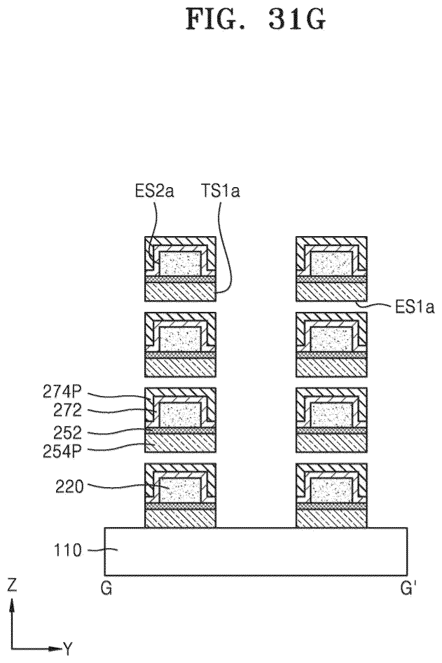

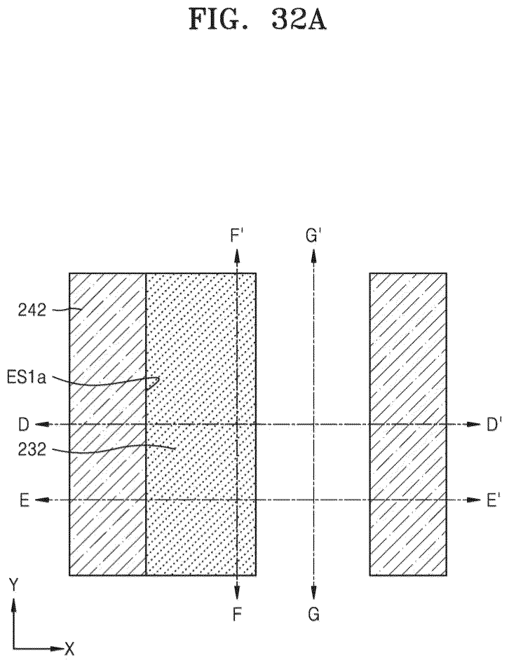

Referring to FIGS. 31A to 31G together, a back gate material layer 254P is provided to cover the bottom of the back gate dielectric film 252. The back gate material layer 254P may cover the lower surface of the gate dielectric film 272 located above the back gate material layer 254P and the lower surface of the back gate dielectric film 252, which covers the lower surface of the portion of the semiconductor layer 220 covered by the gate dielectric film 272 and the gate material layer 274P. However, the back gate material layer 254P may not be in contact with the gate material layer 274P located below the back gate material layer 254P. For example, the back gate material layer 254P has a lower surface at a higher vertical level than the upper surface of the gate material layer 274P located below the back gate material layer 254P and may thus not be in contact with the gate material layer 274P located below the back gate material layer 254P.

Each of the gate dielectric film 272, the gate material layer 274P, the back gate dielectric film 252, and the back gate material layer 254P may include a first portion extending in the second horizontal direction (Y direction) and second portions protruding from the first portion and extending in the first horizontal direction (X direction). The gate dielectric film 272, the gate material layer 274P, the back gate dielectric film 252, and the back gate material layer 254P may overlap each other in the vertical direction (Z direction).

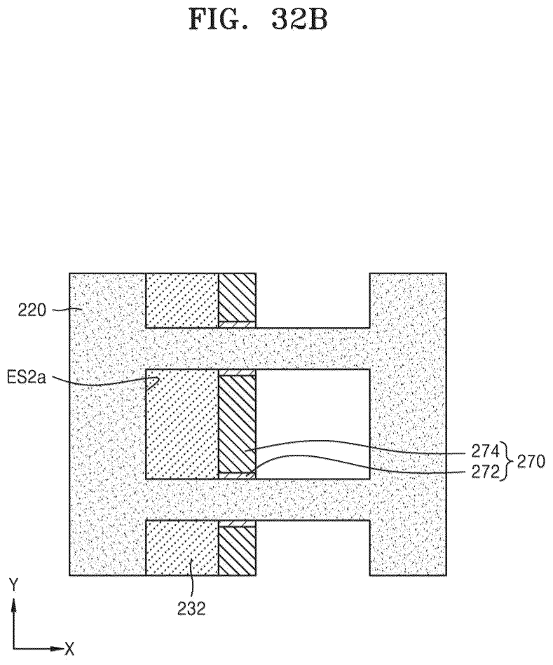

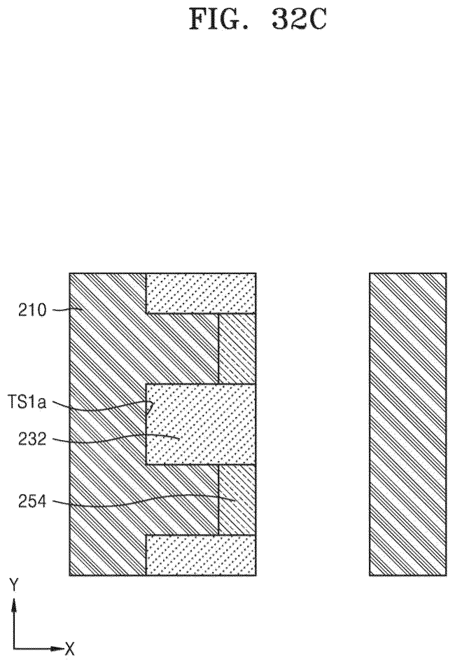

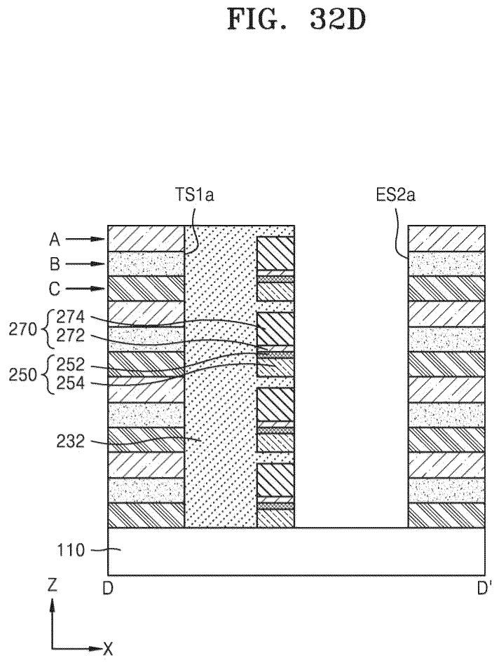

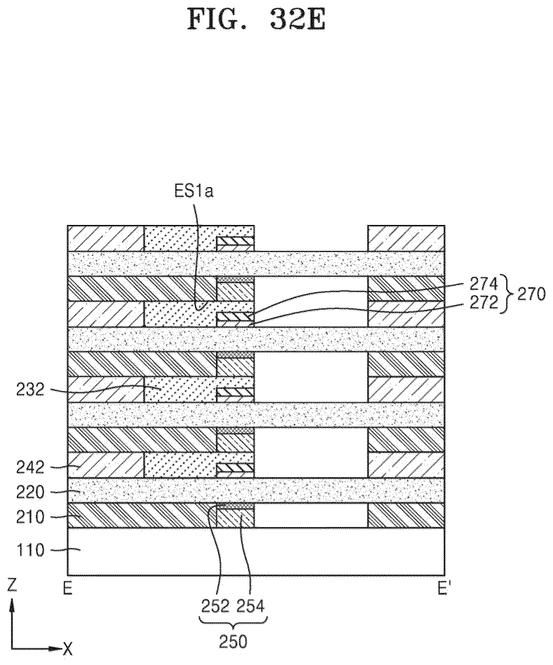

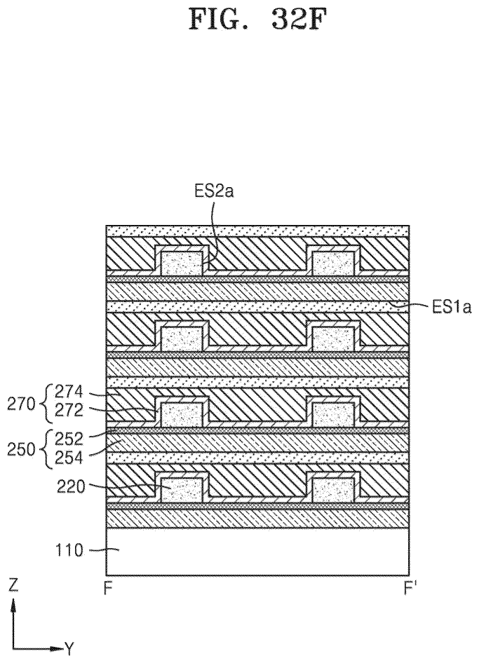

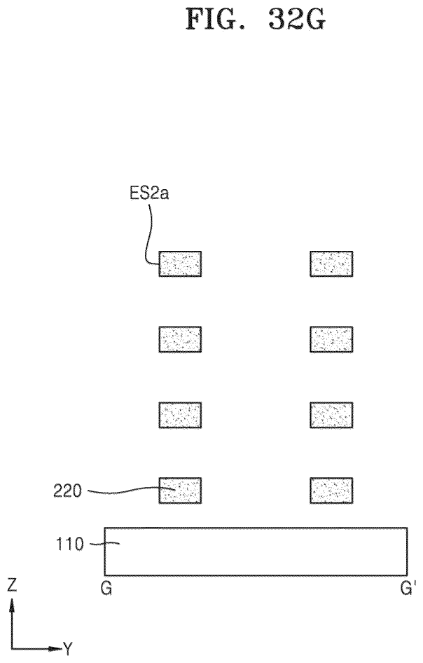

Referring to FIGS. 31A to 31G and FIGS. 32A to 32G together, for each of the gate dielectric film 272, the gate material layer 274P, the back gate dielectric film 252, and the back gate material layer 254P, the second portions protruding from the first portion and extending in the first horizontal direction (X direction) are removed, for example, through an etching operation, and the first portion extending in the second horizontal direction (Y direction) remains. The gate dielectric film 272 and the gate electrode film 274, which is the first portion, that is, the remaining portion of the gate material layer 274P, constitute a gate structure 270. The back gate dielectric film 252 and the back gate electrode film 254, which is the first portion, that is, the remaining portion of the back gate material layer 254P, constitute a back gate structure 250.

A plurality of gate structures 270 and a plurality of back gate structures 250 may extend in the second horizontal direction (Y direction). The plurality of back gate structures 250 and the plurality of gate structures 270 may be alternately arranged in the vertical direction (Z direction) on the substrate 110.

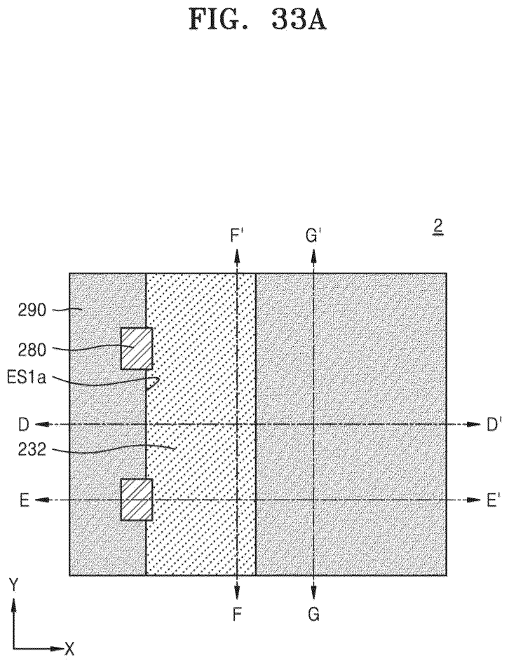

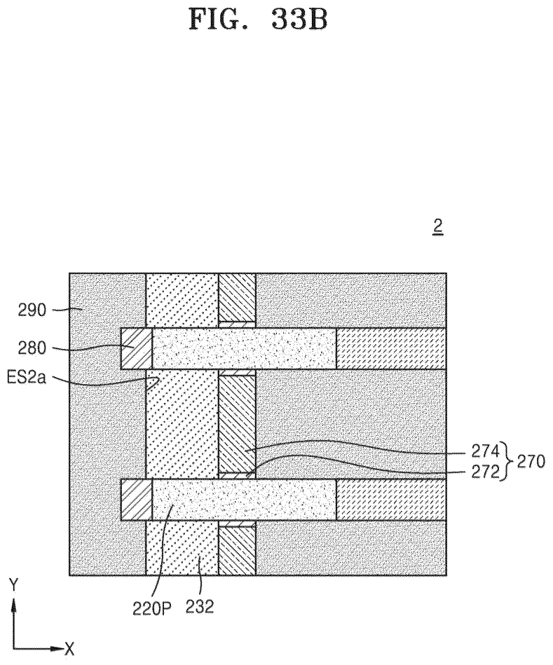

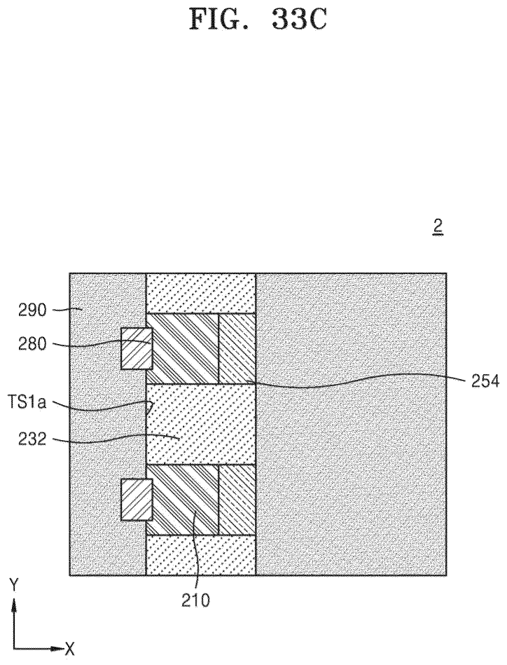

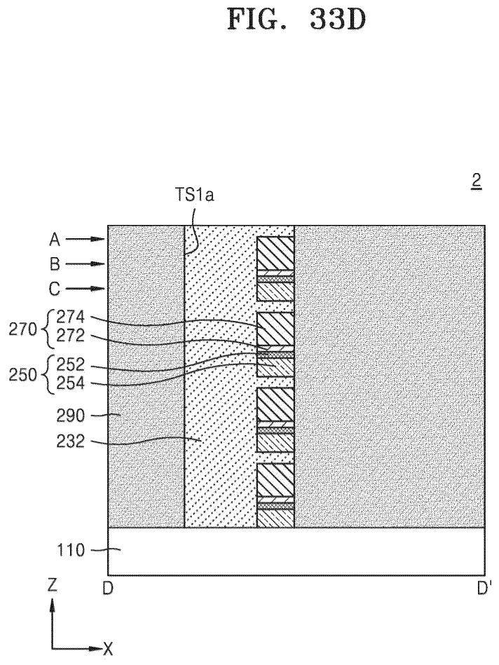

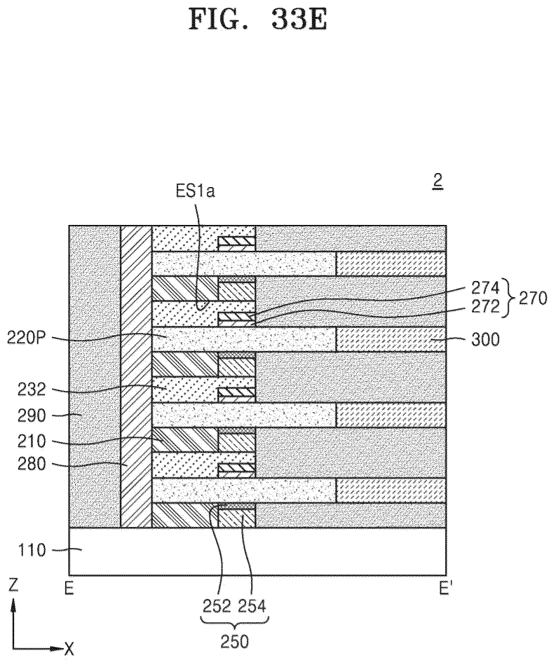

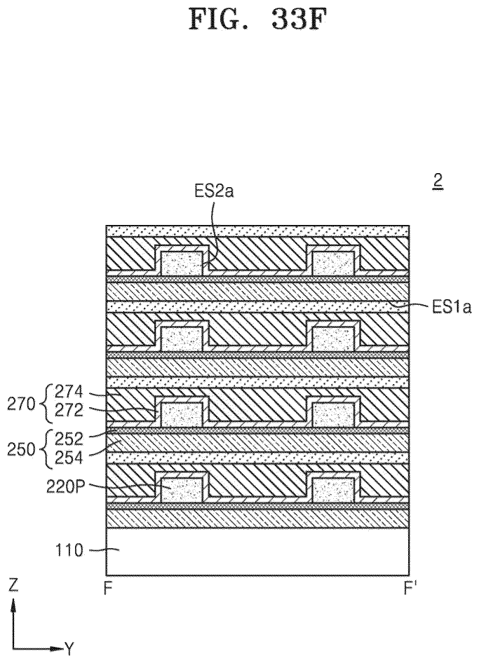

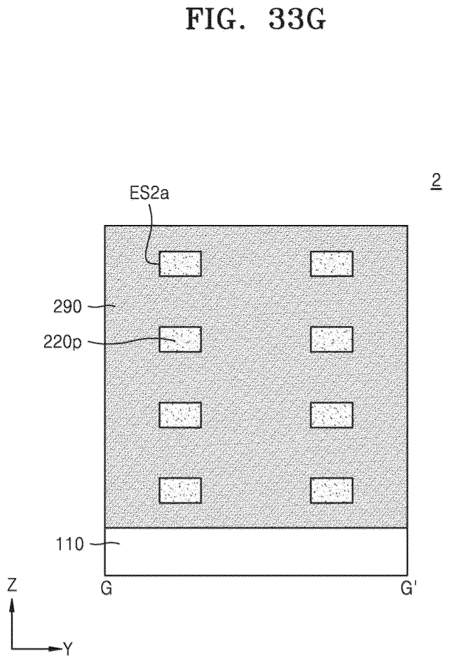

FIG. 33A to 33G are diagrams showing a semiconductor memory device 2 according to example embodiments. Specifically, FIG. 33A is a horizontal cross-sectional view showing a portion of the semiconductor memory device 2 taken along vertical level A of FIG. 33D, FIG. 33B is a horizontal cross-sectional view showing a portion of the semiconductor memory device 2 taken along vertical level B of FIG. 33D, FIG. 33C is a horizontal cross-sectional view showing a portion of the semiconductor memory device 2 taken along vertical level C of FIG. 33D, FIG. 33D is a vertical cross-sectional view showing a portion of the semiconductor memory device 2 taken along line D-D′ of FIG. 33A, FIG. 33E is a vertical cross-sectional view showing a portion of the semiconductor memory device 2 taken along line E-E′ of FIG. 33A, FIG. 33F is a vertical cross-sectional view showing a portion of the semiconductor memory device 2 taken along line F-F′ of FIG. 33A, and FIG. 33G is a vertical cross-sectional view showing a portion of the semiconductor memory device 2 taken along line G-G′ in FIG. 33A.

Referring to FIGS. 32A to 32G and FIGS. 33A to 33G together, the stack structures of the plurality of first insulating layers 210, the plurality of semiconductor layers 220, and the plurality of sacrificial layers 242 are removed, which are arranged on both sides in the first horizontal direction (X direction) about the plurality of gate structures 270 and the plurality of back gate structures 250. For example, removal of the layers may be performed through an etching operation. While the stack structures of the plurality of first insulating layers 210, the plurality of semiconductor layers 220, and the plurality of sacrificial layers 242 are removed which are arranged on both sides in the first horizontal direction (X direction) about the plurality of gate structures 270 and the plurality of back gate structures 250, the stacked structure of the plurality of first insulating layers 210, the plurality of semiconductor layers 220, and the plurality of sacrificial layers 242 and the portions of the plurality of semiconductor layers 220 located between the plurality of gate structures 270 and the plurality of back gate structures 250 may also be removed together. The remaining portions of the semiconductor layer 220 may form a plurality of semiconductor patterns 220P. The plurality of semiconductor patterns 220P may extend in the first horizontal direction (X direction) and be spaced apart from each other in each of the vertical direction (Z direction) and the second horizontal direction (Y direction).

In the first horizontal direction (X direction), a plurality of bit lines 280 are formed on one side of the plurality of semiconductor patterns 220P, a plurality of cell capacitors 300 are formed on the other side of the plurality of semiconductor patterns 220P, and a third filling insulating layer 290 surrounds the plurality of bit lines 280 and the plurality of cell capacitors 300. Consequently, the semiconductor memory device 2 may be formed.

The plurality of bit lines 280 may extend in the vertical direction (Z direction) and be spaced apart from each other in the second horizontal direction (Y direction). Each of the plurality of bit lines 280 may be connected to one side of each of the semiconductor patterns 220P that are spaced apart from each other in the vertical direction (Z direction). The bit line 280 may correspond to the bit line BL shown in FIG. 21. The plurality of cell capacitors 300 may extend in the first horizontal direction (X direction) and be spaced apart from each other in each of the vertical direction (Z direction) and the second horizontal direction (Y direction). The plurality of cell capacitors 300 may be connected to the other side of the plurality of semiconductor patterns 220P. The bit line 280, the semiconductor pattern 220P, and the cell capacitor 300, which are connected to each other in a plan view, may be sequentially arranged in the first horizontal direction (X direction). The cell capacitor 300 may correspond to the cell capacitor CAP shown in FIG. 21.

The cell capacitor 300 may include a lower electrode layer connected to the other side of the semiconductor pattern 220P and extending in the first horizontal direction (X direction), a capacitor dielectric film covering the lower electrode layer, and an upper electrode layer covering the capacitor dielectric film. The lower electrode layer and the upper electrode layer of the cell capacitor 300 may correspond to the first electrode and the second electrode of the cell capacitor CAP, respectively, shown in FIG. 21. The capacitor dielectric film may be located between the lower electrode layer and the upper electrode layer. The semiconductor pattern 220P, the gate dielectric film 272, and the gate electrode film 274 may constitute the cell transistor CTR shown in FIG. 21.

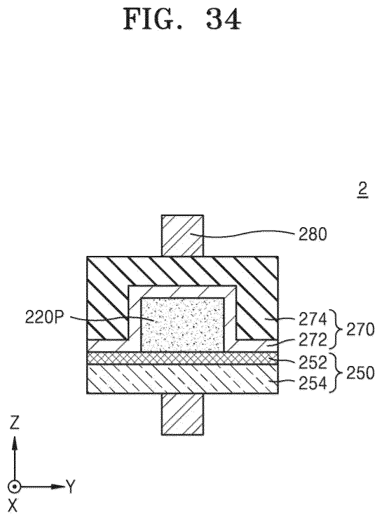

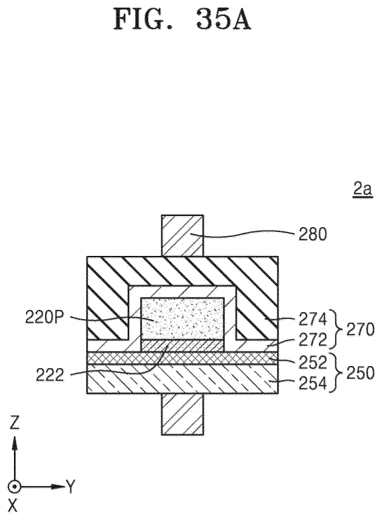

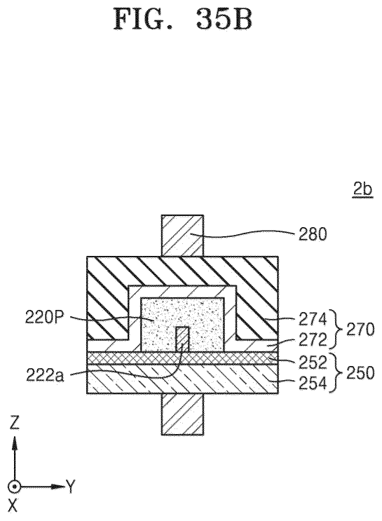

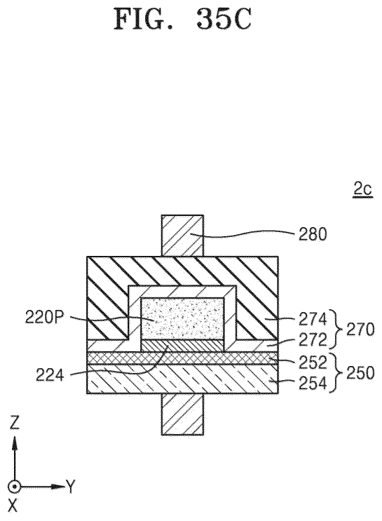

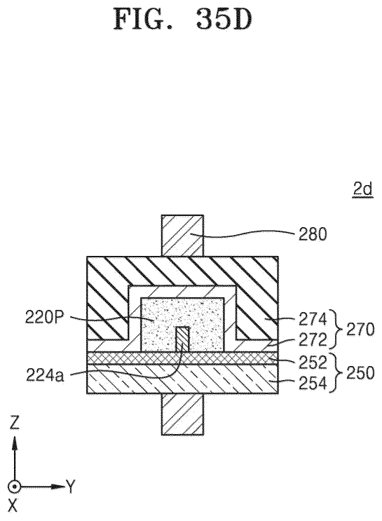

FIG. 34 and FIGS. 35A to 35D are partial enlarged views of semiconductor memory devices according to example embodiments.

Referring to FIGS. 33A to 33G and FIG. 34 together, the semiconductor memory device 2 may include the plurality of gate structures 270 extending in the second horizontal direction (Y direction), the plurality of back gate structures 250 extending in the second horizontal direction (Y direction), the plurality of bit lines 280 extending in the vertical direction (Z direction), and the plurality of semiconductor patterns 220P connected to the plurality of bit lines 280 and extending in the first horizontal direction (X direction). The semiconductor memory device 2 may include a plurality of cell capacitors 300. One end of the plurality of semiconductor patterns 220P is connected to the plurality of bit lines 280, and the other end of the plurality of semiconductor patterns 220P, which is opposite to the one end of the plurality of semiconductor patterns 220P, is connected to the plurality of cell capacitors 300. The plurality of back gate structures 250 and the plurality of gate structures 270 may be alternately arranged in the vertical direction (Z direction) on the substrate 110.

The back gate structure 250 may cover one side surface of the semiconductor pattern 220P and the gate structure 270 may cover the remaining side surfaces of the semiconductor pattern 220P. For example, the back gate dielectric film 252 may be in contact with one side surface of the semiconductor pattern 220P, and the gate dielectric film 272 may be in contact with the remaining side surfaces of the semiconductor pattern 220P. For example, the back gate electrode film 254 may cover one side surface of the semiconductor pattern 220P with the back gate dielectric film 252 therebetween, and the gate electrode film 274 may cover the other side surfaces of the semiconductor pattern 220P with the gate dielectric film 272 therebetween.

For example, in a cross-section perpendicular to the direction in which the semiconductor pattern 220P extends, that is, the Y-Z cross-section perpendicular to the first horizontal direction (X direction), the back gate structure 250 may cover one of the edges of the semiconductor pattern 220P, and the gate structure 270 may cover the remaining edges of the semiconductor pattern 220P other than the one edge of the semiconductor pattern 220P. For example, the lower surface of one semiconductor pattern 220P located above the back gate structure 250 may be in contact with the upper surface of the back gate structure 250. Also, the remaining surfaces of the one semiconductor pattern 220P, that is, the upper surface of the one semiconductor pattern 220P and both side surfaces of the one semiconductor pattern 220P in the second horizontal direction (Y direction), may be in contact with one gate structure 270 located above the back gate structure 250.

Referring to FIG. 35A, a semiconductor memory device 2a may further include a sub insulating layer 222, in contrast to the semiconductor memory device 2 shown in FIG. 34. The sub insulating layer 222 may be located between the back gate structure 250 and the semiconductor pattern 220P. For example, the back gate structure 250 and the semiconductor pattern 220P may be spaced apart from each other with the sub insulating layer 222 therebetween. The sub insulating layer 222 may be formed by depositing, on a lower portion of the semiconductor layer 220, an insulating material layer corresponding to the sub insulating layer 222 during the process of forming the semiconductor layer 220 shown in FIGS. 22A to 22G.

The semiconductor memory device 2a may include a semiconductor pattern 220P having a relatively small thickness due to the sub insulating layer 222. In some example embodiments, the semiconductor pattern 220P may have a thickness of about 5 nm or less. The semiconductor memory device 2a includes the semiconductor pattern 220P having a relatively small thickness, and thus, the occurrence of a floating body effect may be prevented to improve the operation reliability.

Referring to FIG. 35B, a semiconductor memory device 2b may further include a sub insulating layer 222a, in contrast to the semiconductor memory device 2 shown in FIG. 34. The sub insulating layer 222a may be located between the back gate structure 250 and the semiconductor pattern 220P. The sub insulating layer 222a extends from the back gate structure 250 into the semiconductor pattern 220P but may not extend to the gate structure 270. For example, the semiconductor pattern 220P may cover the upper surface of the sub insulating layer 222a and both side surfaces of the sub insulating layer 222a in the second horizontal direction (Y direction). The sub insulating layer 222a may be formed by depositing, on a lower portion of the semiconductor layer 220, an insulating material layer corresponding to the sub insulating layer 222a during the process of forming the semiconductor layer 220 shown in FIGS. 22A to 22G.

The semiconductor memory device 2b may include a semiconductor pattern 220P having a relatively small thickness due to the sub insulating layer 222a. In some example embodiments, the semiconductor pattern 220P may have a thickness of about 5 nm or less between the sub insulating layer 222a and the gate structure 270. The semiconductor memory device 2b includes the semiconductor pattern 220P having a relatively small thickness, and thus, the occurrence of a floating body effect may be prevented to improve the operation reliability.

Referring to FIG. 35C, a semiconductor memory device 2c may further include a sub semiconductor layer 224, in contrast to the semiconductor memory device 2 shown in FIG. 34. The sub semiconductor layer 224 may be located between the back gate structure 250 and the semiconductor pattern 220P. For example, the back gate structure 250 and the semiconductor pattern 220P may be spaced apart from each other with the sub semiconductor layer 224 therebetween. The sub semiconductor layer 224 may be formed by depositing, on a lower portion of the semiconductor layer 220, a semiconductor material layer corresponding to the sub semiconductor layer 224 during the process of forming the semiconductor layer 220 shown in FIGS. 22A to 22G. The sub semiconductor layer 224 may include a different semiconductor material from the semiconductor pattern 220P.

In some example embodiments, the sub semiconductor layer 224 may include a semiconductor material having a band gap smaller than that of the semiconductor material of the semiconductor pattern 220P. For example, the sub semiconductor layer 224 may include SiGe. When the semiconductor pattern 220P and the sub semiconductor layer 224 come into contact with each other, the band gap of a balance band becomes smaller than the band gap of a conduction band. Accordingly, the movement of holes from the semiconductor pattern 220P to the sub semiconductor layer 224 may be facilitated, and the operation reliability of the semiconductor memory device 2c may be improved.

Referring to FIG. 35D, a semiconductor memory device 2d may further include a sub semiconductor layer 224a, in contrast to the semiconductor memory device 2 shown in FIG. 34. The sub semiconductor layer 224a may be located between the back gate structure 250 and the semiconductor pattern 220P. The sub semiconductor layer 224a extends from the back gate structure 250 into the semiconductor pattern 220P but may not extend to the gate structure 270. For example, the semiconductor pattern 220P may cover the upper surface of the sub semiconductor layer 224a and both side surfaces of the sub semiconductor layer 224a in the second horizontal direction (Y direction). The sub semiconductor layer 224a may be formed by depositing, on a lower portion of the semiconductor layer 220, a semiconductor material layer corresponding to the sub semiconductor layer 224a during the process of forming the semiconductor layer 220 shown in FIGS. 22A to 22G. The sub semiconductor layer 224a may include a different semiconductor material from the semiconductor pattern 220P.

In some example embodiments, the sub semiconductor layer 224a may include a semiconductor material having a band gap smaller than that of the semiconductor material of the semiconductor pattern 220P. For example, the sub semiconductor layer 224a may include SiGe. When the semiconductor pattern 220P and the sub semiconductor layer 224a come into contact with each other, the band gap of a balance band becomes smaller than the band gap of a conduction band. Accordingly, the movement of holes from the semiconductor pattern 220P to the sub semiconductor layer 224a may be facilitated, and the operation reliability of the semiconductor memory device 2d may be improved.

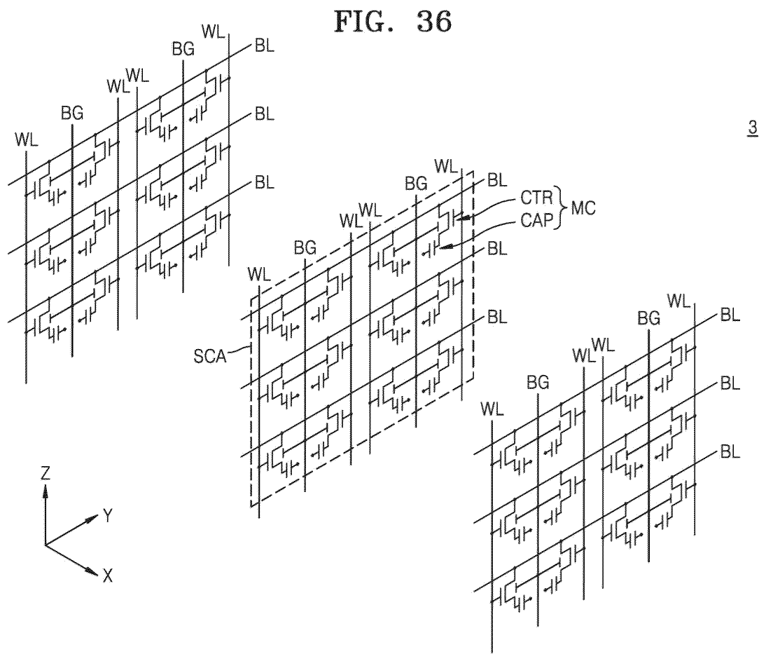

FIG. 36 is an equivalent circuit diagram showing a cell array of a semiconductor memory device 3 according to example embodiments.

Referring to FIG. 36, the cell array of the semiconductor memory device 3 according to example embodiments may include a plurality of sub cell arrays SCA. The plurality of sub cell arrays SCA may be arranged in a first horizontal direction (X direction). Each of the sub cell arrays SCA may include a plurality of bit lines BL, a plurality of word lines WL, a plurality of back gate lines BG, and a plurality of cell transistors CTR. One cell transistor CTR may be located between one word line WL and one bit line BL.

The plurality of word lines WL may extend in the vertical direction (Z direction). The word lines WL in one sub cell array SCA may be spaced apart from each other in the second horizontal direction (Y direction). The plurality of back gate lines BG may extend in the vertical direction (Z direction). The back gate lines BG in one sub cell array SCA may be spaced apart from each other in the second horizontal direction (Y direction). The word lines WL and the back gate lines BG in one sub cell array SCA may be spaced apart from each other in the second horizontal direction (Y direction) and extend parallel to each other in the vertical direction (Z direction). Each of the plurality of back gate lines BG may be located between a pair of neighboring word lines WL among the word lines WL. In one sub cell array SCA, the number of word lines WL may be approximately twice the number of back gate lines BG. For example, the word lines WL and the back gate lines BG in one sub cell array SCA may be configured such that two word lines WL among the word lines WL and one back gate line BG among the back gate lines BG are alternately arranged in the second horizontal direction (Y direction). In this regard, one back gate line BG among the back gate lines BG may be located between two word lines WL adjacent to each other in the second horizontal direction (Y direction) among the word lines WL in one sub cell array SCA. Also, two word lines WL among the word lines WL may be arranged between two back gate lines BG adjacent to each other in the second horizontal direction (Y direction) among the back gate lines BG in the one sub cell array SCA.

The plurality of bit lines BL may extend in the second horizontal direction (Y direction). The bit lines BL in one sub cell array SCA may be spaced apart from each other in the vertical direction (Z direction).

A gate of the cell transistor CTR may be connected to the word line WL and a source of the cell transistor CTR may be connected to the bit line BL. The cell transistor CTR may be connected to a cell capacitor CAP. A drain of the cell transistor CTR may be connected to a first electrode of the cell capacitor CAP, and a second electrode of the cell capacitor CAP may be connected to a ground wire PP.

The semiconductor memory device 3 may include the plurality of sub cell arrays SCA, each of which includes a plurality of memory cells MC spaced apart from each other in the second horizontal direction (Y direction) and the vertical direction (Z direction) and arranged in rows and columns, the plurality of bit lines BL connected to the cell transistors CTR of the memory cells MC arranged in the second horizontal direction (Y direction), extending in the second horizontal direction (Y direction), and spaced apart from each other in the vertical direction (Z direction), and the plurality of word lines WL extending in the vertical direction (Z direction) and spaced apart from each other in the second horizontal direction (Y direction). The plurality of sub cell arrays SCA may be arranged in the first horizontal direction (X direction).

The first horizontal direction (X direction), the second horizontal direction (Y direction), and the vertical direction (Z direction) may be referred to as a first direction, a second direction, and a third direction, respectively. The first direction, the second direction, and the third direction may be perpendicular to each other.

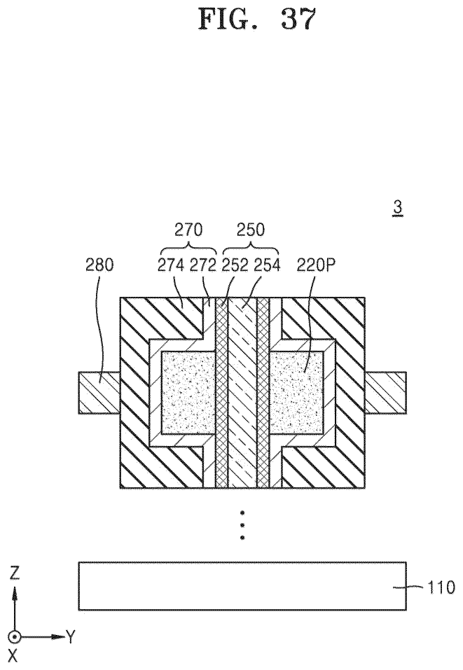

FIG. 37 is a partial enlarged view of the semiconductor memory device 3 according to example embodiments.

Referring to FIGS. 36 and 37 together, the semiconductor memory device 3 may include a plurality of gate structures 270 extending in the vertical direction (Z direction) on the substrate 110, a plurality of bit lines 280 extending in the second horizontal direction (Y direction), and a plurality of semiconductor patterns 220P connected to the plurality of bit lines 280 and extending in the first horizontal direction (X direction). The semiconductor memory device 3 may include a plurality of cell capacitors CAP. One end of the plurality of semiconductor patterns 220P is connected to the plurality of bit lines 280, and the other end of the plurality of semiconductor patterns 220P, which is opposite to the one end of the plurality of semiconductor patterns 220P, is connected to the plurality of cell capacitors CAP. The semiconductor memory device 3 may further include the plurality of back gate structures 250 each located between two gate structures 270 adjacent to each other in the second horizontal direction (Y direction) and extending in the vertical direction (Z direction).

The back gate structure 250 may cover one side surface of the semiconductor pattern 220P and the gate structure 270 may cover the remaining side surfaces of the semiconductor pattern 220P. For example, the back gate dielectric film 252 may be in contact with one side surface of the semiconductor pattern 220P, and the gate dielectric film 272 may be in contact with the remaining side surfaces of the semiconductor pattern 220P. For example, the back gate electrode film 254 may cover one side surface of the semiconductor pattern 220P with the back gate dielectric film 252 therebetween, and the gate electrode film 274 may cover the other side surfaces of the semiconductor pattern 220P with the gate dielectric film 272 therebetween.

For example, in a cross-section perpendicular to the direction in which the semiconductor pattern 220P extends, that is, the Y-Z cross-section perpendicular to the first horizontal direction (X direction), the back gate structure 250 may cover one of the edges of the semiconductor pattern 220P, and the gate structure 270 may cover the remaining edges of the semiconductor pattern 220P other than the one edge of the semiconductor pattern 220P. The back gate structure 250 may be in contact with each of the two semiconductor patterns 220P adjacent to each other in the second horizontal direction (Y direction).

For example, in the Y-Z cross-section, the right side surface of one semiconductor pattern 220P located on the left side of the back gate structure 250 may be in contact with the left side surface of the back gate structure 250. Also, the remaining surfaces of the one semiconductor pattern 220P, that is, the left side surface, the upper surface, and the lower surface of the one semiconductor pattern 220P, may be in contact with one gate structure 270 located on the left side of the back gate structure 250. For example, the left side surface of another semiconductor pattern 220P located on the right side of the back gate structure 250 may be in contact with the right side surface of the back gate structure 250. Also, the remaining surfaces of another semiconductor pattern 220P, that is, the right side surface, the upper surface, and the lower surface of another semiconductor pattern 220P, may be in contact with another gate structure 270 located on the right side of the back gate structure 250. Therefore, the back gate structure 250 may be shared by one semiconductor pattern 220P and one gate structure 270, which are arranged on the left side of the back gate structure 250, and another semiconductor pattern 220P and another gate structure 270, which are arranged on the right side of the back gate structure 250.

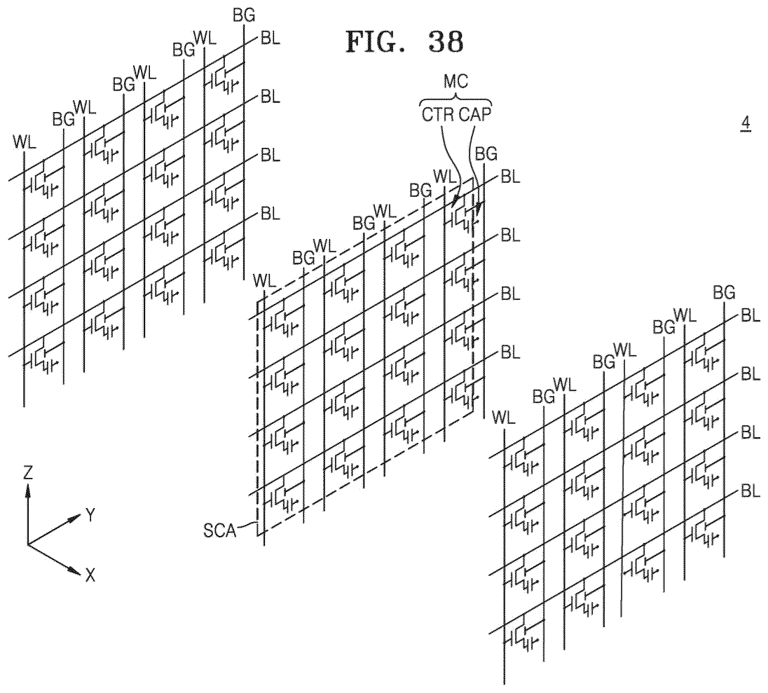

FIG. 38 is an equivalent circuit diagram showing a cell array of a semiconductor memory device 4 according to example embodiments.

The cell array of the semiconductor memory device 4 according to example embodiments may include a plurality of sub cell arrays SCA. The plurality of sub cell arrays SCA may be arranged in a first horizontal direction (X direction). Each of the sub cell arrays SCA may include a plurality of bit lines BL, a plurality of word lines WL, a plurality of back gate lines BG, and a plurality of cell transistors CTR. One cell transistor CTR may be located between one word line WL and one bit line BL.

The plurality of word lines WL may extend in the vertical direction (Z direction). The word lines WL in one sub cell array SCA may be spaced apart from each other in the second horizontal direction (Y direction). The plurality of back gate lines BG may extend in the vertical direction (Z direction). The back gate lines BG in one sub cell array SCA may be spaced apart from each other in the second horizontal direction (Y direction). The word lines WL and the back gate lines BG in one sub cell array SCA may be spaced apart from each other in the second horizontal direction (Y direction) and extend parallel to each other in the vertical direction (Z direction). In one sub cell array SCA, the number of word lines WL may be equal or substantially similar to the number of back gate lines BG. For example, the word lines WL and the back gate lines BG in one sub cell array SCA may be alternately arranged in the second horizontal direction (Y direction). The bit lines BL in one sub cell array SCA may be spaced apart from each other in the vertical direction (Z direction).

A gate of the cell transistor CTR may be connected to the word line WL and a source of the cell transistor CTR may be connected to the bit line BL. The cell transistor CTR may be connected to a cell capacitor CAP. A drain of the cell transistor CTR may be connected to a first electrode of the cell capacitor CAP, and a second electrode of the cell capacitor CAP may be connected to a ground wire PP.

The semiconductor memory device 4 may include the plurality of sub cell arrays SCA, each of which includes a plurality of memory cells MC spaced apart from each other in the second horizontal direction (Y direction) and the vertical direction (Z direction) and arranged in rows and columns, the plurality of bit lines BL connected to the cell transistors CTR of the memory cells MC arranged in the second horizontal direction (Y direction), extending in the second horizontal direction (Y direction), and spaced apart from each other in the vertical direction (Z direction), and the plurality of word lines WL extending in the vertical direction (Z direction) and spaced apart from each other in the second horizontal direction (Y direction). The plurality of sub cell arrays SCA may be arranged in the first horizontal direction (X direction).

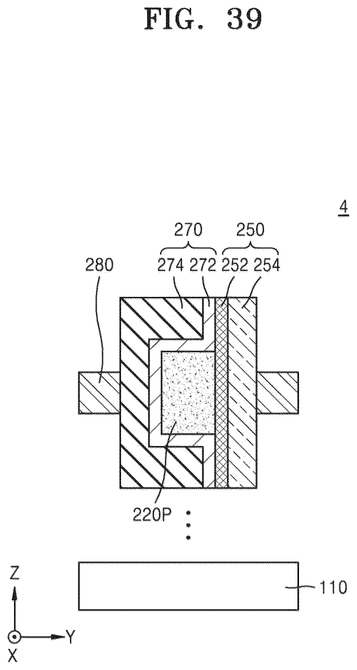

FIG. 39 is a partial enlarged view of the semiconductor memory device 4 according to example embodiments.

Referring to FIGS. 38 and 39 together, the semiconductor memory device 4 may include a plurality of gate structures 270 extending in the vertical direction (Z direction) on the substrate 110, a plurality of back gate structures 250 extending in the vertical direction (Z direction), a plurality of bit lines 280 extending in the second horizontal direction (Y direction), and a plurality of semiconductor patterns 220P connected to the plurality of bit lines 280 and extending in the first horizontal direction (X direction). The semiconductor memory device 4 may include a plurality of cell capacitors CAP. One end of the plurality of semiconductor patterns 220P is connected to the plurality of bit lines 280, and the other end of the plurality of semiconductor patterns 220P, which is opposite to the one end of the plurality of semiconductor patterns 220P, is connected to the plurality of cell capacitors CAP. The plurality of back gate structures 250 and the plurality of gate structures 270 may be alternately arranged in the second horizontal direction (Y direction).

The back gate structure 250 may cover one side surface of the semiconductor pattern 220P and the gate structure 270 may cover the remaining side surfaces of the semiconductor pattern 220P. For example, the back gate dielectric film 252 may be in contact with one side surface of the semiconductor pattern 220P, and the gate dielectric film 272 may be in contact with the remaining side surfaces of the semiconductor pattern 220P. For example, the back gate electrode film 254 may cover one side surface of the semiconductor pattern 220P with the back gate dielectric film 252 therebetween, and the gate electrode film 274 may cover the other side surfaces of the semiconductor pattern 220P with the gate dielectric film 272 therebetween.

For example, in a cross-section perpendicular to the direction in which the semiconductor pattern 220P extends, that is, the Y-Z cross-section perpendicular to the first horizontal direction (X direction), the back gate structure 250 may cover one of the edges of the semiconductor pattern 220P, and the gate structure 270 may cover the remaining edges of the semiconductor pattern 220P other than the one edge of the semiconductor pattern 220P.

For example, the right side surface of one semiconductor pattern 220P located on the left side of the back gate structure 250 may be in contact with the left side surface of the back gate structure 250. Also, the remaining surfaces of the one semiconductor pattern 220P, that is, the left side surface, the upper surface, and the lower surface of the one semiconductor pattern 220P, may be in contact with one gate structure 270 located on the left side of the back gate structure 250.

While aspects of example embodiments have been particularly shown and described, it will be understood that various changes in form and details may be made therein without departing from the spirit and scope of the following claims.

What is claimed is:

1. A semiconductor memory device comprising:
a semiconductor pattern extending in a first direction;
a bit line extending in a second direction perpendicular to the first direction and connected to a first end of the semiconductor pattern in the first direction;
a cell capacitor extending in the first direction and connected to a second end of the semiconductor pattern in the first direction;
a gate structure extending in a third direction perpendicular to both the first direction and the second direction; and
a back gate structure extending in the third direction,
wherein the semiconductor pattern is between the gate structure and the back gate structure, and
wherein the back gate structure covers one surface of the semiconductor pattern and the gate structure covers other surfaces of the semiconductor pattern.

2. The semiconductor memory device of claim 1, wherein the back gate structure covers one of two surfaces of the semiconductor pattern in the second direction, and
wherein the gate structure covers another one of the two surfaces of the semiconductor pattern in the second direction and both of two surfaces of the semiconductor pattern in the third direction.

3. The semiconductor memory device of claim 2, wherein the semiconductor pattern is one of a plurality of semiconductor patterns, the gate structure is one of a plurality of gate structures, and the back gate structure is one of a plurality of back gate structures,
wherein the semiconductor pattern, the gate structure, and the back gate structure is spaced apart from each other in the second direction,
wherein one back gate structure among the plurality of back gate structures is located in the second direction between two gate structures adjacent to each other in the second direction among the plurality of gate structures, and
wherein two gate structures among the plurality of gate structures are arranged in the second direction between two back gate structures adjacent to each other in the second direction among the plurality of back gate structures.

4. The semiconductor memory device of claim 3, wherein the one back gate structure is shared by:
a first semiconductor pattern of the plurality of semiconductor patterns located on one side of the one back gate structure in the second direction;
a first gate structure of the plurality of gate structures located on the one side of the one back gate structure in the second direction;
a second semiconductor pattern of the plurality of semiconductor patterns located on another side of the one back gate structure in the second direction; and
a second gate structure of the plurality of gate structures located on the other side of the one back gate structure in the second direction.

5. The semiconductor memory device of claim 4, wherein the one back gate structure covers one surface of the first semiconductor pattern and one surface of the second semiconductor pattern, which face each other in the second direction,
wherein the first gate structure covers another surface of the first semiconductor pattern in the second direction and both of two surfaces of the first semiconductor pattern in the third direction, and
wherein the second gate structure covers another surface of the second semiconductor pattern in the second direction and both of two surfaces of the second semiconductor pattern in the third direction.

6. The semiconductor memory device of claim 1, further comprising a sub insulating layer between the semiconductor pattern and the back gate structure.

7. The semiconductor memory device of claim 1, further comprising a sub insulating layer located between the semiconductor pattern and the back gate structure, and extending from the back gate structure into the semiconductor pattern,
wherein the semiconductor pattern covers one of two surfaces of the sub insulating layer in the second direction and both of two surfaces of the sub insulating layer in the third direction.

8. The semiconductor memory device of claim 1, further comprising a sub semiconductor layer comprising a material different from a material of the semiconductor pattern,
wherein the sub semiconductor layer is between the semiconductor pattern and the back gate structure.

9. The semiconductor memory device of claim 1, further comprising a sub semiconductor layer comprising a material different from a material of the semiconductor pattern,
wherein the sub semiconductor layer is between the semiconductor pattern and the back gate structure, and extends from the back gate structure into the semiconductor pattern, and
wherein the semiconductor pattern covers one of two surfaces of the sub semiconductor layer in the second direction and both of two surfaces of the sub semiconductor layer in the third direction.

10. The semiconductor memory device of claim 1, wherein the semiconductor pattern is one of a plurality of semiconductor patterns, the gate structure is one of a plurality of gate structures, and the back gate structure is one of a plurality of back gate structures,
wherein the semiconductor pattern, the gate structure, and the back gate structure is spaced apart from each other in the second direction,
wherein the plurality of back gate structures and the plurality of gate structures are alternately arranged in the second direction,
wherein each of the plurality of back gate structures covers one of two surfaces of a corresponding semiconductor pattern among the plurality of semiconductor patterns in the second direction, and
wherein each of the plurality of gate structures covers another one of the two surfaces of the corresponding semiconductor pattern among the plurality of semiconductor patterns in the second direction and both of two surfaces of the corresponding semiconductor pattern in the third direction.

11. A semiconductor memory device comprising:
a plurality of semiconductor patterns, each of the plurality of semiconductor patterns extending in a first horizontal direction on a substrate, wherein the plurality of semiconductor patterns are spaced apart from each other in a vertical direction and a second horizontal direction perpendicular to the first horizontal direction;
a plurality of bit lines extending in the vertical direction on the substrate, wherein the plurality of bit lines are spaced apart from each other in the second horizontal direction, and connected to first ends of the plurality of semiconductor patterns in the first horizontal direction;
a plurality of cell capacitors extending in the first horizontal direction on the substrate and connected to second ends of the plurality of semiconductor patterns in the first horizontal direction;
a plurality of back gate structures extending in the second horizontal direction and covering a first one of upper surfaces and lower surfaces of the plurality of semiconductor patterns, wherein the plurality of back gate structures are spaced apart from each other in the vertical direction; and
a plurality of gate structures extending in the second horizontal direction and covering a second one of the upper surfaces and the lower surfaces of the plurality of semiconductor patterns, and each of two side surfaces of the plurality of semiconductor patterns in the second horizontal direction,
wherein an upper surface and a lower surface of one back gate structure among the plurality of back gate structures respectively cover a lower surface of a first semiconductor pattern, which is one semiconductor pattern provided above the one back gate structure among the plurality of semiconductor patterns, and an upper surface of a second semiconductor pattern, which is another semiconductor pattern provided below the one back gate structure among the plurality of semiconductor patterns.

12. The semiconductor memory device of claim 11, wherein the plurality of gate structures comprise a first gate structure provided above the first semiconductor pattern and a second gate structure provided below the second semiconductor pattern,
wherein the first gate structure covers an upper surface of the first semiconductor pattern and both of side surfaces of the first semiconductor pattern in the second horizontal direction, and
wherein the second gate structure covers a lower surface of the second semiconductor pattern and both of side surfaces of the second semiconductor pattern in the second horizontal direction.

13. The semiconductor memory device of claim 11, wherein each of the plurality of back gate structures comprises a back gate electrode film and a back gate dielectric film between the back gate electrode film and the plurality of semiconductor patterns,
wherein each of the plurality of gate structures comprises a gate electrode film and a gate dielectric film between the gate electrode film and the plurality of semiconductor patterns, and
wherein a portion of the back gate dielectric film is in contact with a portion of the gate dielectric film.

14. The semiconductor memory device of claim 11, wherein the plurality of gate structures and the plurality of back gate structures are spaced apart from each other in the vertical direction,
wherein two gate structures among the plurality of gate structures are arranged between two back gate structures adjacent to each other in the vertical direction among the plurality of back gate structures, and
wherein one back gate structure among the plurality of back gate structures is located between two gate structures adjacent to each other in the vertical direction among the plurality of gate structures, wherein the one back gate structure is shared by two semiconductor patterns which are respectively located above and below the one back gate structure among the plurality of semiconductor patterns.

15. The semiconductor memory device of claim 11, further comprising sub insulating layers respectively arranged between the plurality of semiconductor patterns and the plurality of back gate structures covering the plurality of semiconductor patterns.

16. The semiconductor memory device of claim 15, wherein each of the plurality of semiconductor patterns has a thickness of less than 5 nm between a sub insulating layer and a gate structure.

17. The semiconductor memory device of claim 11, further comprising sub semiconductor layers comprising materials different from materials of the plurality of semiconductor patterns,
wherein the sub semiconductor layers are respectively arranged between the plurality of semiconductor patterns and the plurality of back gate structures covering the plurality of semiconductor patterns.

18. The semiconductor memory device of claim 17, wherein the sub semiconductor layer comprises a semiconductor material having a band gap less than a band gap of a semiconductor material of the plurality of semiconductor patterns.

19. A semiconductor memory device comprising:
a plurality of semiconductor patterns, each of the plurality of semiconductor patterns extending in a first horizontal direction on a substrate, wherein the plurality of semiconductor patterns are spaced apart from each other in a vertical direction and a second horizontal direction perpendicular to the first horizontal direction;
a plurality of bit lines extending in the vertical direction on the substrate, wherein the plurality of bit lines are spaced apart from each other in the second horizontal direction, and connected to first ends of the plurality of semiconductor patterns in the first horizontal direction;
a plurality of cell capacitors extending in the first horizontal direction on the substrate and connected to second ends of the plurality of semiconductor patterns in the first horizontal direction;
a plurality of back gate structures, each of the plurality of back gate structures extending in the second horizontal direction, wherein the plurality of back gate structures are spaced apart from each other in the vertical direction, the plurality of back gate structures each comprising a back gate dielectric film covering a first one of an upper surface and a lower surfaces of a corresponding semiconductor pattern among the plurality of semiconductor patterns and a back gate electrode film covering the back gate dielectric film; and
a plurality of gate structures, each of the plurality of gate structures extending in the second horizontal direction, wherein the plurality of gate structures are spaced apart from each other in the vertical direction, and each of the plurality of gate structures comprises a gate dielectric film covering a second one of the upper surface and the lower surface of the corresponding semiconductor pattern among the plurality of semiconductor patterns and both of side surfaces of the corresponding semiconductor pattern in the second horizontal direction and a gate electrode film covering the gate dielectric film,
wherein two gate structures among the plurality of gate structures are between one semiconductor pattern among the plurality of semiconductor patterns and another semiconductor pattern above the one semiconductor pattern, and one back gate structure among the plurality of back gate structures is between one semiconductor pattern among the plurality of semiconductor patterns and another semiconductor pattern below the one semiconductor pattern.

20. The semiconductor memory device of claim 19, wherein the back gate dielectric films and the gate dielectric films covering two semiconductor patterns adjacent to each other in the second horizontal direction among the plurality of semiconductor patterns are in contact with each other between the two semiconductor patterns adjacent to each other in the second horizontal direction.
